(19) United States
(12) Patent Application Publication
(10) Pub. No.: US 2019/0139783 A1
(43) Pub. Date: May 9, 2019

(54) SEMICONDUCTOR DEVICE AND METHOD FOR FABRICATING SEMICONDUCTOR DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Kazutaka KURIKI, Ebina, Kanagawa (JP); Yuji EGI, Atsugi, Kanagawa (JP); Noritaka ISHIHARA, Koza, Kanagawa (JP); Yusuke NONAKA, Atsugi, Kanagawa (JP); Yasumasa YAMANE, Atsugi, Kanagawa (JP); Ryo TOKUMARU, Isehara, Kanagawa (JP); Daisuke MATSUBAYASHI, Sagamihara, Kanagawa (JP)

(73) Assignee: SEMICONDUCTOR ENERGY LABORATORY CO., LTD., Atsugi-shi, Kanagawa-ken (JP)

(21) Appl. No.: 16/093,268

(22) PCT Filed: Apr. 11, 2017
(86) PCT No.: PCT/IB2017/052071

§ 371 Date: Oct. 12, 2018

(30) Foreign Application Priority Data
Apr. 22, 2016 (JP) 2016-086299

(51) Int. Cl. H01L 21/4757; H01L 27/105; H01L 27/12; H01L 29/66; H01L 21/443; H01L 21/477; H01L 21/02; H01L 29/786; H01J 37/32

(52) U.S. Cl. CPC H01L 21/47576; H01J 2237/3365; H01L 27/1207; H01L 27/1225; H01L 27/1251; H01L 27/1255; H01L 27/127; H01L 29/66969; H01L 21/443; H01L 21/477; H01L 21/02266; H01L 21/0234; H01L 21/02565; H01L 21/02631; H01L 29/7869; H01L 29/78648; H01L 29/78696; H01J 37/32192; H01L 27/1052

(57) ABSTRACT

A semiconductor device having high reliability is provided.

A first conductor is formed, a first insulator is formed over the first conductor, a second insulator is formed over the first insulator, a third insulator is formed over the second insulator, microwave-excited plasma treatment is performed on the third insulator, an island-shaped first oxide semiconductor is formed over the third insulator and a second conductor and a third conductor are formed over the first oxide semiconductor, an oxide semiconductor film is formed over the first oxide semiconductor, the second conductor, and the third conductor, a first insulating film is formed over the oxide semiconductor film, a conductive film is formed over the first insulating film, a fourth insulator and a fourth conductor are formed by partly removing the first insulating film and the conductive film, a second insulating film is formed to cover the oxide semiconductor film, the fourth insulator, and the fourth conductor, a second oxide semiconductor and a fifth insulator are formed by partly removing the oxide semiconductor film and the second insulating film to expose a side surface of the first oxide semiconductor, a sixth insulator is formed in contact with the side surface of the first oxide semiconductor and a side surface of the second oxide semiconductor, a seventh insulator is formed in contact with the sixth insulator, and heat treatment is performed.

### TECHNICAL FIELD

One embodiment of the present invention relates to a semiconductor device and a method for fabricating the semiconductor device.

Note that one embodiment of the present invention is not limited to the above technical field. One embodiment of the invention disclosed in this specification and the like relates to an object, a method, or a manufacturing method. Alternatively, one embodiment of the present invention relates to a process, a machine, manufacture, or a composition of matter (a composition of matter).

Note that in this specification and the like, a semiconductor device generally means a device that can function by utilizing semiconductor characteristics. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

A technique in which a transistor is formed using a semiconductor thin film has attracted attention. The transistor is used in a wide range of electronic devices such as an integrated circuit (IC) and an image display device (also simply referred to as a display device). A silicon-based semiconductor material is widely known as a material for a semiconductor thin film that can be used in a transistor; an oxide semiconductor has attracted attention as another material.

For example, techniques have been disclosed by each of which a display device is fabricated using a transistor whose active layer is formed of zinc oxide or an In—Ga—Zn-based oxide as an oxide semiconductor (see Patent Document 1 and Patent Document 2).

Moreover, in recent years, a technique has been disclosed by which an integrated circuit of a memory device is fabricated using a transistor including an oxide semiconductor (see Patent Document 3). Furthermore, not only memory devices but also arithmetic devices and the like have been fabricated using transistors including oxide semiconductors.

However, it is known that a transistor including an oxide semiconductor as an active layer has a problem in that the electrical characteristics are easily changed by impurities and oxygen vacancies in the oxide semiconductor and thus the reliability is low. For example, the threshold voltage of the transistor varies in some cases between before and after a bias-temperature stress test (BT test).

### REFERENCES

### Patent Documents

### [Patent Document 1] Japanese Published Patent Application No. 2007-123861

### [Patent Document 2] Japanese Published Patent Application No. 2007-96055

### [Patent Document 3] Japanese Published Patent Application No. 2011-119674

### SUMMARY OF INVENTION

### Problems to be Solved by the Invention

In view of the above, an object of one embodiment of the present invention is to provide a semiconductor device having high reliability. Another object of one embodiment of the present invention is to provide a semiconductor device including an oxide semiconductor with the reduced amount of impurities. Another object of one embodiment of the present invention is to provide a semiconductor device including an oxide semiconductor with the reduced amount of oxygen vacancies.

Another object of one embodiment of the present invention is to provide a semiconductor device having good electrical characteristics. Another object of one embodiment of the present invention is to provide a semiconductor device with reduced power consumption. Another object of one embodiment of the present invention is to provide a semiconductor device that can be miniaturized or highly integrated. Another object of one embodiment of the present invention is to provide a semiconductor device with high productivity.

Note that the description of these objects does not disturb the existence of other objects. Note that one embodiment of the present invention does not necessarily achieve all of these objects. Note that other objects will be apparent from the description of the specification, the drawings, the claims, and the like, and other objects can be derived from the description of the specification, the drawings, the claims, and the like.

### Means for Solving the Problems

In view of the above, the present invention achieves a reduction in the amount of oxygen vacancies in an oxide semiconductor by supplying excess oxygen to the oxide semiconductor from an oxide insulator around the oxide semiconductor.

Moreover, dehydration or dehydrogenation is achieved by heat treatment or the like in order to prevent impurities such as water and hydrogen from entering the oxide semiconductor from the oxide insulator or the like around the oxide semiconductor. Moreover, an insulator having a barrier property against impurities such as water and hydrogen is formed to cover the oxide insulator and the oxide semiconductor in order to prevent impurities such as water and hydrogen from entering the dehydrated or dehydrogenated oxide insulator or the like from the outside.

Moreover, the insulator having a barrier property against impurities such as water and hydrogen is made to have low oxygen permeability. Accordingly, outward diffusion of oxygen is prevented and oxygen is effectively supplied to the oxide semiconductor and the surrounding oxide insulator.

In such a manner, the amount of impurities such as water and hydrogen contained in the oxide semiconductor and the surrounding oxide insulator is reduced, and a reduction in the amount of oxygen vacancies in the oxide semiconductor is achieved.

In one embodiment of the present invention, a first conductor is formed; a first insulator is formed over the first conductor; a second insulator is formed over the first insulator; a third insulator is formed over the second insulator; microwave-excited plasma treatment is performed on the third insulator; an island-shaped first oxide semiconductor is formed over the third insulator and a second conductor and a third conductor are formed over the first oxide semiconductor; an oxide semiconductor film is formed over the first oxide semiconductor, the second conductor, and the third conductor; a first insulating film is formed over the oxide semiconductor film; a conductive film is formed over the first insulating film; a fourth insulator and a fourth conductor are formed by partly removing the first insulating film and the conductive film; a second insulating film is formed to cover the oxide semiconductor film, the fourth insulator, and the fourth conductor; a second oxide semiconductor and a fifth insulator are formed by partly removing the oxide semiconductor film and the second insulating film to expose a side surface of the first oxide semiconductor; a sixth insulator is formed in contact with the side surface of the first oxide semiconductor and a side surface of the second oxide semiconductor; a seventh insulator is formed in contact with the sixth insulator; and heat treatment is performed.

In one embodiment of the present invention, a first conductor is formed; a first insulator is formed over the first conductor; a second insulator is formed over the first insulator; a third insulator is formed over the second insulator; microwave-excited plasma treatment is performed on the third insulator; an island-shaped first oxide semiconductor is formed over the third insulator and a second conductor and a third conductor are formed over the first oxide semiconductor; an oxide semiconductor film is formed over the first oxide semiconductor, the second conductor, and the third conductor; a first insulating film is formed over the oxide semiconductor film; a conductive film is formed over the first insulating film; a fourth conductor is formed by partly removing the conductive film; a second insulating film is formed to cover the first insulating film and the fourth conductor; a second oxide semiconductor, a fourth insulator, and a fifth insulator are formed by partly removing the oxide semiconductor film, the first insulating film, and the second insulating film to expose a side surface of the first oxide semiconductor; a sixth insulator is formed in contact with the side surface of the first oxide semiconductor and a side surface of the second oxide semiconductor; a seventh insulator is formed in contact with the sixth insulator; and heat treatment is performed.

The microwave-excited plasma treatment in the above embodiment is performed with a pressure of lower than or equal to 70 Pa.

The microwave-excited plasma treatment in the above embodiment is performed with an oxygen flow rate of higher than or equal to 10% and lower than or equal to 30%.

The microwave-excited plasma treatment in the above embodiment is performed while an RF bias is applied to a substrate.

The sixth insulator in the above embodiment is formed by a sputtering method at a substrate temperature of higher than or equal to 120° C. and lower than or equal to 150° C.

After heat treatment is performed at higher than or equal to 100° C. in a film deposition apparatus, the sixth insulator in the above embodiment is deposited in the film deposition apparatus without exposure to the air.

### Effect of the Invention

According to one embodiment of the present invention, a semiconductor device having high reliability can be provided. According to another embodiment of the present invention, a semiconductor device including an oxide semiconductor with the reduced amount of impurities can be provided. According to another embodiment of the present invention, a semiconductor device including an oxide semiconductor with the reduced amount of oxygen vacancies can be provided.

According to another embodiment of the present invention, a semiconductor device having good electrical characteristics can be provided. According to another embodiment of the present invention, a semiconductor device with reduced power consumption can be provided. According to another embodiment of the present invention, a semiconductor device that can be miniaturized or highly integrated can be provided. According to another embodiment of the present invention, a semiconductor device with high productivity can be provided.

Note that the description of these effects does not disturb the existence of other effects. Note that one embodiment of the present invention does not necessarily have all of these effects. Note that other effects will be apparent from the description of the specification, the drawings, the claims, and the like and other effects can be derived from the description of the specification, the drawings, the claims, and the like.

### BRIEF DESCRIPTION OF DRAWINGS

FIG. 1 A top view and cross-sectional views of a semiconductor device of one embodiment of the present invention.

FIG. 2 A flow chart showing a method for fabricating a semiconductor device of one embodiment of the present invention.

FIG. 3 Diagrams showing a method for fabricating a transistor of one embodiment of the present invention.

FIG. 4 Diagrams showing a method for fabricating a transistor of one embodiment of the present invention.

FIG. 5 Diagrams showing a method for fabricating a transistor of one embodiment of the present invention.

FIG. 6 Diagrams showing a method for fabricating a transistor of one embodiment of the present invention.

FIG. 7 Diagrams showing a method for fabricating a transistor of one embodiment of the present invention.

FIG. 8 Diagrams showing a method for fabricating a transistor of one embodiment of the present invention.

FIG. 9 Diagrams showing a method for fabricating a transistor of one embodiment of the present invention.

FIG. 10 Diagrams showing a method for fabricating a transistor of one embodiment of the present invention.

FIG. 11 Diagrams showing a method for fabricating a transistor of one embodiment of the present invention.

FIG. 12 Diagrams showing a method for fabricating a transistor of one embodiment of the present invention.

FIG. 13 Diagrams showing a method for fabricating a transistor of one embodiment of the present invention.

FIG. 14 Diagrams showing a method for fabricating a transistor of one embodiment of the present invention.

FIG. 15 Diagrams showing a method for fabricating a transistor of one embodiment of the present invention.

FIG. 16 Diagrams showing a method for fabricating a transistor of one embodiment of the present invention.

FIG. 17 Diagrams showing a method for fabricating a transistor of one embodiment of the present invention.

FIG. 18 Diagrams showing a method for fabricating a transistor of one embodiment of the present invention.

FIG. 19 Diagrams showing a method for fabricating a transistor of one embodiment of the present invention.

FIG. 20 Diagrams showing a method for fabricating a transistor of one embodiment of the present invention.

FIG. 21 Diagrams showing a method for fabricating a transistor of one embodiment of the present invention.

FIG. 22 Diagrams showing a method for fabricating a transistor of one embodiment of the present invention.

FIG. 23 A top view and cross-sectional views of a semiconductor device of one embodiment of the present invention.

FIG. 24 A diagram showing energy levels of radicals and ions in plasma.

FIG. 25 A schematic diagram showing a mechanism for reducing hydrogen in an oxide by an insulator.

FIG. 26 Diagrams each showing an atomic ratio range of an oxide of the present invention.

FIG. 27 Band diagrams of stacked-layer structures of oxides.

FIG. 28 A cross-sectional view of a semiconductor device of one embodiment of the present invention.

FIG. 29 A cross-sectional view of a semiconductor device of one embodiment of the present invention.

FIG. 30 A cross-sectional view of a semiconductor device of one embodiment of the present invention.

FIG. 31 A top view showing a manufacturing apparatus of one embodiment of the present invention.

FIG. 32 A top view showing a chamber of one embodiment of the present invention.

FIG. 33 A top view showing a chamber of one embodiment of the present invention.

FIG. 34 Diagrams showing a structure and SIMS results in this example.

FIG. 35 A diagram showing a structure in this example.

FIG. 36 Diagrams showing a structure and TDS results in this example.

FIG. 37 Diagrams showing a structure and TDS results in this example.

FIG. 38 Diagrams showing a structure and TDS results in this example.

FIG. 39 Diagrams showing a structure and TDS results in this example.

FIG. 40 Diagrams showing a structure and TDS results in this example.

FIG. 41 Diagrams showing a structure and TDS results in this example.

FIG. 42 Diagrams showing a structure and SIMS results in this example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope thereof. Thus, the present invention should not be construed as being limited to the description in the following embodiments. Note that in the structures of the invention described below, the same portions or portions having similar functions are denoted by the same reference numerals in different drawings, and description thereof is not repeated in some cases.

Furthermore, the position, size, range, and the like of each component illustrated in the drawings and the like do not represent the actual position, size, range, and the like in some cases for easy understanding of the invention. Therefore, the disclosed invention is not necessarily limited to the position, size, range, and the like as disclosed in the drawings and the like. For example, in the actual manufacturing process, a layer, a resist mask, or the like might be unintentionally reduced in size by treatment such as etching, which is not illustrated in some cases for easy understanding.

Furthermore, especially in a top view (also referred to as a “plan view”), a perspective view, or the like, some components might not be shown for easy understanding of the invention. Furthermore, some hidden lines and the like might not be shown.

Ordinal numbers such as “first” and “second” in this specification and the like are used in order to avoid confusion among components and do not denote the priority or the order such as the order of steps or the stacking order. Furthermore, a term without an ordinal number in this specification and the like might be provided with an ordinal number in the scope of claims in order to avoid confusion among components. Furthermore, a term with an ordinal number in this specification and the like might be provided with a different ordinal number in the scope of claims. Furthermore, even when a term is provided with an ordinal number in this specification and the like, the ordinal number might be omitted in the scope of claims and the like.

Furthermore, in this specification and the like, the term “electrode” or “wiring” does not functionally limit a component. For example, an “electrode” is used as part of a “wiring” in some cases, and vice versa. Moreover, the term “electrode” or “wiring” also includes the case where a plurality of “electrodes” or “wirings” are formed in an integrated manner, for example.

Note that the term “over” or “under” in this specification and the like does not necessarily mean directly over or directly under and direct contact in the description of a positional relationship between components. For example, the expression “electrode B over insulating layer A” does not necessarily mean that the electrode B is formed over and directly in contact with the insulating layer A and does not exclude the case where another component is provided between the insulating layer A and the electrode B.

Furthermore, functions of a source and a drain are interchanged with each other depending on operation conditions, for example, when a transistor of different polarity is employed or when the direction of current flow is changed in circuit operation; therefore, it is difficult to define which is the source or the drain. Thus, the terms “source” and “drain” can be interchanged with each other in this specification.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

A channel width refers to, for example, the length of a portion where a source and a drain face each other in a region where a semiconductor (or a portion where current flows in a semiconductor when a transistor is in an on state) and a gate electrode overlap with each other, or a region where a channel is formed. Note that in one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter, referred to as an “effective channel width”) is different from a channel width shown in a top view of a transistor (hereinafter, referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW: Surrounded Channel Width)” in some cases. Furthermore, in this specification, the simple term “channel width” refers to a surrounded channel width or an apparent channel width in some cases. Alternatively, in this specification, the simple term “channel width” refers to an effective channel width in some cases. Note that a channel length, a channel width, an effective channel width, an apparent channel width, a surrounded channel width, and the like can be determined, for example, by analyzing a cross-sectional TEM image and the like.

Note that in the case where field-effect mobility, a current value per channel width, and the like of a transistor are obtained by calculation, the calculation is performed using a surrounded channel width in some cases. In that case, a value different from one calculated using an effective channel width is obtained in some cases.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased, the carrier mobility may be decreased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also serves as an impurity in some cases. Also in the case of an oxide semiconductor, oxygen vacancies are formed by entry of impurities, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

Furthermore, in this specification, the term “parallel” indicates that the angle formed between two straight lines is greater than or equal to −10° and less than or equal to 10°. Accordingly, the case where the angle is greater than or equal to −5° and less than or equal to 5° is also included. Furthermore, the term “substantially parallel” indicates that the angle formed between two straight lines is greater than or equal to −30° and less than or equal to 30°. Furthermore, the terms “perpendicular” and “orthogonal” indicate that the angle formed between two straight lines is greater than or equal to 80° and less than or equal to 100°. Accordingly, the case where the angle is greater than or equal to 85° and less than or equal to 95° is also included. Furthermore, the term “substantially perpendicular” indicates that the angle formed between two straight lines is greater than or equal to 60° and less than or equal to 120°.

Note that in this specification and the like, the terms “identical”, “the same”, “equal”, “uniform”, and the like (including synonyms thereof) used in describing calculation values and measurement values contain an error of ±20% unless otherwise specified.

Furthermore, in this specification and the like, in the case where an etching step (removal step) is performed after a resist mask is formed by a photolithography method, the resist mask is removed after the etching step, unless otherwise specified.

Note that the terms “film” and “layer” can be interchanged with each other depending on the case or circumstances. For example, the term “conductive layer” can be changed into the term “conductive film” in some cases. For another example, the term “insulating film” can be changed into the term “insulating layer” in some cases.

Furthermore, unless otherwise specified, transistors described in this specification and the like are enhancement-type (normally-off-type) field-effect transistors. Furthermore, unless otherwise specified, transistors described in this specification and the like are n-channel transistors. Thus, unless otherwise specified, the threshold voltage (also referred to as “Vth”) is higher than 0 V.

### Embodiment 1

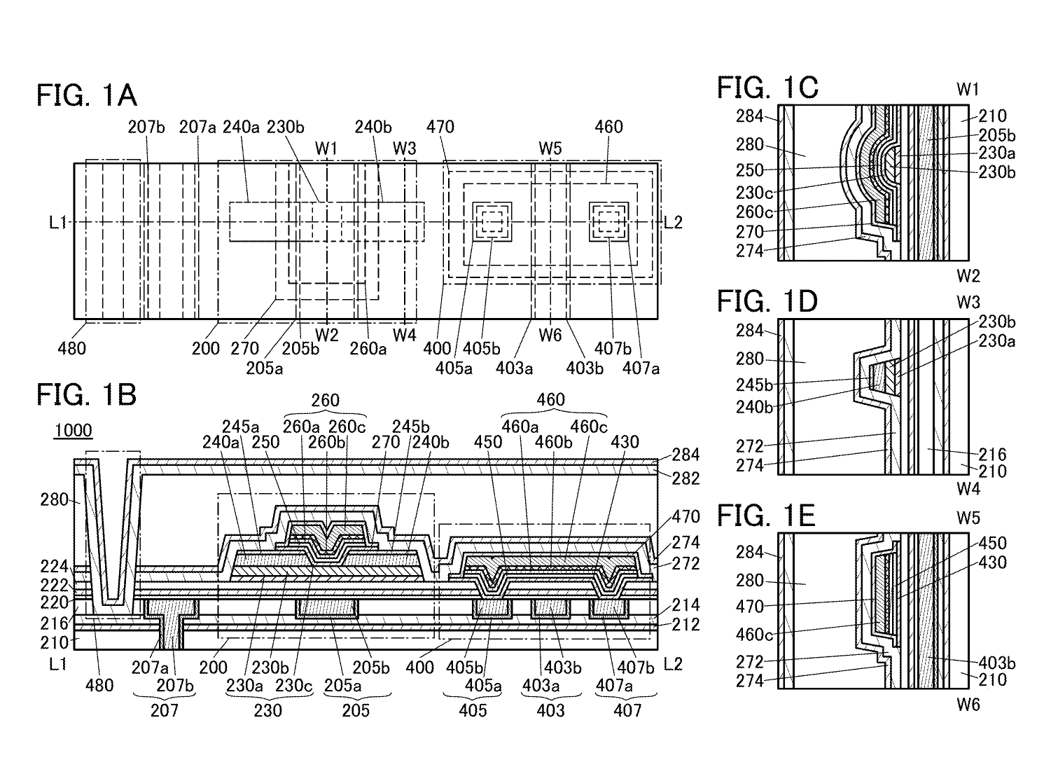

In this embodiment, a semiconductor device provided with a transistor having high reliability and a method for fabricating the semiconductor device will be described with reference to FIG. 1 to FIG. 25. The transistor provided in the semiconductor device described in this embodiment uses an oxide semiconductor for an active layer. The amount of impurities such as water or hydrogen in the oxide semiconductor is reduced and excess oxygen is supplied to reduce the amount of oxygen vacancies, so that the reliability of the transistor provided in the semiconductor device can be improved.

### <Structure Example of Semiconductor Device 1000>

FIG. 1(A), FIG. 1(B), FIG. 1(C), FIG. 1(D), and FIG. 1(E) are a top view and cross-sectional views showing a semiconductor device 1000. The semiconductor device 1000 includes a transistor 200 and a transistor 400. The transistor 200 and the transistor 400 which are formed over a substrate (not shown in the figure) have different structures. For example, the transistor 400 can have a structure in which a drain current (hereinafter, referred to as Icut) is smaller than that of the transistor 200 when a back gate voltage and a top gate voltage are each 0 V. A structure is employed in which the transistor 400 is used as a switching element to control the potential of a back gate of the transistor 200. Thus, a charge at a node connected to the back gate of the transistor 200 can be prevented from being lost by making the node connected to the back gate of the transistor 200 have a desired potential and then turning off the transistor 400.

Here, FIG. 1(A) is a top view of the semiconductor device 1000. FIG. 1(B) corresponds to the dashed-dotted line L1-L2 in FIG. 1(A) and is a cross-sectional view of the transistor 200 and the transistor 400 in the channel length direction. Furthermore, FIG. 1(C) corresponds to the dashed-dotted line W1-W2 in FIG. 1(A) and is a cross-sectional view of the transistor 200 in the channel width direction. Furthermore, FIG. 1(D) is a cross-sectional view of the transistor 200 that corresponds to the dashed-dotted line W3-W4 in FIG. 1(A). Furthermore, FIG. 1(E) corresponds to the dashed-dotted line W5-W6 in FIG. 1(A) and is a cross-sectional view of the transistor 400 in the channel width direction.

Hereinafter, the structure of each of the transistor 200 and the transistor 400 will be described with reference to FIG. 1(A), FIG. 1(B), FIG. 1(C), FIG. 1(D), and FIG. 1(E). Note that the details of the materials of the transistor 200 and the transistor 400 will be described in detail in <Materials>.

### [Transistor 200]

As shown in FIG. 1(A), FIG. 1(B), FIG. 1(C), and FIG. 1(D), the transistor 200 includes an insulator 212 provided over an insulator 210, an insulator 214 provided over the insulator 212, a conductor 205 (a conductor 205a and a conductor 205b) provided over the insulator 214, an insulator 220, an insulator 222, and an insulator 224 provided over the conductor 205, an oxide 230 (an oxide 230a, an oxide 230b, and an oxide 230c) provided over the insulator 224, a conductor 240a and a conductor 240b (hereinafter, the conductor 240a and the conductor 240b are collectively referred to as a conductor 240) provided over the oxide 230b, a layer 245a and a layer 245b (hereinafter, the layer 245a and the layer 245b are collectively referred to as a layer 245) provided over the conductor 240, an insulator 250 provided over the oxide 230c, a conductor 260 (a conductor 260a, a conductor 260b, and a conductor 260c) provided over the insulator 250, a layer 270 provided over the conductor 260c, an insulator 272 provided over the layer 270, and an insulator 274 provided over the insulator 272.

For the insulator 212 and the insulator 214, an insulating material that is less likely to transmit impurities such as water or hydrogen is preferably used, and for example, aluminum oxide is preferably used. This can suppress diffusion of impurities such as hydrogen or water from a layer under the insulator 210 to a layer over the insulator 212 and the insulator 214. Note that it is preferable that the insulator 212 and the insulator 214 be less likely to transmit at least one of impurities such as a hydrogen atom, a hydrogen molecule, a water molecule, an oxygen atom, an oxygen molecule, a nitrogen atom, a nitrogen molecule, a nitrogen oxide molecule (N₂O, NO, NO₂, and the like), and a copper atom. Furthermore, hereinafter, the same applies to the description of an insulating material that is less likely to transmit impurities.

Furthermore, the insulator 212 is preferably deposited using an atomic layer deposition (ALD: Atomic Layer Deposition) method, for example. Accordingly, the insulator 212 can be deposited with good coverage, and formation of cracks, pinholes, and the like can be suppressed. Furthermore, the insulator 214 is preferably deposited using a sputtering method, for example. This allows the insulator 214 to be deposited at a higher deposition rate than the insulator 212 and to have a larger thickness with higher productivity than the insulator 212. With such a stack of the insulator 212 and the insulator 214, a barrier property against impurities such as hydrogen or water can be improved. Note that a structure may be employed in which the insulator 212 is provided under the insulator 214. Furthermore, when the insulator 214 has a sufficient barrier property against impurities, a structure may be employed in which the insulator 212 is not provided.

Furthermore, for the insulator 212 and the insulator 214, an insulating material that is less likely to transmit oxygen is preferably used. This can suppress downward diffusion of oxygen contained in the insulator 224 or the like. Thus, oxygen can be effectively supplied to the oxide 230b.

Here, an opening is formed in the insulator 210, the insulator 212, and the insulator 214, and the insulator 210, the insulator 212, and the insulator 214 are on the same plane on the inside of the opening. A plurality of openings are formed in the insulator 216, one of them is formed to overlap with the position of the opening in the insulator 210, the insulator 212, and the insulator 214, and the diameter of the opening is larger than that of the opening in the insulator 210, the insulator 212, and the insulator 214. Furthermore, the other openings in the insulator 216 reach a top surface of the insulator 214.

The conductor 205a is formed in contact with the inside of the opening in the insulator 216, and the conductor 205b is formed on the inner side. Here, the top surfaces of the conductor 205a and the conductor 205b can be substantially level with the top surface of the insulator 216.

Furthermore, like the conductor 205, a conductor 207 may be provided. The conductor 207 is provided in the opening formed in the insulator 210, the insulator 212, the insulator 214, and the insulator 216. Part of the conductor 207 formed in the same layer as the insulator 216 functions as a wiring, and part of the conductor 207 formed in the same layer as the insulator 210, the insulator 212, and the insulator 216 functions as a plug. As the conductor 207, a conductor 207a is formed in contact with the inside of the opening, and a conductor 207b is formed inside the opening with the conductor 207a positioned therebetween. Here, top surfaces of the conductor 207a and the conductor 207b can be substantially level with the top surface of the insulator 216. When such a conductor 207 is provided, it can be connected to a wiring, a circuit element, a semiconductor element, or the like positioned in a layer under the insulator 210. Furthermore, when a similar wiring and plug are provided in a layer over the conductor 207, it can be connected to a wiring, a circuit element, a semiconductor element, or the like positioned in an upper layer.

Here, for the conductor 205a and the conductor 207a, a conductive material that is less likely to transmit impurities such as water or hydrogen is preferably used. Furthermore, for example, tantalum, tantalum nitride, ruthenium, or ruthenium oxide is preferably used, and a single layer or a stacked layer can be used. This can suppress diffusion of impurities such as hydrogen or water from a layer under the insulator 210 into an upper layer through the conductor 205 or the conductor 207. Note that it is preferable that the conductor 205a and the conductor 207a be less likely to transmit at least one of impurities such as a hydrogen atom, a hydrogen molecule, a water molecule, an oxygen atom, an oxygen molecule, a nitrogen atom, a nitrogen molecule, a nitrogen oxide molecule (N₂O, NO, NO₂, and the like), and a copper atom. Furthermore, hereinafter, the same applies to the description of a conductive material that is less likely to transmit impurities.

Furthermore, when a metal that easily diffuses into silicon oxide, such as copper, is used for the conductor 205b and the conductor 207b, the use of an insulating material that is less likely to transmit copper, such as silicon nitride or silicon nitride oxide, for the insulator 220 can prevent diffusion of impurities such as copper to an area over the insulator 220. At this time, an insulating material that is less likely to transmit copper is also preferably used for the conductor 205a and the conductor 207a to prevent diffusion of impurities such as copper to the outside of the conductor 205a and the conductor 205b.

Furthermore, for the insulator 222, an insulating material that is less likely to transmit impurities such as water or hydrogen and oxygen is preferably used, and for example, aluminum oxide and hafnium oxide are preferably used. This can suppress diffusion of impurities such as hydrogen or water from a layer under the insulator 210 into a layer over the insulator 212 and the insulator 214. Moreover, downward diffusion of oxygen contained in the insulator 224 or the like can be suppressed.

The insulator 224 is preferably formed using an insulator from which oxygen is released by heating. Specifically, it is preferable to use an insulator in which the released amount of oxygen converted into oxygen atoms is 1.0×10¹⁸ atoms/cm³ or more, and preferably 3.0×10²⁰ atoms/cm³ or more in thermal desorption spectroscopy (TDS (Thermal Desorption Spectroscopy)). Note that oxygen released by heating is also referred to as “excess oxygen”. When such an insulator 224 is provided in contact with the oxide 230, oxygen can be supplied to the oxide 230b effectively.

Furthermore, the concentration of impurities such as water, hydrogen, or nitrogen oxide in the insulator 224 is preferably lowered. For example, the released amount of hydrogen from the insulator 224 that is converted into hydrogen molecules per unit area of the insulator 224 is less than or equal to 2×10¹⁵ molecules/cm², preferably less than or equal to 1×10¹⁵ molecules/cm², and further preferably less than or equal to 5×10¹⁴ molecules/cm² in TDS in the range from 50° C. to 500° C.

As the oxide 230a, for example, an oxide deposited under an oxygen atmosphere is preferably used. Thus, the shape of the oxide 230a can be stable. Note that the details of the components of the oxide 230a to the oxide 230c will be described later.

In order to impart stable electrical characteristics and high reliability to the transistor 200, it is preferable that the amounts of impurities and oxygen vacancies in the oxide be reduced so that the oxide 230b is highly purified intrinsic or substantially highly purified intrinsic. The highly purified intrinsic or substantially highly purified intrinsic oxide has a low density of defect states and accordingly has a low density of trap states in some cases.

Furthermore, charges trapped by the trap states in the oxide take a long time to disappear and may behave like fixed charges. Thus, a transistor whose channel region is formed in an oxide having a high density of trap states has unstable electrical characteristics and low reliability in some cases.

Thus, reductions in the amount of oxygen vacancies and impurity concentration in the oxide are effective in achieving stable electrical characteristics and improved reliability of the transistor. Furthermore, in order to reduce the impurity concentration in the oxide, the impurity concentration in an adjacent film is also preferably reduced.

Furthermore, as the oxide 230b, an oxide having a higher electron affinity than the oxide 230a and the oxide 230c is used. For example, as the oxide 230b, an oxide having a higher electron affinity than the oxide 230a and the oxide 230c by 0.07 eV or more and 1.3 eV or less, preferably 0.1 eV or more and 0.7 eV or less, and further preferably 0.1 eV or more and 0.4 eV or less is used. Note that the electron affinity is a difference in energy between the vacuum level and the conduction band minimum.

Furthermore, the oxide 230b includes a first region, a second region, and a third region. In the top view, the third region is sandwiched between the first region and the second region. The transistor 200 includes the conductor 240a over the first region of the oxide 230b and the conductor 240b over the second region of the oxide 230b. One of the conductor 240a and the conductor 240b can function as one of a source conductor and a drain conductor and the other can function as the other of the source conductor and the drain conductor. Thus, one of the first region and the second region of the oxide 230b can function as a source region and the other can function as a drain region. Furthermore, the third region of the oxide 230b can function as a channel formation region.

Here, side surfaces of the conductor 240a and the conductor 240b that are in contact with the oxide 230c each preferably have a taper angle of less than 90°. The angle formed between the side surface of the conductor 240 or the conductor 240b that is in contact with the oxide 230c and the bottom surface thereof is preferably greater than or equal to 45° and less than or equal to 75°. When the conductor 240a and the conductor 240b are formed as described above, the oxide 230c can be deposited with good coverage even in step portions formed by the conductor 240. This can prevent the contact between the oxide 230b and the insulator 250 or the like that is caused by a break or the like of the oxide 230c.

Furthermore, the layer 245a is formed over the conductor 240a, and the layer 245b is formed over the conductor 240b. Here, for the layer 245a and the layer 245b, a material that is less likely to transmit oxygen is preferably used, and for example, aluminum oxide can be used. This can prevent the consumption of surrounding excess oxygen by the oxidation of the conductor 240a and the conductor 240b.

The oxide 230c is formed over the layer 245a, the layer 245b, the conductor 240a, the conductor 240b, the oxide 230b, and the oxide 230a. Here, the oxide 230c is in contact with a top surface of the oxide 230b, side surfaces of the oxide 230b in the channel width direction, side surfaces of the oxide 230a in the channel width direction, and a top surface of the insulator 224. The oxide 230c may have a function of supplying oxygen to the oxide 230b. Furthermore, impurities such as water or hydrogen can be prevented from directly entering the oxide 230b from the insulator 250 by forming the insulator 250 over the oxide 230c. Furthermore, for example, an oxide deposited under an oxygen atmosphere is preferably used. Thus, the shape of the oxide 230c can be stable.

The insulator 250 can function as a gate insulating film. Like the insulator 224, the insulator 250 is preferably formed using an insulator from which oxygen is released by heating. When such an insulator 250 is provided in contact with the oxide 230, oxygen can be effectively supplied to the oxide 230. Furthermore, as in the insulator 224, the concentration of impurities such as water or hydrogen in the insulator 250 is preferably lowered.

The conductor 260a is included over the insulator 250, the conductor 260b is included over the conductor 260a, and the conductor 260c is included over the conductor 260b. The insulator 250 and the conductor 260 include a region overlapping with the third region. Furthermore, end portions of the insulator 250, the conductor 260a, the conductor 260b, and the conductor 260c are substantially aligned with each other.

Note that one of the conductor 205 and the conductor 260 can function as a gate electrode and the other can function as a back gate electrode. The gate electrode and the back gate electrode are placed with the channel formation region in the semiconductor positioned therebetween. The potential of the back gate electrode may be the same as the potential of the gate electrode or may be a ground potential or a given potential. Furthermore, by changing the potential of the back gate electrode independently of that of the gate electrode, the threshold voltage of the transistor can be changed.

The conductor 260a is preferably an oxide having conductivity. For example, among In—Ga—Zn-based oxides that can be used as the oxide 230, an oxide having high conductivity and a metal atomic ratio of [In]:[Ga]:[Zn]=4:2:3 to 4.1 or in the vicinity thereof is preferably used.

The conductor 260b is preferably a conductor that can add impurities such as nitrogen to the conductor 260a to increase the conductivity of the conductor 260a. In the case where an In—Ga—Zn-based oxide is used as the conductor 260a, for example, titanium nitride or the like is preferably used as the conductor 260b. Furthermore, for example, tungsten having low conductivity is preferably used as the conductor 260c.

Furthermore, the layer 270 is formed over the conductor 260. Here, for the layer 270, a material that is less likely to transmit oxygen is preferably used, and for example, aluminum oxide can be used. This can prevent the consumption of surrounding excess oxygen by the oxidation of the conductor 260. As described above, the layer 270 has a function as a gate cap for protecting the gate. The layer 270 and the oxide 230c extend beyond end portions of the conductor 260 and have regions where they overlap and are in contact with each other in the extending portions, and end portions of the layer 270 are substantially aligned with end portions of the oxide 230c.

The insulator 272 is provided to cover the oxide 230, the conductor 240, the layer 245, the insulator 250, the conductor 260, and the layer 270. Moreover, the insulator 272 is provided in contact with side surfaces of the oxide 230b and the top surface of the insulator 224. Moreover, the insulator 274 is provided over the insulator 272.

Here, as the insulator 272, an oxide insulator deposited by a sputtering method is preferably used, and for example, aluminum oxide is preferably used. With the use of such an insulator 272, oxygen can be added to surfaces of the insulator 224 and the oxide 230b that are in contact with the insulator 272, so that an oxygen excess state can be created.

Furthermore, the insulator 272 preferably has a property of gettering hydrogen in the oxide 230 and the insulator 224 when being subjected to heat treatment, and for example, aluminum oxide is preferably used. As a result, the amount of impurities such as water or hydrogen in the insulator 224 and the oxide 230b can be reduced.

Furthermore, for the insulator 272 and the insulator 274, an insulating material that is less likely to transmit impurities such as water or hydrogen is preferably used, and for example, aluminum oxide is preferably used. With the use of such an insulator 272, impurities such as hydrogen or water can be inhibited from diffusing from a layer over the insulator 274 into a layer under the insulator 272.

Moreover, as the insulator 274, an oxide insulator deposited by an ALD method is preferably used, and for example, aluminum oxide is preferably used. The insulator 274 deposited by an ALD method has good coverage, and is a film in which formation of cracks, pinholes, and the like is suppressed. Although the insulator 272 and the insulator 274 are provided over a shape having unevenness, the use of the insulator 274 deposited by an ALD method enables the transistor 200 to be covered with the insulator 274 without formation of breaks, cracks, pinholes, or the like. Accordingly, even when a break or the like occurs in the insulator 272, it can be covered with the insulator 274; thus, the barrier property of a stacked film of the insulator 272 and the insulator 274 against impurities such as hydrogen or water can be improved noticeably.

Furthermore, in the case where the insulator 272 is deposited by a sputtering method and the insulator 274 is deposited by an ALD method, the ratio of the thickness of a portion over a top surface of a region of the conductor 260c overlapping with the conductor 240, which serves as a film formation surface, (hereinafter, referred to as a first thickness) to the thickness of a portion over the side surfaces of the oxide 230a, the oxide 230b, and the conductor 240, which serves as a film formation surface, (hereinafter, referred to as a second thickness) might be different between the insulator 272 and the insulator 274. In the insulator 272, the first thickness can be approximately the same as the second thickness. By contrast, in the insulator 274, the first thickness is greater than the second thickness in many cases; for example, the first thickness is approximately twice as large as the second thickness in some cases.

Furthermore, for the insulator 272 and the insulator 274, an insulating material that is less likely to transmit oxygen is preferably used. This can suppress upward diffusion of oxygen contained in the insulator 224, the insulator 250, or the like.

As described above, when a structure is employed in which the transistor 200 is sandwiched between the insulators 274 and 272 and the insulators 214 and 212, a large amount of oxygen can be contained in the insulator 224, the oxide 230, and the insulator 250 without outward diffusion of oxygen. Moreover, impurities such as hydrogen or water can be prevented from entering from over the insulator 274 and from under the insulator 212; thus, the impurity concentrations in the insulator 224, the oxide 230, and the insulator 250 can be lowered.

In this manner, the amount of oxygen vacancies in the oxide 230b functioning as an active layer of the transistor 200 is reduced and the amount of impurities such as hydrogen or water is reduced, so that the electrical characteristics of the transistor 200 can be stabilized and the reliability thereof can be improved.

An insulator 280 is provided over the insulator 274. As in the insulator 224 or the like, the concentration of impurities such as water or hydrogen in the film of the insulator 280 is preferably lowered.

Moreover, an insulator 282 is provided over the insulator 280, and an insulator 284 is provided over the insulator 282. For the insulator 282 and the insulator 284, an insulating material that is less likely to transmit impurities such as water or hydrogen and oxygen, for example, aluminum oxide is preferably used, as in the case of the insulator 272 and the insulator 274.

Like the insulator 272, the insulator 282 preferably has a property of gettering hydrogen in the insulator 280 when being subjected to heat treatment, and for example, aluminum oxide is preferably used. When such an insulator 282 is provided, the concentration of impurities such as water or hydrogen in the film of the insulator 280 can be lowered.

Furthermore, for the insulator 284, an oxide insulator deposited by an ALD method is preferably used, as in the case of the insulator 274, and for example, aluminum oxide is preferably used. With the use of such an insulator 274, impurities such as hydrogen or water can be inhibited from diffusing from a layer over the insulator 284 into a layer under the insulator 282.

Here, in the insulator 216, the insulator 220, the insulator 222, the insulator 224, the insulator 272, the insulator 274, and the insulator 280, an opening 480 reaching the insulator 214 is formed. The insulator 282 is deposited also inside the opening 480 and in contact with the top surface of the insulator 214. Note that although only part of the opening 480 extending in the W1-W2 direction is shown in FIG. 1(A), the opening 480 is formed to surround the transistor 200 and the transistor 400 and the opening 480 is formed to surround at least the outer side of the oxide 230. Furthermore, it is preferable that the opening 480 be closed so that a region inside the opening 480 and a region outside the opening 480 are separated. In the opening 480, the top surface of the insulator 214 is in contact with a bottom surface of the insulator 282, that is, a region surrounded by the opening 480 can be regarded as a region surrounded by the insulator 214 and the insulator 282.

With such a structure, the transistor 200 can be surrounded and sealed with the insulator 282 and the insulator 284 in not only a perpendicular direction but also a lateral direction of the substrate. Accordingly, impurities such as water or hydrogen can be prevented from diffusing from the outside of the insulator 284 into the transistor 200 and the transistor 400. Moreover, the insulator 282 can be deposited without a break or the like even in the opening 480 when deposited by an ALD method. Accordingly, even the insulator 282 in which a break or the like occurs can be covered with the insulator 284; therefore, the barrier property of a stacked film of the insulator 282 and the insulator 284 against impurities can be improved.

Furthermore, the opening 480 is preferably provided inside dicing lines or scribe lines along which the semiconductor device 1000 is cut out. In that case, even when the semiconductor device 1000 is cut out, side surfaces of the insulator 280, the insulator 224, the insulator 216, and the like remain sealed with the insulator 282 and the insulator 284; therefore, impurities such as hydrogen or water can be prevented from infiltrating and diffusing from these insulators into the transistor 200 and the transistor 400. Note that a structure may be employed in which a plurality of regions surrounded by the opening 480 are provided inside the dicing lines or the scribe lines and a plurality of semiconductor devices are separately sealed with the insulator 282 and the insulator 284.

### [Transistor 400]

As shown in FIG. 1(A), FIG. 1(B), and FIG. 1(E), the transistor 400 includes the insulator 212 provided over the insulator 210; the insulator 214 provided over the insulator 212; a conductor 403 (a conductor 403a and a conductor 403b), a conductor 405 (a conductor 405a and a conductor 405b), and a conductor 407 (a conductor 407a and a conductor 407b) that are provided over the insulator 214; the insulator 220, the insulator 222, and the insulator 224 that are provided over the conductor 403, the conductor 405, and the conductor 407; an oxide 430 provided over the insulator 224, the conductor 405, and the conductor 407; an insulator 450 provided over the oxide 430; a conductor 460 (a conductor 460a, a conductor 460b, and a conductor 460c) provided over the insulator 450; a layer 470 provided over the conductor 460c; the insulator 272 provided over the layer 470; and the insulator 274 provided over the insulator 272. Hereinafter, description of the components already made for the transistor 200 is omitted.

The conductor 403, the conductor 405, and the conductor 407 are provided in the openings in the insulator 216. The conductor 403, the conductor 405, and the conductor 407 preferably have a structure similar to that of the conductor 205. The conductor 403a is formed in contact with the inside of the opening in the insulator 216, and the conductor 403b is formed on the inner side. The conductor 405 and the conductor 407 also have a structure similar to that of the conductor 403. One of the conductor 405 and the conductor 407 can function as one of a source conductor and a drain conductor, and the other can function as the other of the source conductor and the drain conductor.

The oxide 430 preferably has a structure similar to that of the oxide 230c. Furthermore, the oxide 430 includes a first region, a second region, and a third region. In the top view, the third region is sandwiched between the first region and the second region. The transistor 400 includes the conductor 405 under the first region of the oxide 430 and the conductor 407 under the second region of the oxide 430. Thus, one of the first region and the second region of the oxide 430 can function as a source region and the other can function as a drain region. Furthermore, the third region of the oxide 430 can function as a channel formation region.

Note that although a channel is formed in the oxide 230b in the transistor 200, a channel is formed in the oxide 430 in the transistor 400. For the oxide 230b and the oxide 430, semiconductor materials having different electrical characteristics are preferably used. When semiconductor materials having different electrical characteristics are used for the oxide 230b and the oxide 430, electrical characteristics of the transistor 200 and the transistor 400 can be different from each other.

Furthermore, for example, when a semiconductor having lower electron affinity than the oxide 230b is used for the oxide 430, the threshold voltage of the transistor 400 can be higher than that of the transistor 200. Specifically, when each of the oxide 430 and the oxide 230b is an In-M-Zn oxide (an oxide containing In, an element M, and Zn) and In:M:Zn=x₁:y₁:z₁ [atomic ratio] holds for the oxide 430 and In:M:Zn=x₂:y₂:z₂ [atomic ratio] holds for the oxide 230b, the oxide 430 and the oxide 230b in which y₁/x₁ is larger than y₂/x₂ are used. The oxide 230b is preferably deposited using a target having an atomic ratio of In:M:Zn=1:1:1, In:M:Zn=1:1:1.2, In:M:Zn=2:1:1.5, In:M:Zn=2:1:2.3, In:M:Zn=2:1:3, In:M:Zn=3:1:2, In:M:Zn=4:2:4.1, In:M:Zn=4:2:3, In:M:Zn=5:1:7, or the like. Furthermore, the oxide 430 is preferably deposited using a target having an atomic ratio of In:M:Zn=1:2:4, In:M:Zn=1:3:2, In:M:Zn=1:3:4, In:M:Zn=1:3:6, In:M:Zn=1:3:8, In:M:Zn=1:4:3, In:M:Zn=1:4:4, In:M:Zn=1:4:5, In:M:Zn=1:4:6, In:M:Zn=1:6:3, In:M:Zn=1:6:4, In:M:Zn=1:6:5, In:M:Zn=1:6:6, In:M:Zn=1:6:7, In:M:Zn=1:6:8, In:M:Zn=1:6:9, In:M:Zn=1:10:1, or the like. Note that not limited to the above, the atomic ratios of the oxide 430 and the oxide 230b can be set as appropriate within the range satisfying the above formula. With the use of such In-M-Zn oxides, Vth of the transistor 400 can be higher than that of the transistor 200.

Furthermore, since a region of the oxide 230 where a channel is formed is in direct contact with the insulator 224 and the insulator 450, the transistor 400 is likely to be affected by interface scattering and the trap states. Thus, the field-effect mobility and the carrier density of the transistor 400 can be lowered. Furthermore, the threshold voltage of the transistor 400 can be higher than that of the transistor 200.

The oxide 430 preferably contains a large amount of excess oxygen, and for example, an oxide deposited under an oxygen atmosphere is preferably used. With the use of such an oxide 430 for an active layer, the threshold voltage of the transistor 400 can be higher than 0 V, the off-state current can be reduced, and Icut can be significantly small.

The insulator 450 preferably has a structure similar to that of the insulator 250 and can function as a gate insulating film. When such an insulator 450 is provided in contact with the oxide 430, oxygen can be supplied to the oxide 430 effectively. Furthermore, as in the insulator 224, the concentration of impurities such as water or hydrogen in the insulator 450 is preferably lowered.

The conductor 460 preferably has a structure similar to that of the conductor 260. The conductor 460a is included over the insulator 450, the conductor 460b is included over the conductor 460a, and the conductor 460c is included over the conductor 460b. The insulator 450 and the conductor 460 each have a region overlapping with the third region. Furthermore, end portions of the insulator 450, the conductor 460a, the conductor 460b, and the conductor 460c are substantially aligned with each other. Note that one of the conductor 403 and the conductor 460 can function as a gate electrode and the other can function as a back gate electrode.

The layer 470 preferably has a structure similar to that of the layer 270. The layer 470 is formed over the conductor 460. This can prevent the consumption of surrounding excess oxygen by the oxidation of the conductor 460. The layer 470 and the oxide 430 extend beyond end portions of the conductor 460 and have regions where they overlap and are in contact with each other in the extending portions, and end portions of the layer 470 and the oxide 430 are substantially aligned with each other.

When the transistor 400 is sandwiched between the insulators 274 and 272 and the insulators 214 and 212 as in the case of the transistor 200, a large amount of oxygen can be contained in the insulator 224, the oxide 430, and the insulator 450 without outward diffusion of oxygen. Moreover, impurities such as hydrogen or water can be prevented from entering from over the insulator 274 and from under the insulator 212; thus, the impurity concentrations in the insulator 224, the oxide 230, and the insulator 250 can be lowered.

In this manner, the amount of oxygen vacancies in the oxide 430 functioning as the active layer of the transistor 400 is reduced and the amount of impurities such as hydrogen or water is reduced, so that the threshold voltage of the transistor 400 can be higher than 0 V, the off-state current can be reduced, and Icut can be significantly small. Moreover, the electrical characteristics of the transistor 400 can be stabilized, and the reliability thereof can be improved.

With the structure in which the transistor 400 is used as a switching element so that the potential of the back gate of the transistor 200 can be retained, the off state of the transistor 200 can be maintained for a long time.

### <Materials>

### [Insulator]

For the insulator 210, the insulator 216, the insulator 220, the insulator 224, the insulator 250, the insulator 450, and the insulator 280, for example, a single layer or a stack of layers of an insulating material containing boron, carbon, nitrogen, oxygen, fluorine, magnesium, aluminum, silicon, phosphorus, argon, gallium, germanium, yttrium, zirconium, lanthanum, neodymium, hafnium, or tantalum is used. For example, a single layer or a stack of layers of a material selected from silicon oxide, silicon oxynitride, silicon nitride oxide, silicon nitride, aluminum nitride, aluminum oxide, aluminum nitride oxide, aluminum oxynitride, magnesium oxide, gallium oxide, germanium oxide, yttrium oxide, zirconium oxide, lanthanum oxide, neodymium oxide, hafnium oxide, tantalum oxide, aluminum silicate, and the like is used. Furthermore, a material in which more than one of materials selected from an oxide material, a nitride material, an oxynitride material, and a nitride oxide material are mixed may be used.

Note that in this specification, a nitride oxide refers to a compound that contains more nitrogen than oxygen. Furthermore, an oxynitride refers to a compound that contains more oxygen than nitrogen. Note that the content of each element can be measured by Rutherford backscattering spectrometry (RBS: Rutherford Backscattering Spectrometry), for example.

The insulator 212, the insulator 214, the insulator 222, the insulator 272, the insulator 274, the insulator 282, and the insulator 284 are preferably formed using an insulating material that is less likely to transmit impurities such as water or hydrogen than the insulator 224, the insulator 250, the insulator 450, and the insulator 280. Examples of an insulating material that is less likely to transmit impurities include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride. A single layer or a stack thereof is used.

When an insulating material that is less likely to transmit impurities is used for the insulator 212, the insulator 214, and the insulator 222, impurity diffusion from the substrate side into the transistor can be inhibited, and the reliability of the transistor can be improved. When an insulating material that is less likely to transmit impurities is used for the insulator 272, the insulator 274, the insulator 282, and the insulator 284, impurity diffusion from a layer over the insulator 280 into the transistor can be inhibited, and the reliability of the transistor can be improved.

Note that a stack of a plurality of insulating layers formed of these materials may be used as each of the insulator 212, the insulator 214, the insulator 272, the insulator 282, and the insulator 284. Furthermore, one of the insulator 212 and the insulator 214 may be omitted. Furthermore, one of the insulator 282 and the insulator 284 may be omitted.

Here, an insulating material that is less likely to transmit impurities has high oxidation resistance and a function of inhibiting the diffusion of oxygen and impurities typified by hydrogen or water.

For example, compared with silicon oxide, aluminum oxide has an extremely small diffusion length of oxygen or hydrogen per hour in an insulating material that is less likely to transmit impurities under an atmosphere at 350° C. or 400° C. Thus, it can be said that aluminum oxide is a material that is less likely to transmit impurities.

Furthermore, as an example of an insulating material that is less likely to transmit impurities, silicon nitride formed by a CVD method can be used. Here, diffusion of hydrogen into a semiconductor element including an oxide semiconductor, such as the transistor 200, degrades the characteristics of the semiconductor element in some cases. Thus, the transistor 200 is preferably sealed with a film that inhibits hydrogen diffusion. The film that inhibits hydrogen diffusion is specifically a film from which a small amount of hydrogen is released.

The released amount of hydrogen can be analyzed by TDS, for example. The released amount of hydrogen from the insulator 212 that is converted into hydrogen molecules per unit area of the insulator 212 is less than or equal to 2×10¹⁵ molecules/cm², preferably less than or equal to 1×10¹⁵ molecules/cm², and further preferably less than or equal to 5×10¹⁴ molecules/cm² in TDS in the range from 50° C. to 500° C., for example.

Furthermore, in particular, the dielectric constant of the insulator 216, the insulator 224, and the insulator 280 is preferably low. For example, the relative dielectric constant of the insulator 216, the insulator 224, and the insulator 280 is preferably lower than 3, further preferably lower than 2.4, and still further preferably lower than 1.8. When a material with a low dielectric constant is used for an interlayer film, the parasitic capacitance generated between wirings can be reduced. An insulating material that is less likely to transmit impurities is preferably used for formation.

Furthermore, when an oxide semiconductor is used for the oxide 230, the hydrogen concentration in the insulator is preferably lowered in order to prevent an increase in the hydrogen concentration in the oxide 230. Specifically, the hydrogen concentration in the insulator is lower than or equal to 2×10²⁰ atoms/cm³, preferably lower than or equal to 5×10¹⁹ atoms/cm³, further preferably lower than or equal to 1×10¹⁹ atoms/cm³, and still further preferably lower than or equal to 5×10¹⁸ atoms/cm³ in SIMS. It is particularly preferable to lower the hydrogen concentrations in the insulator 216, the insulator 224, the insulator 250, the insulator 450, and the insulator 280. It is preferable to lower the hydrogen concentrations in at least the insulator 224, the insulator 250, and the insulator 450 that are in contact with the oxide 230 or the oxide 430.

Furthermore, the nitrogen concentration in the insulator is preferably lowered in order to prevent an increase in the nitrogen concentration in the oxide 230. Specifically, the nitrogen concentration in the insulator is lower than or equal to 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³ in SIMS.

Furthermore, it is preferable that a region of the insulator 224 that is in contact with at least the oxide 230 and a region of the insulator 250 that is in contact with at least the oxide 230 have few defects and typically have as few signals observed by electron spin resonance spectroscopy (ESR: Electron Spin Resonance) as possible. Examples of the signals include an E′ center observed at a g-factor of 2.001. Note that the E′ center is due to the dangling bond of silicon. In the case where a silicon oxide layer or a silicon oxynitride layer is used as the insulator 224 and the insulator 250, a silicon oxide layer or a silicon oxynitride layer whose spin density due to the E′ center is lower than or equal to 3×10¹⁷ spins/cm³, and preferably lower than or equal to 5×10¹⁶ spins/cm³ is used.

Furthermore, in addition to the above-described signal, a signal due to nitrogen dioxide (NO₂) might be observed. The signal is divided into the following three signals according to the N nuclear spin: a signal observed at a g-factor of greater than or equal to 2.037 and less than or equal to 2.039 (first signal), a signal observed at a g-factor of greater than or equal to 2.001 and less than or equal to 2.003 (second signal), and a signal observed at a g-factor of greater than or equal to 1.964 and less than or equal to 1.966 (third signal).

It is suitable to use an insulating layer whose spin density due to nitrogen dioxide (NO₂) is higher than or equal to 1×10¹⁷ spins/cm³ and lower than 1×10¹⁸ spins/cm³ as the insulator 224 and the insulator 250, for example.

Note that a nitrogen oxide (NOₓ) containing nitrogen dioxide (NO₂) forms a state in the insulating layer. The state is positioned in the energy gap of the oxide semiconductor. Thus, when a nitrogen oxide (NOₓ) diffuses to the interface between the insulating layer and the oxide semiconductor, an electron can potentially be trapped by the state on the insulating layer side. As a result, the trapped electron remains in the vicinity of the interface between the insulating layer and the oxide semiconductor; thus, the threshold voltage of the transistor is shifted in the positive direction. Accordingly, a film with a low nitrogen oxide content is used as the insulator 224 and the insulator 250, so that a shift in the threshold voltage of the transistor can be reduced.

As an insulating layer that releases a small amount of nitrogen oxide (NOₓ), for example, a silicon oxynitride layer can be used. The silicon oxynitride layer is a film of which the released amount of ammonia is larger than the released amount of nitrogen oxide (NOₓ) in TDS; the released amount of ammonia is typically greater than or equal to 1×10¹⁸/cm³ and less than or equal to 5×10¹⁹/cm³. Note that the released amount of ammonia is the total amount in the range of the heat treatment temperature in TDS from 50° C. to 650° C. or from 50° C. to 550° C.

Since a nitrogen oxide (NOₓ) reacts with ammonia and oxygen in heat treatment, the use of an insulating layer that releases a large amount of ammonia reduces a nitrogen oxide (NOₓ).

Furthermore, at least one of the insulator 216, the insulator 224, the insulator 250, and the insulator 450 is preferably formed using an insulator from which oxygen is released by heating. Specifically, it is preferable to use an insulator in which the released amount of oxygen that is converted into oxygen atoms is 1.0×10¹⁸ atoms/cm³ or more, and preferably 3.0×10²⁰ atoms/cm³ or more in TDS.

Furthermore, the insulating layer containing excess oxygen can also be formed by performing treatment for adding oxygen to an insulating layer. The treatment for adding oxygen can be performed by heat treatment under an oxygen atmosphere, an ion implantation method, an ion doping method, a plasma immersion ion implantation method, plasma treatment, or the like. Furthermore, for the plasma treatment with oxygen, an apparatus including a power source for generating high-density plasma using microwaves is preferably used, for example. Alternatively, a power source for applying an RF (Radio Frequency) to a substrate side may be included. The use of high-density plasma enables high-density oxygen radicals to be produced, and RF application to the substrate side allows the oxygen radicals generated by the high-density plasma to be efficiently introduced into a target film. Alternatively, after plasma treatment with an inert gas is performed with this apparatus, plasma treatment with oxygen may be performed to compensate for released oxygen. Note that as a gas for adding oxygen, an oxygen gas of ¹⁶O₂, ¹⁸O₂, or the like, a nitrous oxide gas, an ozone gas, or the like can be used. Note that in this specification, the treatment for adding oxygen is also referred to as “oxygen doping treatment”.

Furthermore, by oxygen doping treatment, the crystallinity of the semiconductor can be increased, and impurities such as hydrogen or water can be removed, in some cases. That is, “oxygen doping treatment” can also be referred to as “impurity removal treatment”. In particular, when plasma treatment with oxygen under a reduced pressure is performed as oxygen doping treatment, bonds involving hydrogen and water in a target insulator or oxide are cut, which makes it easy for hydrogen and water to be released. Thus, it is preferable that plasma treatment be performed while heating is performed or heat treatment be performed after plasma treatment. Furthermore, when plasma treatment is performed after heat treatment and heat treatment is further performed, the impurity concentration in a target film can be reduced.

There is no particular limitation on the method for forming the insulator, and any of a sputtering method, an SOG method, spin coating, dipping, spray coating, a droplet discharging method (e.g., an inkjet method), a printing method (e.g., screen printing or offset printing), and the like is used depending on the material.

Furthermore, any of the above insulating layers may be used as the layer 245a, the layer 245b, the layer 270, and the layer 470. In the case where an insulating layer is used as the layer 245a, the layer 245b, and the layer 270, an insulating layer that is less likely to release and/or absorb oxygen is preferably used.

### [Oxide]

The oxide 230 and the oxide 430 of the present invention will be described below.

The oxides preferably contain at least indium or zinc. In particular, indium and zinc are preferably contained. Furthermore, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxides are each InMZnO containing indium, an element M, and zinc is considered. Note that the element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, and magnesium. Note that a plurality of the above-described elements may be combined as the element M.

### <Structure>

An oxide is classified into a single crystal oxide and the other, a non-single-crystal oxide. Examples of a non-single-crystal oxide include a CAAC-OS (c-axis aligned crystalline oxide semiconductor), a polycrystalline oxide, an nc-OS (nanocrystalline oxide semiconductor), an amorphous-like oxide (a-like OS: amorphous-like oxide semiconductor), and an amorphous oxide.

The CAAC-OS has c-axis alignment, a plurality of nanocrystals are connected in the a-b plane direction, and the crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal lattice arrangement, a heptagonal lattice arrangement, and the like are included in the distortion in some cases. Note that a clear crystal grain boundary (also referred to as grain boundary) cannot be observed even in the vicinity of distortion in the CAAC-OS. That is, formation of a crystal grain boundary is inhibited by the distortion of a lattice arrangement. This is probably because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation of the whole film is not observed. Accordingly, in some cases, the nc-OS cannot be distinguished from an a-like OS or an amorphous oxide, depending on an analysis method.

The a-like OS is an oxide having a structure between those of the nc-OS and the amorphous oxide. The a-like OS contains a void or a low-density region. That is, the a-like OS has low crystallinity as compared with the nc-OS and the CAAC-OS.

An oxide has various structures with different properties. Two or more of the amorphous oxide, the polycrystalline oxide, the a-like OS, the nc-OS, and the CAAC-OS may be included in an oxide of one embodiment of the present invention.

### <Atomic Ratio>

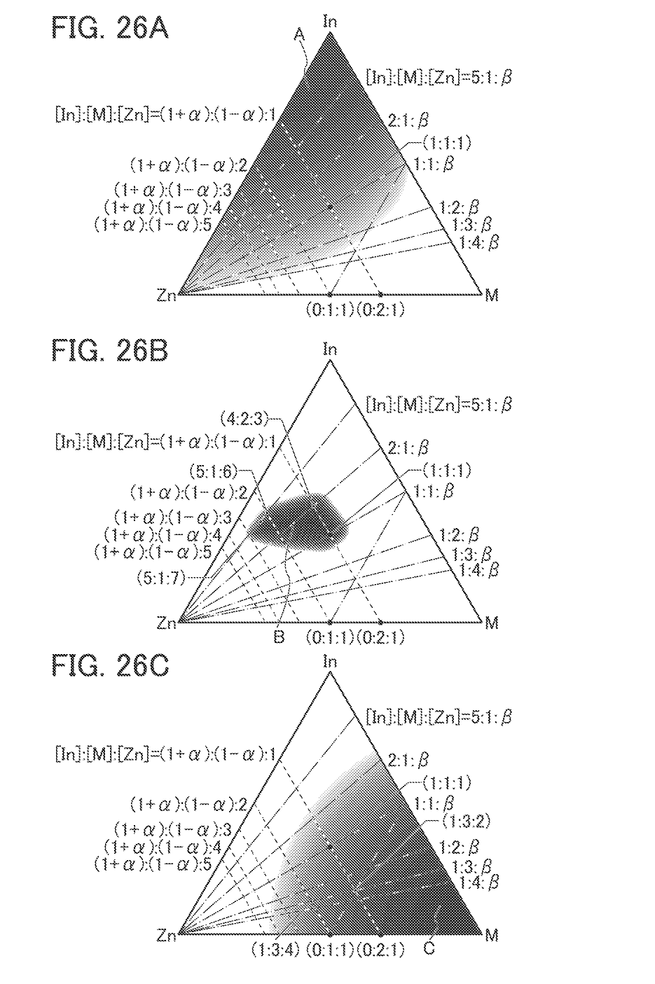

Next, preferred ranges of the atomic ratio of indium, the element M, and zinc contained in the oxide of the present invention will be described with reference to FIG. 26(A), FIG. 26(B), and FIG. 26(C). Note that the atomic ratio of oxygen is not shown in FIG. 26(A), FIG. 26(B), and FIG. 26(C). Furthermore, the terms of the atomic ratio of indium, the element M, and zinc contained in the oxide are denoted by [In], [M], and [Zn], respectively.

In FIG. 26(A), FIG. 26(B), and FIG. 26(C), broken lines indicate a line representing the atomic ratio of [In]:[M]:[Zn]=(1+α):(1−α):1 (−1≤α≤1), a line representing the atomic ratio of [In]:[M]:[Zn]=(1+α):(1−α):2, a line representing the atomic ratio of [In]:[M]:[Zn]=(1+α):(1−α):3, a line representing the atomic ratio of [In]:[M]:[Zn]=(1+α):(1−α):4, and a line representing the atomic ratio of [In]:[M]:[Zn]=(1+α):(1−α):5.

Furthermore, dashed-dotted lines indicate a line representing the atomic ratio of [In]:[M]:[Zn]=5:1:β (β≥0), a line representing the atomic ratio of [In]:[M]:[Zn]=2:1:β, a line representing the atomic ratio of [In]:[M]:[Zn]=1:1:β, a line representing the atomic ratio of [In]:[M]:[Zn]=1:2:β, a line representing the atomic ratio of [In]:[M]:[Zn]=1:3:β, and a line representing the atomic ratio of [In]:[M]:[Zn]=1:4:β.

Furthermore, a dashed double-dotted line indicates a line representing the atomic ratio of [In]:[M]:[Zn]=(1+y):2:(1−γ) (−1≤γ≤1). Furthermore, an oxide with an atomic ratio of [In]:[M]:[Zn]=0:2:1 and a value in the vicinity thereof shown in FIG. 26(A), FIG. 26(B), and FIG. 26(C) tends to have a spinel crystal structure.

Furthermore, a plurality of phases (e.g., two phases or three phases) coexist in the oxide in some cases. For example, with an atomic ratio having a value in the vicinity of [In]:[M]:[Zn]=0:2:1, two phases of a spinel crystal structure and a layered crystal structure are likely to coexist. Furthermore, with an atomic ratio having a value in the vicinity of [In]:[M]:[Zn]=1:0:0, two phases of a bixbyite crystal structure and a layered crystal structure are likely to coexist. In the case where a plurality of phases coexist in the oxide, a crystal grain boundary might be formed between different crystal structures.

A region A shown in FIG. 26(A) shows an example of the preferred range of the atomic ratio of indium, the element M, and zinc contained in an oxide.

When the indium content in an oxide is increased, carrier mobility (electron mobility) of the oxide can be increased. That is, an oxide having a high indium content has higher carrier mobility than an oxide having a low indium content.

By contrast, when the indium and zinc contents in an oxide become lower, carrier mobility becomes lower. Thus, with an atomic ratio of [In]:[M]:[Zn]=0:1:0 and a value in the vicinity thereof (e.g., a region C shown in FIG. 26(C)), insulation performance becomes better.

Accordingly, an oxide of one embodiment of the present invention preferably has an atomic ratio represented by the region A in FIG. 26(A), with which a layered structure with high carrier mobility and a few crystal grain boundaries is easily obtained.

In the region A, particularly in a region B shown in FIG. 26(B), an excellent oxide that easily becomes a CAAC-OS and has high carrier mobility can be obtained.

The CAAC-OS is an oxide with high crystallinity. On the other hand, a clear crystal grain boundary cannot be observed in the CAAC-OS; thus, a reduction in electron mobility due to the crystal grain boundary is less likely to occur. Furthermore, entry of impurities, formation of defects, or the like might decrease the crystallinity of an oxide, which means that the CAAC-OS is an oxide having small amounts of impurities and defects (e.g., oxygen vacancies). Thus, an oxide including a CAAC-OS is physically stable. Therefore, the oxide including a CAAC-OS is resistant to heat and has high reliability.

Note that the region B includes values of [In]:[M]:[Zn]=4:2:3 to 4.1 and in the vicinity thereof. The values in the vicinity include an atomic ratio of [In]:[M]:[Zn]=5:3:4, for example. Furthermore, the region B includes a value of [In]:[M]:[Zn]=5:1:6 and in the vicinity thereof and a value of [In]:[M]:[Zn]=5:1:7 and in the vicinity thereof.

Note that the properties of an oxide are not uniquely determined by an atomic ratio. Even with the same atomic ratio, the properties of an oxide might be different depending on a formation condition. For example, in the case where the oxide is deposited with a sputtering apparatus, a film having an atomic ratio deviated from the atomic ratio of a target is formed. Furthermore, [Zn] in the film might be smaller than [Zn] in the target, depending on the substrate temperature in the film deposition. Thus, the illustrated regions are each a region representing an atomic ratio with which an oxide tends to have specific properties, and boundaries of the region A to the region C are not clear.

### [Transistor Including Oxide]

Next, the case where the oxide is used for a transistor will be described.

Note that when the oxide is used for a transistor, carrier scattering or the like at a crystal grain boundary can be reduced; thus, the transistor having high field-effect mobility can be obtained. Furthermore, the transistor having high reliability can be obtained.

Furthermore, an oxide with a low carrier density is preferably used for the transistor. In the case where the carrier density of an oxide semiconductor film is reduced, the impurity concentration in the oxide semiconductor film is reduced to reduce the density of defect states. In this specification and the like, a state with a low impurity concentration and a low density of defect states is referred to as a highly purified intrinsic or substantially highly purified intrinsic state. For example, an oxide has a carrier density lower than 8×10¹¹/cm³, preferably lower than 1×10¹¹/cm³, and further preferably lower than 1×10¹⁰/cm³, and higher than or equal to 1×10⁻⁹/cm³.

A highly purified intrinsic or substantially highly purified intrinsic oxide has a low density of defect states and accordingly has a low density of trap states in some cases.

Furthermore, charges trapped by the trap states in the oxide take a long time to disappear and may behave like fixed charges. Thus, a transistor whose channel region is formed in an oxide having a high density of trap states has unstable electrical characteristics in some cases.

Thus, a reduction in the impurity concentration in the oxide is effective in achieving stable electrical characteristics of the transistor. Furthermore, in order to reduce the impurity concentration in the oxide, the impurity concentration in an adjacent film is also preferably reduced. Examples of impurities include hydrogen, nitrogen, an alkali metal, an alkaline earth metal, iron, nickel, and silicon.

### <Impurity>

Here, the influence of impurities in the oxide will be described.

When silicon or carbon, which is one of Group 14 elements, is contained in the oxide, defect states are formed in the oxide. Thus, the concentration of silicon or carbon in the oxide and the concentration of silicon or carbon in the vicinity of an interface with the oxide (the concentration obtained by secondary ion mass spectrometry (SIMS: Secondary Ion Mass Spectrometry)) are set lower than or equal to 2×10¹⁸ atoms/cm³, and preferably lower than or equal to 2×10¹⁷ atoms/cm³.

Furthermore, when the oxide contains an alkali metal or an alkaline earth metal, defect states are formed and carriers are generated, in some cases. Thus, a transistor using an oxide that contains an alkali metal or an alkaline earth metal is likely to have normally-on characteristics. Accordingly, it is preferable to reduce the concentration of an alkali metal or an alkaline earth metal in the oxide. Specifically, the concentration of an alkali metal or an alkaline earth metal in the oxide obtained by SIMS is set lower than or equal to 1×10¹⁸ atoms/cm³, and preferably lower than or equal to 2×10¹⁶ atoms/cm³.

Furthermore, when containing nitrogen, the oxide easily becomes n-type by generation of electrons serving as carriers and an increase in carrier density. As a result, a transistor in which an oxide containing nitrogen is used as a semiconductor is likely to have normally-on characteristics. Thus, the concentration of nitrogen in the oxide is preferably reduced as much as possible; for example, the nitrogen concentration in the oxide is set lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³ in SIMS.

Furthermore, hydrogen contained in an oxide reacts with oxygen bonded to a metal atom to be water, and thus forms an oxygen vacancy, in some cases. Entry of hydrogen into the oxygen vacancy generates an electron serving as a carrier in some cases. Furthermore, in some cases, bonding of part of hydrogen to oxygen bonded to a metal atom generates an electron serving as a carrier. Thus, a transistor using an oxide that contains hydrogen is likely to have normally-on characteristics. Accordingly, the concentration of hydrogen in the oxide is preferably reduced as much as possible. Specifically, the hydrogen concentration in the oxide obtained by SIMS is set lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide with sufficiently reduced impurity concentration is used for a channel region in a transistor, stable electrical characteristics can be given.

### <Band Diagram>

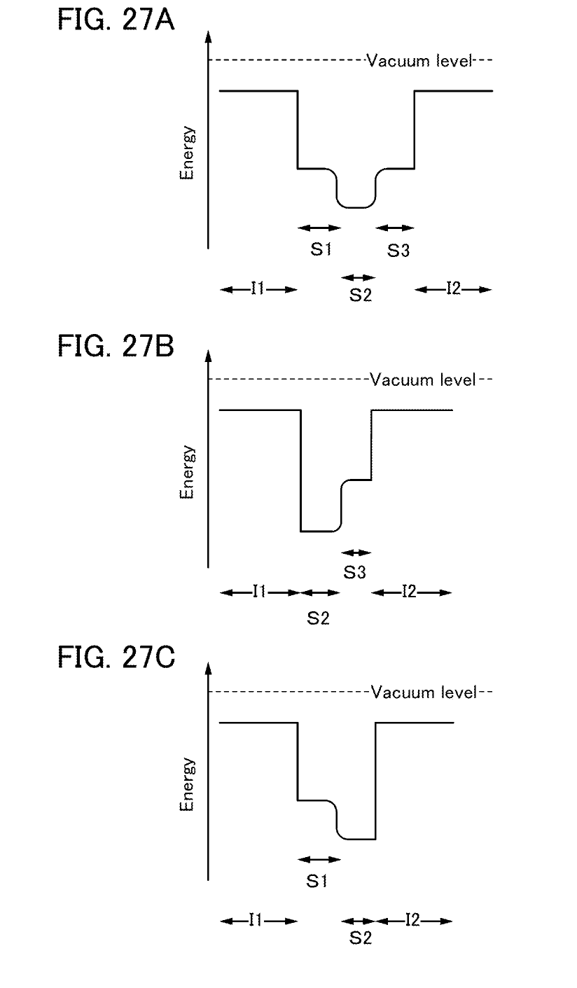

Next, the case where the oxide has a two-layer structure or a three-layer structure will be described. With reference to FIG. 27, the description is made on a band diagram of a stacked-layer structure of an oxide S1, an oxide S2, and an oxide S3 and insulators that are in contact with the stacked-layer structure; a band diagram of a stacked-layer structure of the oxide S2 and the oxide S3 and insulators that are in contact with the stacked-layer structure; and a band diagram of a stacked-layer structure of the oxide S1 and the oxide S2 and insulators that are in contact with the stacked-layer structure.

FIG. 27(A) is an example of a band diagram of a stacked-layer structure including an insulator I1, the oxide S1, the oxide S2, the oxide S3, and an insulator 12 in the thickness direction. Furthermore, FIG. 27(B) is an example of a band diagram of a stacked-layer structure including the insulator I1, the oxide S2, the oxide S3, and the insulator 12 in the thickness direction. Furthermore, FIG. 27(C) is an example of a band diagram of a stacked-layer structure including the insulator I1, the oxide S1, the oxide S2, and the insulator 12 in the thickness direction. Note that for easy understanding, the band diagrams show the energy level of the conduction band minimum (Ec) of each of the insulator I1, the oxide S1, the oxide S2, the oxide S3, and the insulator 12.

The energy level of the conduction band minimum of each of the oxide S1 and the oxide S3 is closer to the vacuum level than that of the oxide S2, and typically, a difference between the energy level of the conduction band minimum of the oxide S2 and the energy level of the conduction band minimum of each of the oxide S1 and the oxide S3 is preferably greater than or equal to 0.15 eV or greater than or equal to 0.5 eV, and less than or equal to 2 eV or less than or equal to 1 eV. That is, a difference between the electron affinity of each of the oxide S1 and the oxide S3 and the electron affinity of the oxide S2 is preferably greater than or equal to 0.15 eV or greater than or equal to 0.5 eV, and less than or equal to 2 eV or less than or equal to 1 eV.

As shown in FIG. 27(A), FIG. 27(B), and FIG. 27(C), the energy level of the conduction band minimum gradually changes in the oxide S1, the oxide S2, and the oxide S3. In other words, it continuously changes or is continuously connected. To obtain such a band diagram, the density of defect states in a mixed layer formed at an interface between the oxide S1 and the oxide S2 or an interface between the oxide S2 and the oxide S3 is preferably made low.

Specifically, when the oxide S1 and the oxide S2 or the oxide S2 and the oxide S3 contain the same element (as a main component) in addition to oxygen, a mixed layer with a low density of defect states can be formed. For example, when the oxide S2 is an In—Ga—Zn oxide, it is preferable to use an In—Ga—Zn oxide, a Ga—Zn oxide, gallium oxide, or the like as the oxide S1 and the oxide S3.

At this time, the oxide S2 serves as a main carrier path. Since the density of defect states at the interface between the oxide S1 and the oxide S2 and the interface between the oxide S2 and the oxide S3 can be made low, the influence of interface scattering on carrier conduction is small, and a large on-state current can be obtained.

When an electron is trapped by a trap state, the trapped electron behaves like a fixed charge; thus, the threshold voltage of a transistor is shifted in the positive direction. When the oxide S1 and the oxide S3 are provided, the trap state can be made apart from the oxide S2.

This structure can prevent the positive shift of the threshold voltage of the transistor.

A material whose conductivity is sufficiently lower than that of the oxide S2 is used for the oxide S1 and the oxide S3. In that case, the oxide S2, the interface between the oxide S2 and the oxide S1, and the interface between the oxide S2 and the oxide S3 mainly function as a channel region. For example, an oxide with high insulation performance and the atomic ratio represented by the region C in FIG. 26(C) can be used as the oxide S1 and the oxide S3. Note that the region C shown in FIG. 26(C) represents the atomic ratios of [In]:[M]:[Zn]=0:1:0 and a value in the vicinity thereof, [In]:[M]:[Zn]=1:3:2 and a value in the vicinity thereof, and [In]:[M]:[Zn]=1:3:4 and a value in the vicinity thereof.

In the case where an oxide with the atomic ratio represented by the region A is used as the oxide S2, an oxide with [M]/[In] of greater than or equal to 1, and preferably greater than or equal to 2 is particularly preferably used as each of the oxide S1 and the oxide S3. Furthermore, an oxide with [M]/([Zn]+[In]) of greater than or equal to 1 to have sufficiently high insulation performance is suitably used as the oxide S3.

Furthermore, in this specification and the like, a transistor in which the oxide is used for a semiconductor where a channel is formed is also referred to as an “OS transistor”. Furthermore, in this specification and the like, a transistor in which silicon having crystallinity is used for a semiconductor where a channel is formed is also referred to as a “crystalline Si transistor”.

The crystalline Si transistor tends to have relatively high mobility as compared to the OS transistor. On the other hand, the crystalline Si transistor has difficulty in obtaining an extremely small off-state current unlike the OS transistor. Thus, it is important that the semiconductor material used for the semiconductor be properly selected depending on the purpose and the usage. For example, depending on the purpose and the usage, the OS transistor and the crystalline Si transistor and the like may be used in combination.

Note that an indium gallium oxide has a low electron affinity and a high oxygen-blocking property. Thus, the oxide 230c preferably contains an indium gallium oxide. The atomic proportion of gallium [Ga/(In+Ga)] is, for example, higher than or equal to 70%, preferably higher than or equal to 80%, and further preferably higher than or equal to 90%.

Note that the oxide 230a and the oxide 230c may be gallium oxide. For example, when gallium oxide is used for the oxide 230c, a leakage current generated between the conductor 205 and the oxide 230 can be reduced. In other words, the off-state current of the transistor 200 can be reduced.

At this time, when a gate voltage is applied, a channel is formed in the oxide 230b having the highest electron affinity among the oxide 230a, the oxide 230b, and the oxide 230c.

In order to impart stable electrical characteristics and high reliability to the transistor using the oxide, it is preferable that the amounts of impurities and oxygen vacancies in the oxide be reduced to perform high purification so that at least the oxide 230b can be regarded as an intrinsic or substantially intrinsic oxide. Furthermore, it is preferable that at least the channel formation region in the oxide 230b be regarded as an intrinsic or substantially intrinsic semiconductor.

Furthermore, the layer 245a, the layer 245b, the layer 270, and the layer 470 may be formed using a material and a method that are similar to those of the oxide 230 or the oxide 430. In the case where an oxide is used for the layer 245a, the layer 245b, the layer 270, and the layer 470, an oxide that is less likely to release or absorb oxygen is preferably used.

### [Conductor]

As a conductive material for forming the conductor 205, the conductor 207, the conductor 403, the conductor 405, the conductor 407, the conductor 240, the conductor 260, and the conductor 460, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, and the like can be used. Furthermore, a semiconductor having high electrical conductivity, typified by polycrystalline silicon including an impurity element such as phosphorus, or silicide such as nickel silicide may be used.

Furthermore, a conductive material containing the above metal element and oxygen may be used. Furthermore, a conductive material containing the above metal element and nitrogen may be used. For example, a conductive material containing nitrogen, such as titanium nitride or tantalum nitride, may be used. Furthermore, indium tin oxide (ITO: Indium Tin Oxide), indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used.

Furthermore, a stack including a plurality of conductive layers formed with the above materials may be used. For example, a stacked-layer structure combining a material containing the above metal element and a conductive material containing oxygen may be employed. Furthermore, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

Note that for the conductor 205b, the conductor 207b, the conductor 403b, the conductor 405b, and the conductor 407b, for example, a conductive material such as tungsten or polysilicon is used. Furthermore, as the conductor 205a, the conductor 207a, the conductor 403a, the conductor 405a, and the conductor 407a, which are in contact with the insulator 212 and the insulator 214, a stacked layer or a single layer of a barrier layer (a diffusion prevention layer) such as a titanium layer, a titanium nitride layer, or a tantalum nitride layer can be used.

The use of an insulating material that is less likely to transmit impurities for the insulator 212 and the insulator 214, and the use of a conductive material that is less likely to transmit impurities for the conductor 205a, the conductor 207a, the conductor 403a, the conductor 405a, and the conductor 407a, which are in contact with the insulator 212 and the insulator 214, can further inhibit diffusion of impurities into the transistor 200 and the transistor 400. Thus, the reliability of the transistor 200 and the transistor 400 can be further increased.

Furthermore, the above conductive material may be used for the layer 245a, the layer 245b, the layer 270, and the layer 470. In the case where a conductive material is used for the layer 245a, the layer 245b, the layer 270, and the layer 470, a conductive material that is less likely to release and/or absorb oxygen is preferably used.

### [Substrate]

Although there is no large limitation on a material used for a substrate, it is necessary that it have heat resistance high enough to withstand at least heat treatment performed later. For example, a single crystal semiconductor substrate or a polycrystalline semiconductor substrate including silicon, silicon carbide, or the like as a material or a compound semiconductor substrate including silicon germanium or the like as a material can be used as the substrate. Furthermore, an SOI substrate, a semiconductor substrate on which a semiconductor element such as a strained transistor or a FIN-type transistor is provided, or the like can be used. Alternatively, gallium arsenide, aluminum gallium arsenide, indium gallium arsenide, gallium nitride, indium phosphide, silicon germanium, or the like that can be used for a high-electron-mobility transistor (HEMT: High Electron Mobility Transistor) may be used. That is, the substrate is not limited to a simple supporting substrate, and may be a substrate where another device such as a transistor is formed. In this case, at least one of the gate, the source, and the drain of the transistor 200 or the transistor 400 may be electrically connected to the other device.

Furthermore, a glass substrate of barium borosilicate glass, aluminoborosilicate glass, or the like, a ceramic substrate, a quartz substrate, a sapphire substrate, or the like can be used as the substrate. Note that a flexible substrate (flexible substrate) may be used as the substrate. In the case where a flexible substrate is used, a transistor, a capacitor, or the like may be directly fabricated over the flexible substrate, or the transistor, the capacitor, or the like may be fabricated over another fabrication substrate and then separated therefrom and transferred onto the flexible substrate. Note that to perform separation from the fabrication substrate and transfer to the flexible substrate, a separation layer is preferably provided between the fabrication substrate and the transistor, the capacitor, or the like.

For the flexible substrate, for example, a metal, an alloy, a resin, glass, or fiber thereof can be used. The flexible substrate used as the substrate preferably has a lower coefficient of linear expansion because deformation due to an environment is suppressed. For the flexible substrate used as the substrate, for example, a material whose coefficient of linear expansion is lower than or equal to 1×10⁻³/K, lower than or equal to 5×10⁻⁵/K, or lower than or equal to 1×10⁻⁵/K is used. Examples of the resin include polyester, polyolefin, polyamide (nylon, aramid, or the like), polyimide, polycarbonate, and acrylic. In particular, aramid is suitable for the flexible substrate because of its low coefficient of linear expansion.

### <Fabrication Method Example of Semiconductor Device 1000>

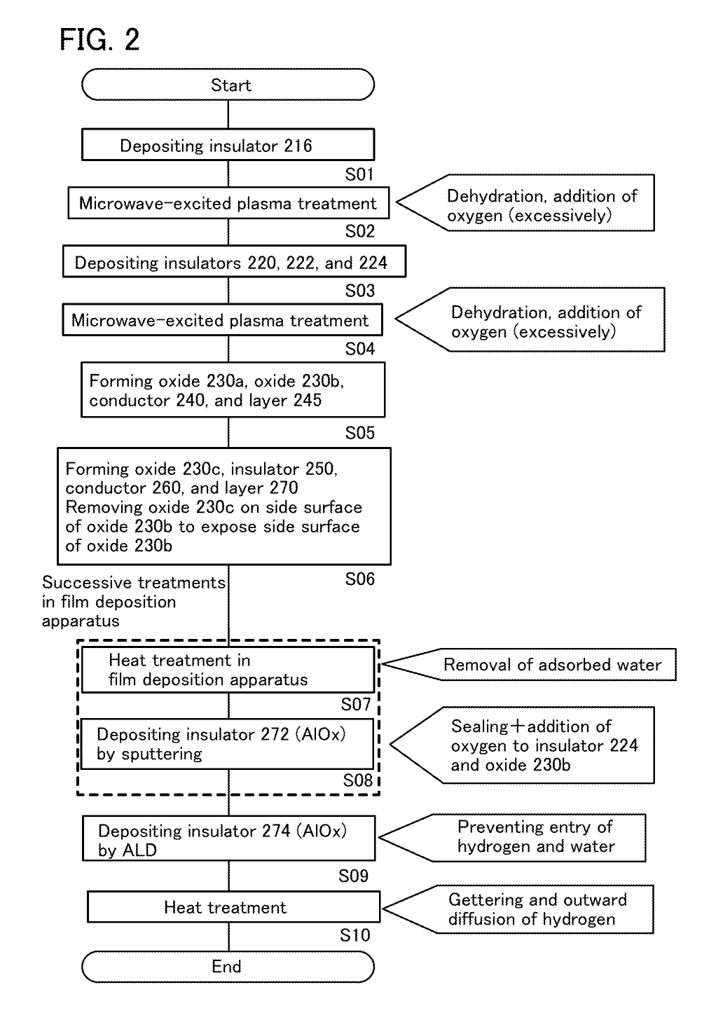

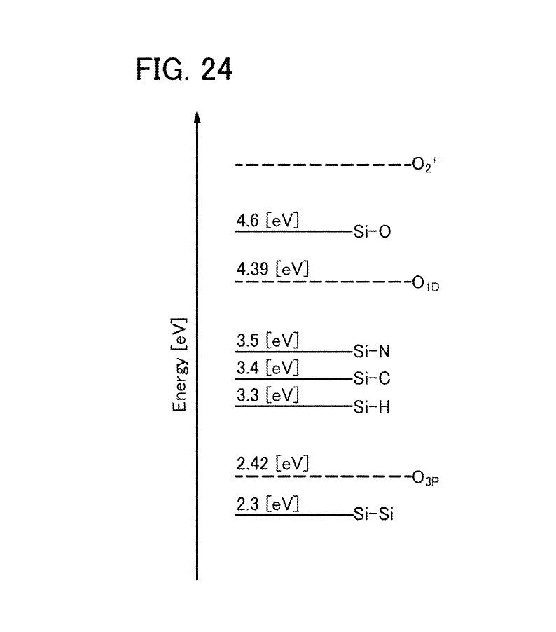

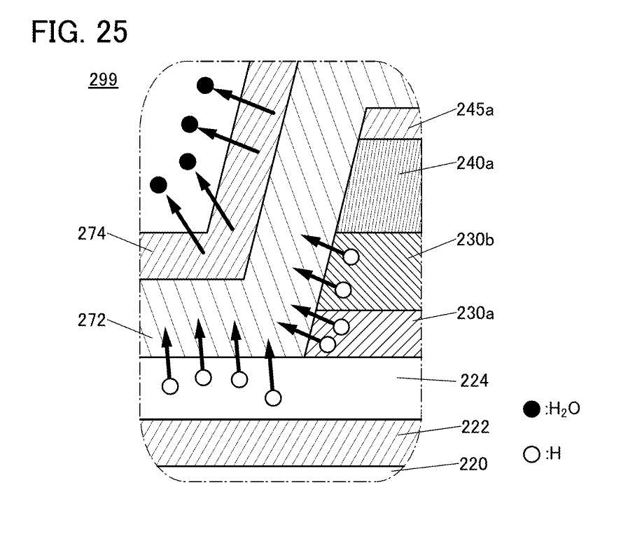

A fabrication method example of a semiconductor device 1000 will be described with reference to FIG. 2 to FIG. 25. Here, FIG. 2 is a flow chart showing part of a fabrication process of the semiconductor device 1000. The flow chart shown in FIG. 2 shows the process (steps) on the left side and shows the effects of the steps on the behavior of impurities such as hydrogen or water and oxygen on the right side. FIG. 24 is a diagram showing energy levels of radicals and ions contained in plasma excited by microwaves. Furthermore, FIG. 25 is a schematic diagram showing a mechanism for reducing hydrogen in an oxide by aluminum oxide.

First, the outline of the formation method of the semiconductor device 1000 will be described with reference to FIG. 2.

As shown in Step S01, the insulator 216 is deposited. Next, as shown in Step S02, microwave-excited plasma treatment is preferably performed on the insulator 216. By performing microwave-excited plasma treatment, water and nitrogen, which are impurities in the insulator 216, can be removed. Moreover, the microwave-excited plasma treatment is performed under a mixed atmosphere of oxygen and a rare gas while an RF bias is applied to a substrate, whereby a region containing excess oxygen can be formed in the insulator 216. Note that as the RF bias becomes higher, a larger amount of excess oxygen can be introduced. By contrast, when the RF bias is too high, a target structure is damaged by plasma in some cases. Thus, the RF bias to be applied is preferably higher than 0 W and lower than or equal to 600 W.

Here, the principle of the microwave-excited plasma treatment on the insulator 216 in the case where silicon oxide is deposited as the insulator 216 will be described with reference to FIG. 24.

In the insulator 216, hydrogen, nitrogen, and carbon are present as impurities. In particular, it is difficult to remove an impurity bonded to a silicon atom by heat treatment because a bond between an impurity atom and the silicon atom needs to be cut. In solid silicon oxide, for example, bond energy between a hydrogen atom and a silicon atom is 3.3 eV, bond energy between a carbon atom and a silicon atom is 3.4 eV, and bond energy between a nitrogen atom and a silicon atom is 3.5 eV. Thus, in order to remove a hydrogen atom bonded to a silicon atom, radicals or ions having an energy of at least greater than or equal to 3.3 eV are made to collide with a bond portion between the hydrogen atom and the silicon atom to cut the bond between the hydrogen atom and the silicon atom. Note that the same applies to other impurities such as nitrogen and carbon; radicals or ions having energy at least greater than or equal to bond energy are made to collide with a bond portion between an impurity atom and a silicon atom to cut the bond between the impurity atom and the silicon atom.

Here, examples of radicals and ions generated by microwave-excited plasma include O(³P), which is an oxygen atom radical in the ground state, O(¹D), which is an oxygen atom radical in the first excited state, and O₂⁺, which is a monovalent cation of an oxygen molecule. The energy of O(³P) is 2.42 eV, and the energy of O(¹D) is 4.6 eV. Furthermore, the energy of O₂⁺ having charges is not uniquely determined because it is accelerated by the potential distribution in plasma and a bias; however, at least only the internal energy is higher than the energy of O(¹D). That is, by generating large amounts of radicals and ions such as O(¹D) and O₂⁺, the bond between each of hydrogen, nitrogen, and carbon atoms in the insulator 216 and a silicon atom can be efficiently cut to remove hydrogen, nitrogen, and carbon bonded to the silicon atom. Furthermore, the impurities such as hydrogen, nitrogen, and carbon can also be reduced by thermal energy and the like applied to a substrate in performing the microwave-excited plasma treatment.

Note that the proportion of the radicals and ions having high energy, such as O(¹D) and O₂⁺, in the total radical and ion species increases when the microwave-excited plasma treatment is performed in the low pressure and low oxygen conditions. Thus, the pressure during the microwave-excited plasma treatment is lower than or equal to 200 Pa, preferably lower than or equal to 70 Pa, and further preferably lower than or equal to 60 Pa. Furthermore, the oxygen flow rate (O₂/O₂+Ar) is lower than or equal to 50%, and preferably higher than or equal to 10% and lower than or equal to 30%.

Then, as shown in Step S03 in FIG. 2, the insulator 220, the insulator 222, and the insulator 224 are deposited. After that, as shown in Step S04, microwave-excited plasma treatment is performed. In particular, since being in contact with the oxide 230a formed later, the insulator 224 is preferably a film with reduced impurity concentration.

Note that the microwave-excited plasma treatment is preferably performed at least on the insulator 224. When the conditions of the microwave-excited plasma treatment performed on the insulator 224 are set as appropriate, the amount of impurities in the insulator 216 under the insulator 224 can be reduced. Thus, the microwave-excited plasma treatment on the insulator 216 is not necessarily performed.

Next, as shown in Step S05, the oxide 230a, the oxide 230b, the conductor 240, and the layer 245 are formed. Then, as shown in Step S06, the oxide 230c, the insulator 250, the conductor 260, and the layer 270 are formed. At this time, an oxide film 230C on the side surface of the oxide 230b is removed to expose the side surface of the oxide 230b. Note that the details of this step will be described later.

Next, as shown in Step S07, heat treatment is performed at a substrate temperature of higher than or equal to 100° C. for about five minutes. This can remove moisture such as adsorbed water before the insulator 272 is deposited. In particular, when the heat treatment is performed in an oxygen gas atmosphere, the heat treatment can be performed without forming oxygen vacancies in the oxide 230. Then, as shown in Step S08, the insulator 272 is deposited by a sputtering method. Here, as shown in the flow chart, the deposition of the insulator 272 is successively performed following the heat treatment in Step S07 without exposure to the outside air.

The insulator 272 is preferably deposited in an oxygen-containing atmosphere by a sputtering method. For example, as the insulator 272, an aluminum oxide film is deposited in an oxygen-containing atmosphere by a sputtering method. Accordingly, oxygen can be added to the vicinity of surfaces in contact with the insulator 272 (the side surface of the oxide 230a, the side surface of the oxide 230b, the top surface of the insulator 224, and the like), so that an oxygen excess state can be created.

Furthermore, the deposition condition of the insulator 272 is preferably as follows: a substrate temperature is higher than 100° C. and lower than or equal to 200° C., and preferably higher than or equal to 120° C. and lower than or equal to 150° C. Then, as shown in Step S09, the insulator 274 is deposited by an ALD method.

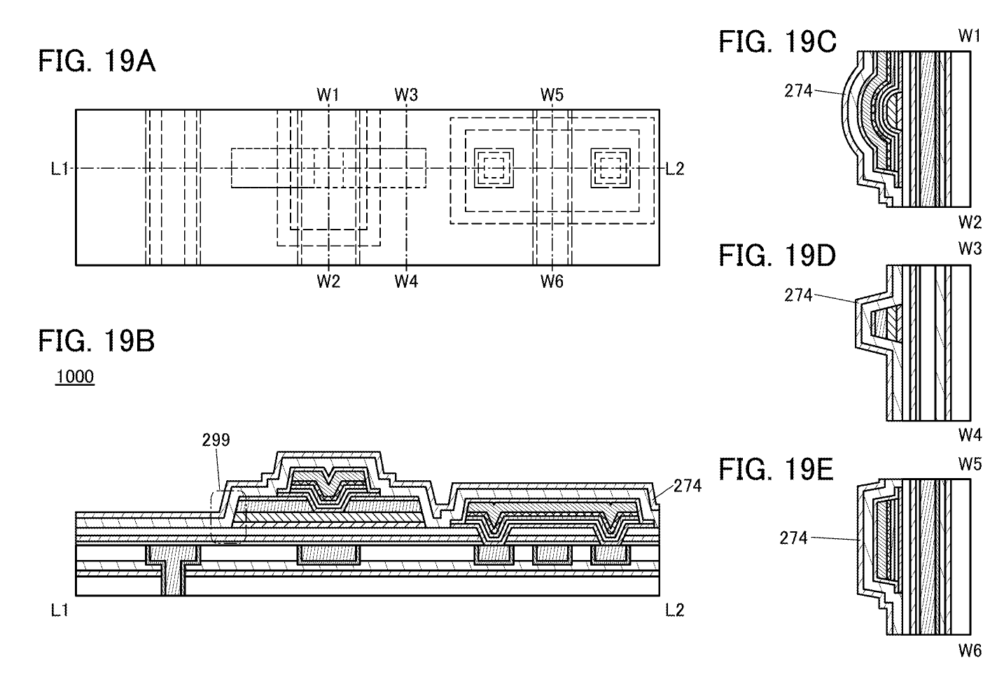

Next, as shown in Step S10, heat treatment is performed. Here, FIG. 25 shows a schematic diagram showing states of hydrogen and water in the vicinity of the side surface of the oxide 230b (hereinafter, referred to as a region 299, see FIG. 19) when the heat treatment shown in Step S10 is performed.

By performing the heat treatment, hydrogen contained in the insulator 224, the oxide 230a, the oxide 230b, and the like is gettered by the insulator 272 and diffused outward from the upper sides of the insulator 272 and the insulator 274 as water. Thus, the insulator 272 has a function of releasing hydrogen contained in the insulator 224, the oxide 230a, the oxide 230b, and the like outside the insulator 272 and the insulator 274 as water. Note that the function of gettering impurities in the film such as the oxide 230b is enhanced when the insulator 272 is deposited at low temperatures.

It can be said that the above function of the insulator 272 produces an effect similar to a catalyst. That is, it can be said that the insulator 272 has a catalytic effect. In this manner, the amount of impurities such as hydrogen in the insulator 272, the oxide 230a, and the oxide 230b can be further reduced.

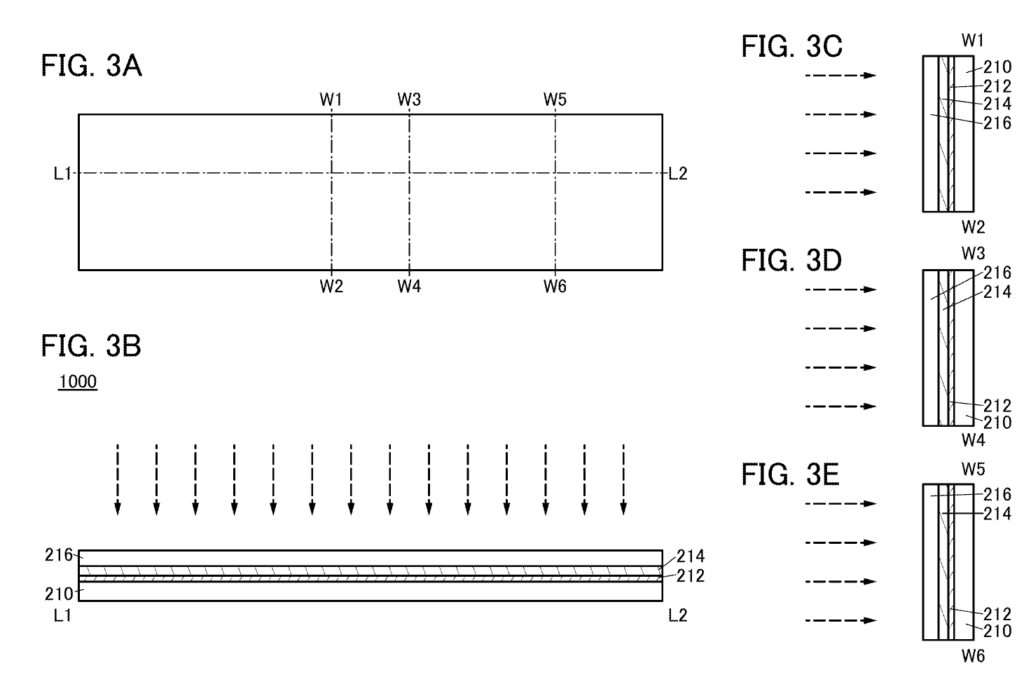

Next, the fabrication method of the semiconductor device 100 shown in FIG. 1 will be described with reference to FIG. 3 to FIG. 22. Note that FIG. 3 to FIG. 22 correspond to FIG. 1. FIG. 3(A) to FIG. 22(A) are top views of the semiconductor device 1000. FIG. 3(B) to FIG. 22(B) correspond to the dashed-dotted line L1-L2 in FIG. 3(A) to FIG. 22(A) and are cross-sectional views of the transistor 200 and the transistor 400 in the channel length direction. Furthermore, FIG. 3(C) to FIG. 22(C) correspond to the dashed-dotted line W1-W2 in FIG. 3(A) to FIG. 22(A) and are cross-sectional views of the transistor 200 in the channel width direction. Furthermore, FIG. 3(D) to FIG. 22(D) are cross-sectional views of the transistor 200 corresponding to the dashed-dotted line W3-W4 in FIG. 3(A) to FIG. 22(A). Furthermore, FIG. 3(E) to FIG. 22(E) correspond to the dashed-dotted line W5-W6 in FIG. 3(A) to FIG. 22(A) and are cross-sectional views of the transistor 400 in the channel width direction.

Note that hereinafter, an insulating material for forming the insulators, a conductive material for forming the conductors, or a semiconductor material for forming the semiconductors can be formed by a sputtering method, a spin coating method, a CVD (Chemical Vapor Deposition) method (including a thermal CVD method, an MOCVD (Metal Organic Chemical Vapor Deposition) method, a PECVD (Plasma Enhanced CVD) method, a high density plasma CVD (High density plasma CVD) method, an LPCVD method (low pressure CVD), an APCVD method (atmospheric pressure CVD), and the like), an ALD method, an MBE (Molecular Beam Epitaxy) method, or a PLD (Pulsed Laser Deposition) method as appropriate.

A plasma CVD method can provide a high-quality film at a relatively low temperature. With the use of a film deposition method that does not use plasma at the time of film deposition, such as an MOCVD method, an ALD method, or a thermal CVD method, damage is not easily caused on a formation surface and a film with few defects can be obtained.

Note that in the case of the film deposition by an ALD method, a gas that does not contain chlorine is preferably used as a material gas.

First, over a substrate (not illustrated), the insulator 210, the insulator 212, the insulator 214, and the insulator 216 are deposited in this order (see FIG. 3(A) to FIG. 3(E)). In this embodiment, a single crystal silicon substrate (including a p-type semiconductor substrate or an n-type semiconductor substrate) is used as the substrate.

In this embodiment, as the insulator 210, silicon oxynitride is deposited by a CVD method. When an insulator is formed by a plasma CVD method, a high-quality film can be obtained at a relatively low temperature.

In this embodiment, as the insulator 212, aluminum oxide is formed by an ALD method. When an insulating layer is formed by an ALD method, a dense insulating layer with reduced defects such as cracks and pinholes or with a uniform thickness can be formed.

In this embodiment, as the insulator 214, aluminum oxide is formed by a sputtering method. Note that as described above, the insulator 224 is preferably an insulator containing excess oxygen. Furthermore, after the formation of the insulator 216, oxygen doping treatment may be performed.

Next, as the insulator 216, silicon oxynitride is deposited by a CVD method. When an insulator is formed by a plasma CVD method, a high-quality film can be obtained at a relatively low temperature.

Then, the microwave-excited plasma treatment (indicated by broken line arrows in the figure) is preferably performed on the insulator 216. By performing the microwave-excited plasma treatment, water and nitrogen, which are impurities in the insulator 216, can be removed. Moreover, the microwave-excited plasma treatment is performed under a mixed atmosphere of oxygen and a rare gas while the RF bias is applied to the substrate, whereby a region containing excess oxygen can be formed in the insulator 216. Note that the pressure during the microwave-excited plasma treatment is lower than or equal to 200 Pa, preferably lower than or equal to 70 Pa, and further preferably lower than or equal to 60 Pa. Furthermore, the oxygen flow rate (O2/O2+Ar) is lower than or equal to 50%, and preferably lower than or equal to 30% and higher than or equal to 10%. Furthermore, the RF bias to be applied is preferably higher than 0 W and lower than or equal to 600 W.

In this embodiment, the microwave-excited plasma treatment is preferably performed for five minutes. Furthermore, plasma is preferably generated under an atmosphere of argon (Ar) at a flow rate of 150 sccm and oxygen (O₂) at a flow rate of 50 sccm under the conditions where the pressure in a reaction chamber is 60 Pa, a high-frequency (RF) bias of 13.56 MHz is applied, and a microwave of 4000 W (2.45 GHz) is used.

Next, a resist mask is formed over the insulator 216, and openings corresponding to the conductor 205, the conductor 405, the conductor 403, and the conductor 407 are formed in the insulator 216. Furthermore, an opening corresponding to the conductor 207 is formed in the insulator 210, the insulator 212, the insulator 214, and the insulator 216. The formation of the resist mask can be performed by a photolithography method, a printing method, an inkjet method, or the like as appropriate. Formation of the resist mask by a printing method, an inkjet method, or the like does not use photomask; thus, manufacturing costs can be reduced.

The formation of the resist mask by a photolithography method can be performed in such a manner that a photosensitive resist is irradiated with light through a photomask and part of the resist that has been exposed to light (or part that has not been exposed to light) is removed using a developing solution. Examples of light with which the photosensitive resist is irradiated include KrF excimer laser light, ArF excimer laser light, and EUV (Extreme Ultraviolet) light. Furthermore, a liquid immersion technique may be employed in which a portion between a substrate and a projection lens is filled with liquid (e.g., water) to perform light exposure. Furthermore, an electron beam or an ion beam may be used instead of the above-described light. Note that a photomask is not necessary in the case of using an electron beam or an ion beam. Note that the removal of the resist mask can be performed by a dry etching method such as ashing or a wet etching method using a dedicated stripper or the like. Both the dry etching method and the wet etching method may be used.

Note that at the time of forming the openings, part of the insulator 214 is also removed in some cases. The etching of the insulator 210, the insulator 212, the insulator 214, and the insulator 216 can be performed by a dry etching method, a wet etching method, or the like. Both the dry etching method and the wet etching method may be used. The resist mask is removed after the formation of the openings.

Next, conductive films to be the conductor 207a, the conductor 205a, the conductor 403a, the conductor 405a, and the conductor 407a and conductive films to be the conductor 207b, the conductor 205b, the conductor 403b, the conductor 405b, and the conductor 407b are deposited over the insulator 214 and the insulator 216. In this embodiment, a stacked-layer film of tantalum nitride and titanium nitride is formed by a sputtering method as the conductive films to be the conductor 207a, the conductor 205a, the conductor 403a, the conductor 405a, and the conductor 407a. Furthermore, tungsten is formed by a sputtering method as the conductive films to be the conductor 207b, the conductor 205b, the conductor 403b, the conductor 405b, and the conductor 407b.

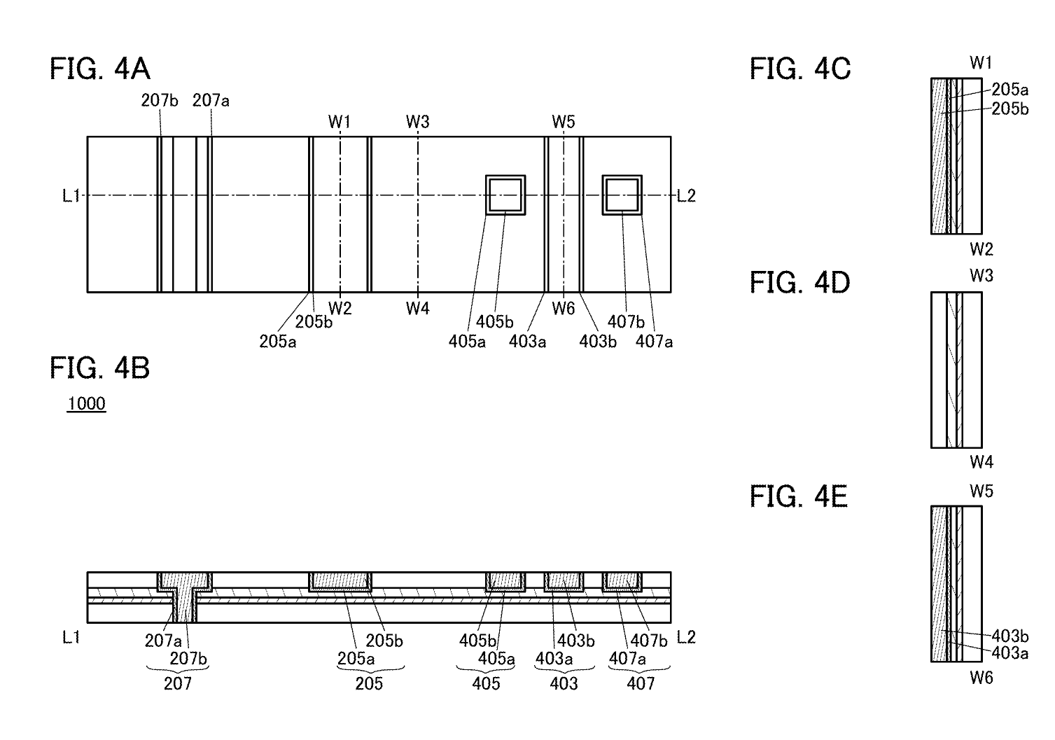

Next, chemical mechanical polishing (CMP: Chemical Mechanical Polishing) treatment (also referred to as “CMP treatment”) is performed to form the conductor 207a, the conductor 207b, the conductor 205a, the conductor 205b, the conductor 403a, the conductor 403b, the conductor 405a, the conductor 405b, the conductor 407a, and the conductor 407b (see FIG. 4(A) to FIG. 4(E)). By the CMP treatment, parts of the conductive films are removed. At this time, part of a surface of the insulator 216 is also removed in some cases. By performing the CMP treatment, unevenness of a sample surface can be reduced, so that coverage with an insulating layer and a conductive layer to be formed later can be increased.

Note that the conductor 207, the conductor 205, the conductor 405, the conductor 403, and the conductor 407 can be fabricated at the same time by a dual damascene method. In this manner, the conductor 207, the conductor 205, the conductor 403, the conductor 405, and the conductor 407 are formed (see FIG. 4).

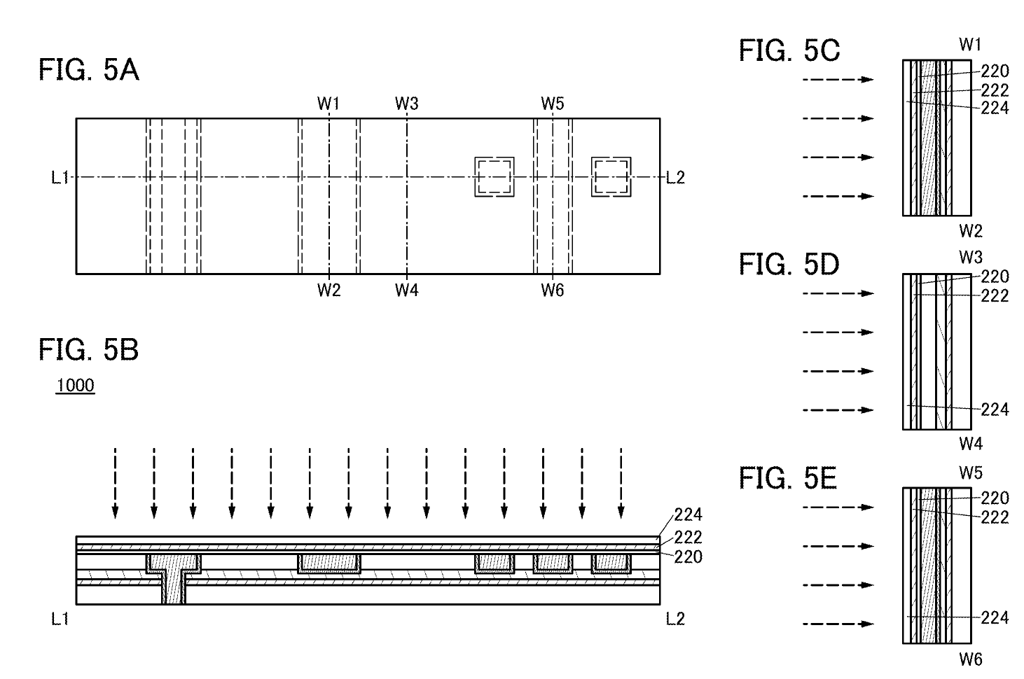

The insulator 220, the insulator 222, and the insulator 224 are deposited in this order over the insulator 216, the conductor 207, the conductor 205, the conductor 403, the conductor 405, and the conductor 407 (see FIG. 5(A) to FIG. 5(E)). In this embodiment, hafnium oxide is deposited by an ALD method as the insulator 222 and silicon oxide is deposited by a CVD method as the insulator 220 and the insulator 224.

Next, the microwave-excited plasma treatment (indicated by broken line arrows in the figure) is performed on the insulator 224. The concentration of impurities such as water or hydrogen in the film of the insulator 224 is preferably lowered.

By performing the microwave-excited plasma treatment, water and nitrogen, which are impurities in the insulator 224, can be removed. Furthermore, when the conditions of the microwave-excited plasma treatment performed on the insulator 224 are set as appropriate, the amount of impurities in the insulator 216 under the insulator 224 can be reduced. Moreover, the microwave-excited plasma treatment is performed under a mixed atmosphere of oxygen and a rare gas while the RF bias is applied to the substrate, whereby a region containing excess oxygen can be formed in the insulator 216. Note that the pressure during the microwave-excited plasma treatment is lower than or equal to 200 Pa, preferably lower than or equal to 70 Pa, and further preferably lower than or equal to 60 Pa. Furthermore, the oxygen flow rate (O2/O2+Ar) is lower than or equal to 50%, and preferably lower than or equal to 30% and higher than or equal to 10%. Furthermore, the RF bias to be applied is preferably higher than 0 W and lower than or equal to 600 W.

In this embodiment, the microwave-excited plasma treatment is preferably performed for five minutes. Furthermore, plasma is preferably generated under an atmosphere of argon (Ar) at a flow rate of 150 sccm and oxygen (O₂) at a flow rate of 50 sccm under the conditions where the pressure in a reaction chamber is 60 Pa, a high-frequency (RF) bias of 13.56 MHz is applied, and a microwave of 4000 W (2.45 GHz) is used.

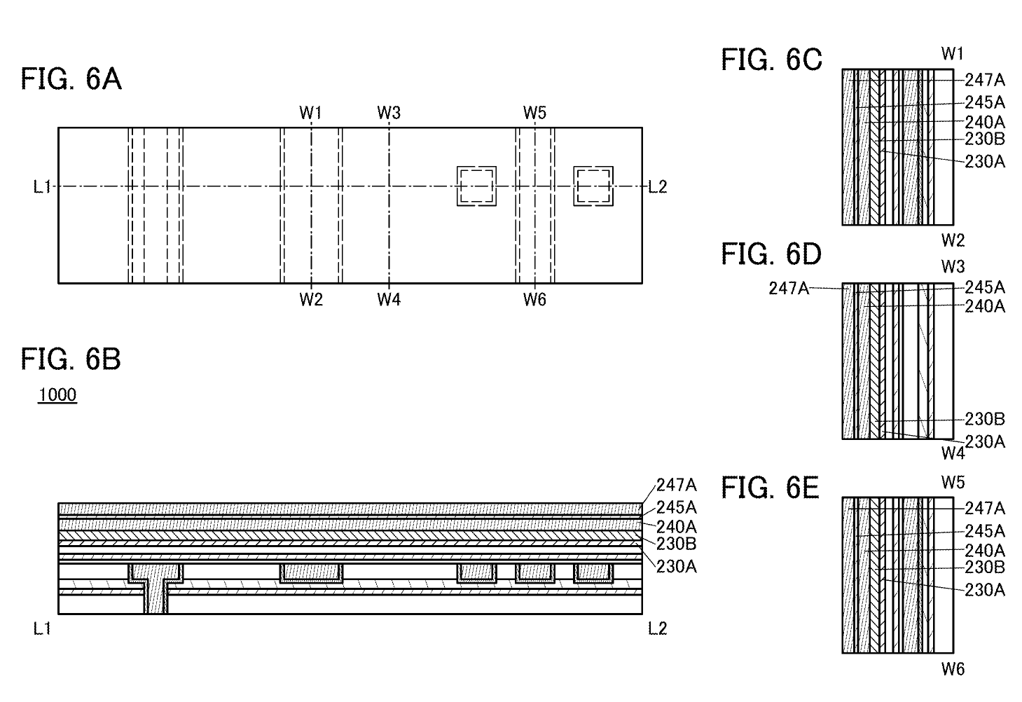

Next, an oxide film 230A, an oxide film 230B, a conductive film 240A, a film 245A, and a conductive film 247A are deposited in this order, see FIG. 6(A) to FIG. 6(E).

When an oxide is included as the oxide 230 and the oxide 430, oxide films forming the oxide 230 and the oxide 430 are preferably formed by a sputtering method. The formation by a sputtering method is suitable because the density of the oxide 230 and the oxide 430 can be increased. A rare gas (typically, argon), oxygen, or a mixed gas of a rare gas and oxygen is used as a sputtering gas. Furthermore, film deposition may be performed while the substrate is heated.

Furthermore, the purity of a sputtering gas needs to be increased. For example, as an oxygen gas or a rare gas used as a sputtering gas, a gas that is highly purified to have a dew point of −60° C. or lower, and preferably −100° C. or lower is used. When the highly purified sputtering gas is used for film deposition, entry of moisture or the like into the oxide 230 and the oxide 430 can be prevented as much as possible.

Furthermore, in the case where the oxide 230 and the oxide 430 are formed by a sputtering method, moisture in a film deposition chamber of a sputtering apparatus is preferably removed as much as possible. For example, with an adsorption vacuum evacuation pump such as cryopump, the film deposition chamber is preferably evacuated to be a high vacuum state (to a degree of about 5×10⁻⁷ Pa to 1×10⁻⁴ Pa). In particular, the partial pressure of gas molecules corresponding to H₂O (gas molecules corresponding to m/z=18) in the film deposition chamber in the standby mode of the sputtering apparatus is preferably lower than or equal to 1×10⁻⁴ Pa, further preferably lower than or equal to 5×10⁻⁵ Pa.

In this embodiment, the oxide film 230A is formed by a sputtering method. Furthermore, oxygen or a mixed gas of oxygen and a rare gas is used as the sputtering gas. By increasing the proportion of oxygen in the sputtering gas, the amount of excess oxygen in the oxide film to be deposited can be increased.

Furthermore, at the time of the formation of the oxide film 230B, part of oxygen contained in the sputtering gas is supplied to the insulator 224 and the insulators 222 and 216 in some cases. As the amount of oxygen contained in the sputtering gas increases, the amount of oxygen supplied to the insulator 224 and the insulators 222 and 216 increases. Thus, regions containing excess oxygen can be formed in the insulator 224, the insulator 222, and the insulator 216. Furthermore, part of oxygen supplied to the insulator 224 and the insulators 222 and 216 reacts with hydrogen left in the insulator 224 and the insulators 222 and 216 to be water, and is released from the insulator 224 and the insulators 222 and 216 by later heat treatment. Thus, the hydrogen concentrations in the insulator 224 and the insulators 222 and 216 can be reduced.

Accordingly, the proportion of oxygen in the sputtering gas is preferably higher than or equal to 70%, further preferably higher than or equal to 80%, and still further preferably 100%. When an oxide containing excess oxygen is used for the oxide film 230A, oxygen can be supplied to the oxide 230b by later heat treatment.

Then, the oxide film 230B is formed by a sputtering method. At this time, when the proportion of oxygen contained in the sputtering gas is higher than or equal to 1% and lower than or equal to 30%, and preferably higher than or equal to 5% and lower than or equal to 20% during the film deposition, an oxygen-deficient oxide is formed. A transistor using an oxygen-deficient oxide can have relatively high field-effect mobility.

Note that when an oxygen-deficient oxide is used for the oxide film 230B, an oxide film containing excess oxygen is preferably used as the oxide film 230A. Furthermore, after the formation of the oxide film 230B, oxygen doping treatment may be performed.

Note that after the deposition of the oxide film 230A and the oxide film 230B, heat treatment is preferably performed. The details of the conditions of the heat treatment will be described below. In this embodiment, the heat treatment is performed at 400° C. in an oxygen gas atmosphere for one hour. Accordingly, oxygen is introduced into the oxide film 230A and the oxide film 230B. Further preferably, heat treatment is performed at 400° C. in a nitrogen gas atmosphere for one hour before the heat treatment in an oxygen gas atmosphere. By performing the heat treatment in a nitrogen gas atmosphere first, impurities such as moisture or hydrogen contained in the oxide film 230A and the oxide film 230B are released, so that the impurity concentrations in the oxide film 230A and the oxide film 230B can be reduced.

Next, the conductive film 240A is deposited. In this embodiment, tantalum nitride is formed by a sputtering method as the conductive film 240A. Tantalum nitride has high oxidation resistance and thus is preferable in the case where heat treatment is performed in a later step.

Furthermore, when the conductive film 240A is in contact with the oxide film 230B, an impurity element is introduced into the surface of the oxide film 230B in some cases. Addition of the impurities into the oxide film 230B can change the threshold voltage of the transistor 200. Note that the impurity element may be introduced by an ion implantation method, an ion doping method, a plasma immersion ion implantation method, plasma treatment using a gas containing the impurity element, or the like before the conductive film 240A is formed. Furthermore, the introduction of the impurity element may be performed by an ion implantation method or the like after the conductive film 240A is formed.

Next, the film 245A is deposited. In this embodiment, aluminum oxide is formed by an ALD method as the film 245A. With the use of an ALD method, a dense film with reduced defects such as cracks and pinholes or with a uniform thickness can be formed.

The conductive film 247A serves as a hard mask for forming the conductor 240a and the conductor 240b in a later step. In this embodiment, tantalum nitride is used for the conductive film 247A.

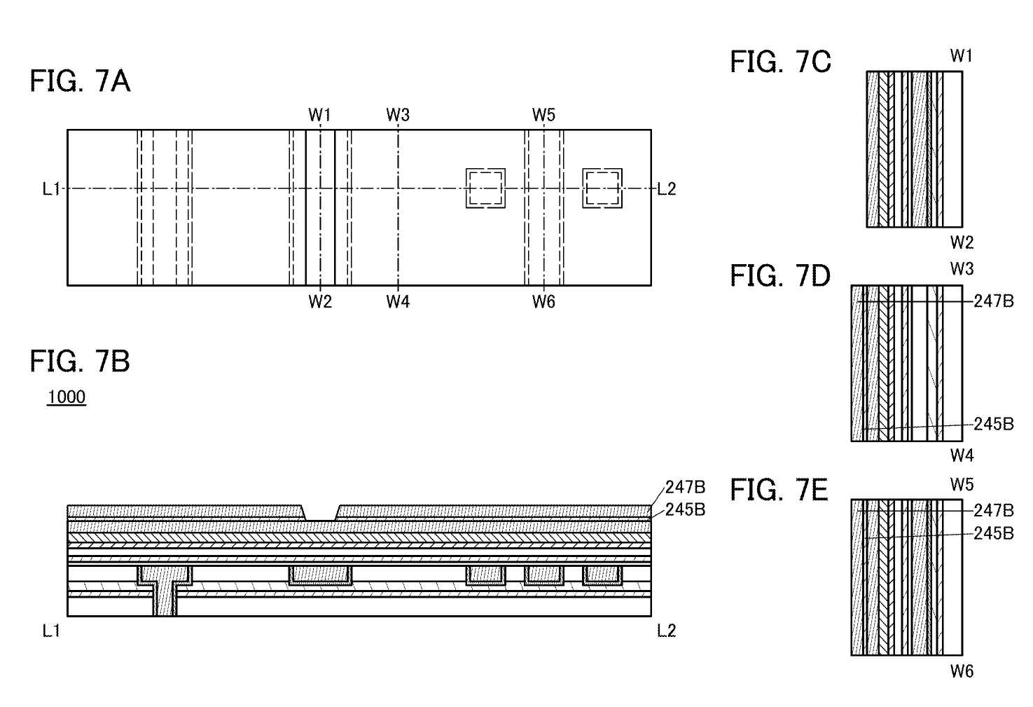

Next, the film 245A and the conductive film 247A are processed by a photolithography method to form a film 245B and a conductive film 247B (see FIG. 7(A) to FIG. 7(E)). The film 245B and the conductive film 247B have an opening.

Note that at the time of forming the opening, the side surfaces of the film 245B and the conductive film 247B on the opening side each preferably have an angle with respect to the top surface of the oxide 230b. Note that the angle is 30° or more and 90° or less, and preferably 45° or more and 80° or less. Furthermore, the formation of the opening with the resist mask is preferably performed using the minimum feature size. That is, the film 245B has an opening portion whose width is the minimum feature size.

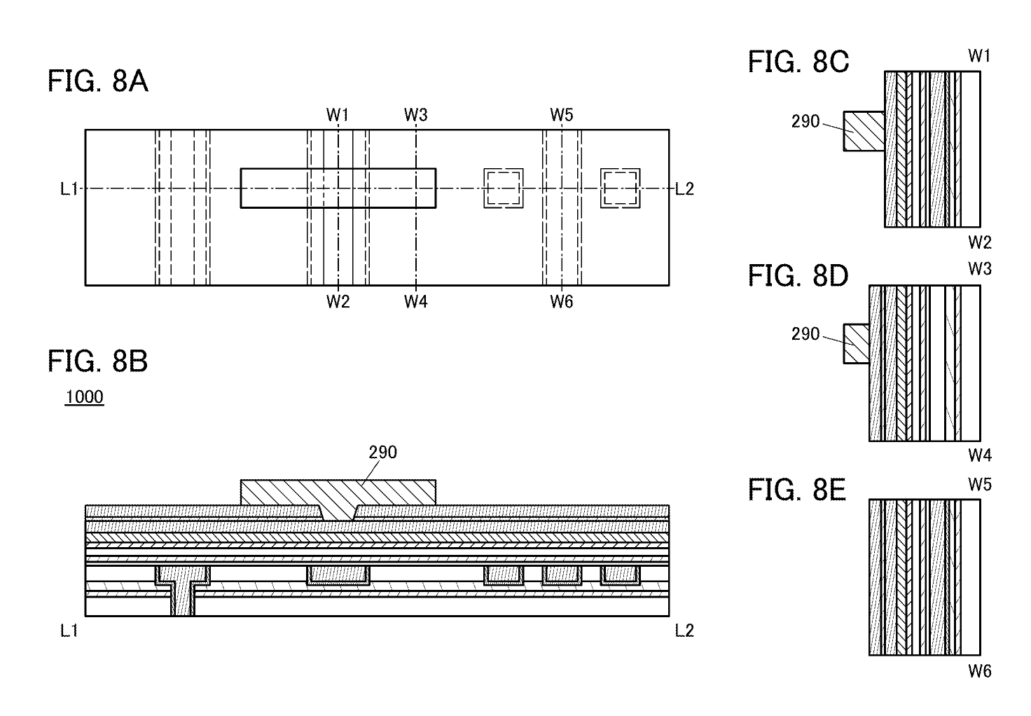

Next, a resist mask 290 is formed over the film 245B and the conductive film 247B by a photolithography method (see FIG. 8(A) to FIG. 8(E)).

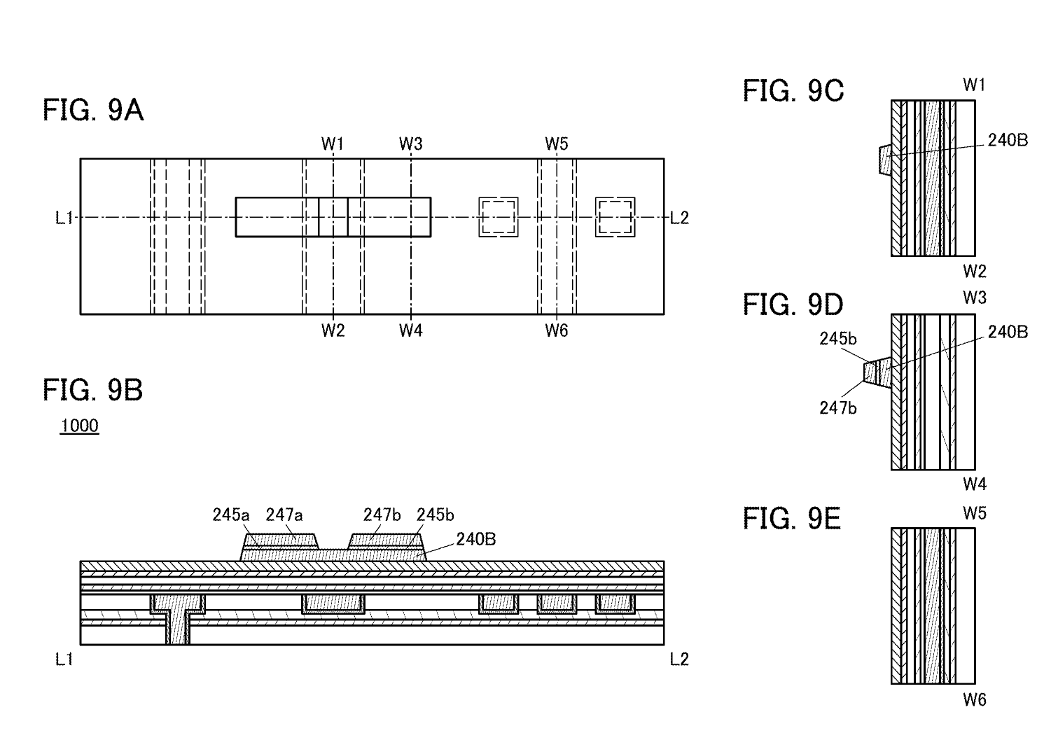

With the use of the resist mask 290 as a mask, parts of the conductive film 240A, the film 245B, and the conductive film 247B are selectively removed to perform the processing into an island shape (see FIG. 9(A) to FIG. 9(E)). At this time, a conductive film 240B is formed from the conductive film 240A, the layer 245a and the layer 245b are formed from the film 245B, and a conductor 247a and a conductor 247b are formed from the conductive film 247B. Note that when the opening in the film 245B has the minimum feature size, the distance between the layer 245a and the layer 245b is the minimum feature size.

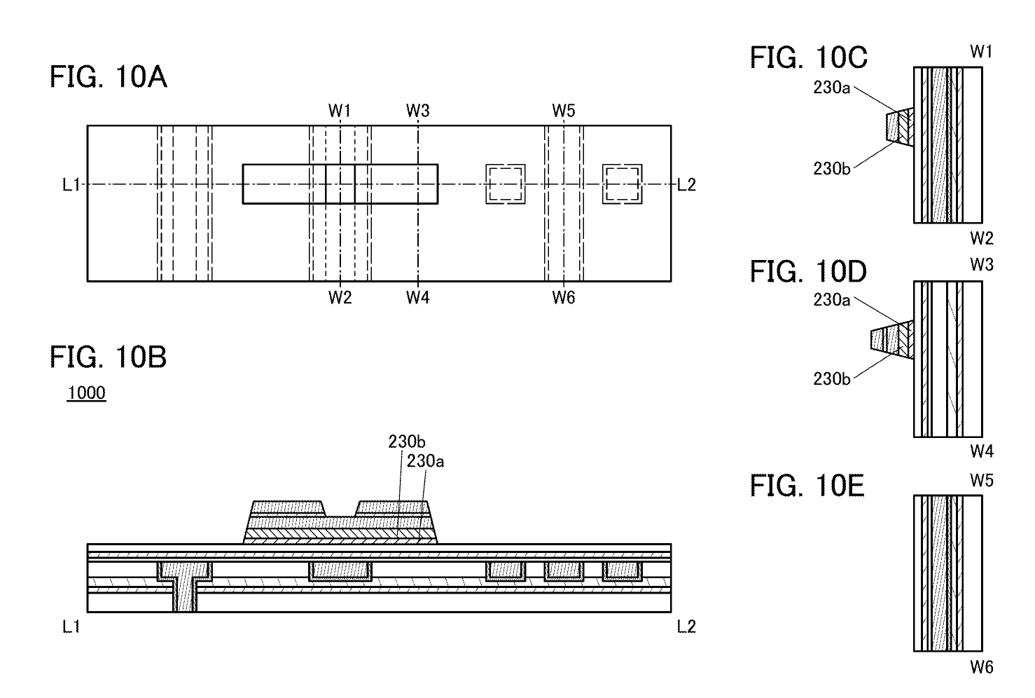

Then, parts of the oxide 230A and the oxide 230B are selectively removed using the conductive film 240B as a mask (see FIG. 10(A) to FIG. 10(E)). At this time, part of the insulator 224 is simultaneously removed in some cases. After that, the resist mask is removed, whereby a stacked-layer structure of the island-shaped oxide 230a, the island-shaped oxide 230b, the island-shaped conductive film 240B, the layer 245a, the layer 245b, the conductor 247a, and the conductor 247b can be formed.

Note that the oxide film 230A, the oxide film 230B, the conductive film 240A, and the film 245A can be removed by a dry etching method, a wet etching method, or the like. Both the dry etching method and the wet etching method may be used.

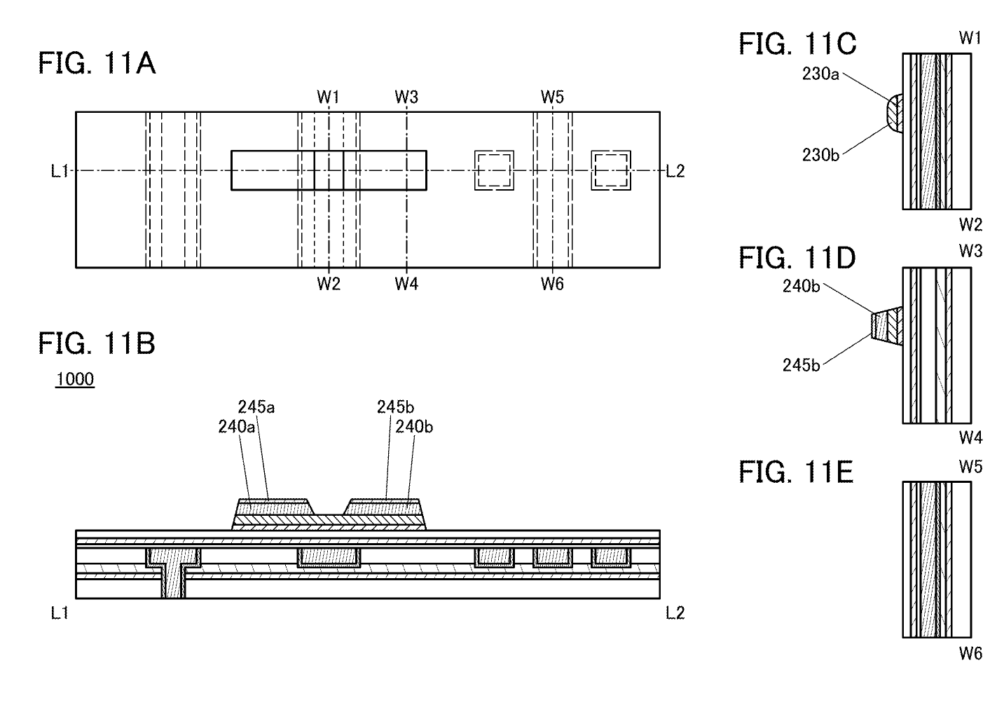

Then, part of the conductive film 240B is selectively removed by a dry etching method using the layer 245a, the layer 245b, the conductor 247a, and the conductor 247b as masks. Through the etching step, the conductive film 240B is separated into the conductor 240a and the conductor 240b (see FIG. 11(A) to FIG. 11(E)).

As a gas used for the dry etching, for example, a C₄F₆ gas, a C₂F₆ gas, a C₄F₈ gas, a CF₄ gas, an SF₆ gas, a CHF₃ gas, or the like can be used alone or a mixture of two or more of the gases can be used. Alternatively, an oxygen gas, a helium gas, an argon gas, a hydrogen gas, or the like can be added to the above gases as appropriate. In particular, a gas with which an organic substance can be generated by plasma is preferably used. For example, it is preferable to use any one of a C₄F₆ gas, a C₄F₈ gas, and a CHF₃ gas to which a helium gas, an argon gas, a hydrogen gas, or the like is added as appropriate.

Here, the conductor 247a and the conductor 247b function as hard masks, and the conductor 247a and the conductor 247b are also removed as etching proceeds.

With the use of a gas with which an organic substance can be generated, the conductive film 240B is etched while an organic substance is attached to the side surfaces of the layer 245a, the layer 245b, the conductor 247a, and the conductor 247b, whereby the side surfaces, which are in contact with the oxide 230c, of the conductor 240a and the conductor 240b can have tapered shapes.

The conductor 240a and the conductor 240b have functions as a source electrode and a drain electrode of the transistor; thus, a length of a space between the conductor 240a and the conductor 240b facing each other can be referred to as a channel length of the transistor. That is, when the opening in the film 245B has the minimum feature size, the distance between the layer 245a and the layer 245b is the minimum feature size; thus, the gate line width and the channel length that are smaller than the minimum feature size can be formed.

Note that the angle of the side surface of the opening in the film 245B can be controlled in accordance with the ratio of the etching rate of the conductive film 240B to the deposition rate of the organic substance deposited on the side surfaces of the layer 245a and the layer 245b. For example, when the ratio of the etching rate to the deposition rate of the organic substance is 1, the angle is 45°.

The ratio of the etching rate to the deposition rate of the organic substance is determined by setting etching conditions as appropriate depending on the gas to be used in the etching. For example, the ratio of the etching rate to the deposition rate of the organic substance can be controlled by using a mixed gas of a C₄F₈ gas and an argon gas as etching gases and controlling the high-frequency power and the etching pressure of the etching apparatus.

Furthermore, when the conductor 240a and the conductor 240b are formed by a dry etching method, impurity elements such as remaining components of an etching gas might be attached to the exposed oxide 230b. For example, when a chlorine-based gas is used as the etching gas, chlorine and the like are attached in some cases. Furthermore, when a hydrocarbon-based gas is used as the etching gas, carbon, hydrogen, and the like are attached in some cases. Thus, the impurity elements attached to the exposed surface of the oxide 230b are preferably reduced. A reduction in the amount of impurities is performed by, for example, cleaning treatment using hydrofluoric acid or the like, cleaning treatment using ozone or the like, or cleaning treatment using ultraviolet rays or the like. Note that a plurality of cleaning treatments may be combined.

Furthermore, plasma treatment using an oxidizing gas may be performed. For example, plasma treatment using a nitrous oxide gas is performed. By performing the plasma treatment, the fluorine concentration in the oxide 230b can be lowered. Furthermore, an effect of removing an organic substance on the sample surface can be obtained.

Furthermore, oxygen doping treatment may be performed on the exposed oxide 230b. Furthermore, heat treatment described later may be performed.

Furthermore, for example, when processing is performed using the layer 245a and the layer 245b as masks, an etching gas having relatively high selectivity to the conductive film 240B and the insulator 224 can be used. Accordingly, even in a structure in which the total thickness of the insulator 224 is small, over-etching of a wiring layer in the lower part can be prevented. Furthermore, when the total thickness of the insulator 224 is small, voltage is efficiently applied from the conductor 205; thus, the transistor with low power consumption can be provided.

Next, heat treatment is preferably performed to further reduce the amount of impurities such as moisture or hydrogen contained in the oxide 230a and the oxide 230b to highly purify the oxide 230a and the oxide 230b.

Furthermore, plasma treatment using an oxidizing gas may be performed before the heat treatment. For example, plasma treatment using a nitrous oxide gas is performed. By performing the plasma treatment, the fluorine concentration in the exposed insulating layer can be lowered. Furthermore, an effect of removing an organic substance on the sample surface can be obtained.

The heat treatment is performed, for example, under an inert atmosphere containing nitrogen, a rare gas, or the like, under an oxidizing gas atmosphere, or under an ultra-dry air (the air in which the moisture amount measured with a dew point meter in a CRDS (cavity ring down laser spectroscopy) system is 20 ppm (−55° C. by conversion into a dew point) or less, preferably 1 ppm or less, and further preferably 10 ppb or less) atmosphere. Note that the “oxidizing gas atmosphere” refers to an atmosphere containing an oxidizing gas such as oxygen, ozone, or nitrogen oxide at 10 ppm or higher. Furthermore, the “inert atmosphere” refers to an atmosphere containing the above-described oxidizing gas at lower than 10 ppm and is filled with another element such as nitrogen or a rare gas. The pressure during the heat treatment is not particularly limited; however, the heat treatment is preferably performed under a reduced pressure.

Furthermore, by performing the heat treatment, at the same time as the release of the impurities, oxygen contained in the insulator 224 is diffused into the oxide 230a and the oxide 230b and the amount of oxygen vacancies contained in the oxides can be reduced. Note that after the heat treatment is performed in an inert atmosphere, heat treatment may be performed in an atmosphere containing an oxidizing gas at 10 ppm or more, 1% or more, or 10% or more in order to compensate for desorbed oxygen. Note that the heat treatment may be performed at any time after the oxide 230a and the oxide 230b are formed.

The heat treatment is performed at higher than or equal to 250° C. and lower than or equal to 650° C., and preferably higher than or equal to 300° C. and lower than or equal to 500° C. The treatment time is shorter than or equal to 24 hours. Heat treatment for over 24 hours is not preferable because the productivity is reduced. Furthermore, in the case where a metal that is likely to diffuse when heated, such as Cu, is used for the conductor, the temperature of the heat treatment is set to lower than or equal to 410° C., and preferably lower than or equal to 400° C.

In this embodiment, after heat treatment is performed at 400° C. in a nitrogen gas atmosphere for one hour, the nitrogen gas is replaced by an oxygen gas and another heat treatment is performed at 400° C. for one hour. By performing the heat treatment in a nitrogen gas atmosphere first, impurities such as moisture or hydrogen contained in the oxide 230a and the oxide 230b are released, so that the impurity concentrations in the oxide 230a and the oxide 230b are reduced. By performing the heat treatment in an oxygen gas atmosphere next, oxygen is introduced into the oxide 230a and the oxide 230b.

Furthermore, since part of an upper surface of the conductive film 240B is covered with the layer 245a and the layer 245b at the heat treatment, oxidation caused from the upper surface can be prevented.

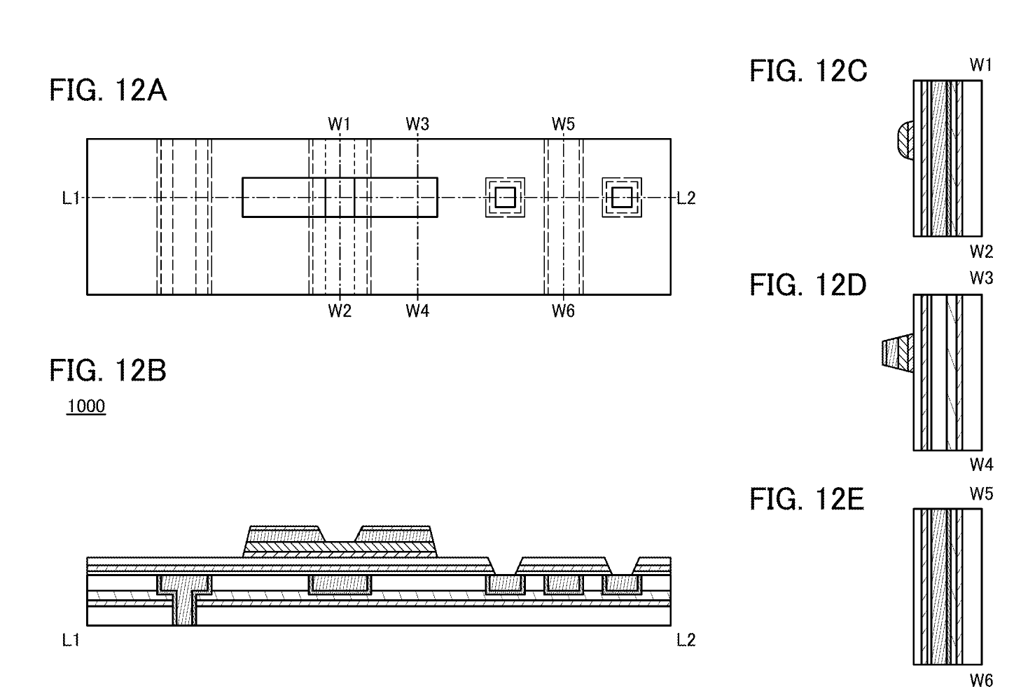

Next, openings are formed in the insulator 220, the insulator 222, and the insulator 224 by a photolithography method. Note that the openings are provided over a conductor 405c and a conductor 407c (see FIG. 12(A) to FIG. 12(E)).

Next, the oxide film 230C to be the oxide 230c and the oxide 430 are formed. In this embodiment, an oxide containing a large amount of excess oxygen is used for the oxide film 230C, as for the oxide film 230A. When a semiconductor containing excess oxygen is used for the oxide film 230C, oxygen can be supplied to the oxide 230b by later heat treatment.

Furthermore, at the time of the formation of the oxide 230c, part of oxygen contained in the sputtering gas is supplied to the insulator 224, the insulator 222, and the insulator 216 to form an excess-oxygen region in some cases, as in the case of the oxide 230a. Furthermore, part of oxygen supplied to the insulator 224, the insulator 222, and the insulator 216 reacts with hydrogen left in the insulator 224, the insulator 222, and the insulator 216 to be water, and is released from the insulator 224, the insulator 222, and the insulator 216 by later heat treatment. Thus, the hydrogen concentrations in the insulator 224, the insulator 222, and the insulator 216 can be reduced.

Note that after the formation of the oxide film 230C, either or both of oxygen doping treatment and heat treatment may be performed. By performing the heat treatment, oxygen contained in the oxide 230a and the oxide 230c can be supplied to the oxide 230b. By supplying oxygen to the oxide 230b, the amount of oxygen vacancies in the oxide 230b can be reduced. Thus, when an oxygen-deficient oxide is used as the oxide 230b, a semiconductor containing excess oxygen is preferably used as the oxide 230c.

Part of the oxide 230c is in contact with a channel formation region of the oxide 230b. Furthermore, a top surface and side surfaces of the region where the channel is formed of the oxide 230b are covered with the oxide 230c. In such a manner, the oxide 230b can be surrounded by the oxide 230a and the oxide 230c. By surrounding the oxide 230b by the oxide 230a and the oxide 230c, diffusion of impurities generated in a later step into the oxide 230b can be inhibited.

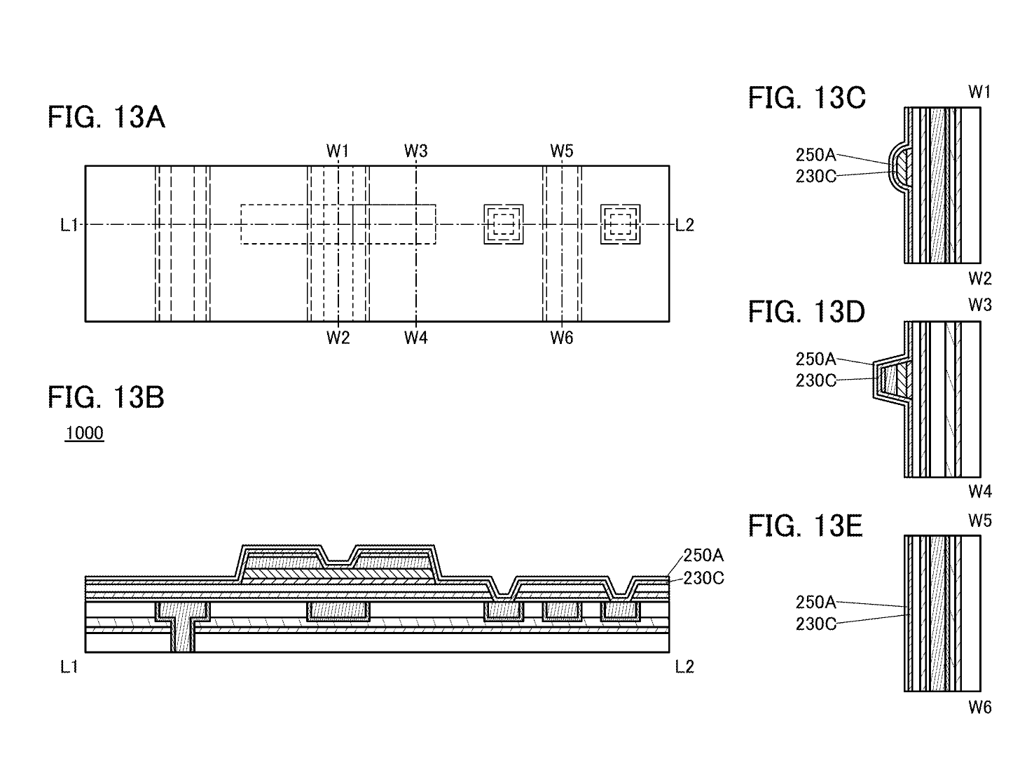

Next, an insulating film 250A is formed over the oxide film 230C (see FIG. 13(A) to FIG. 13(E)). In this embodiment, silicon oxynitride is formed by a CVD method as the insulating film 250A. Note that the insulating film 250A is preferably an insulating layer containing excess oxygen. Furthermore, the insulating film 250A may be subjected to oxygen doping treatment. Furthermore, heat treatment may be performed after the formation of the insulating film 250A.

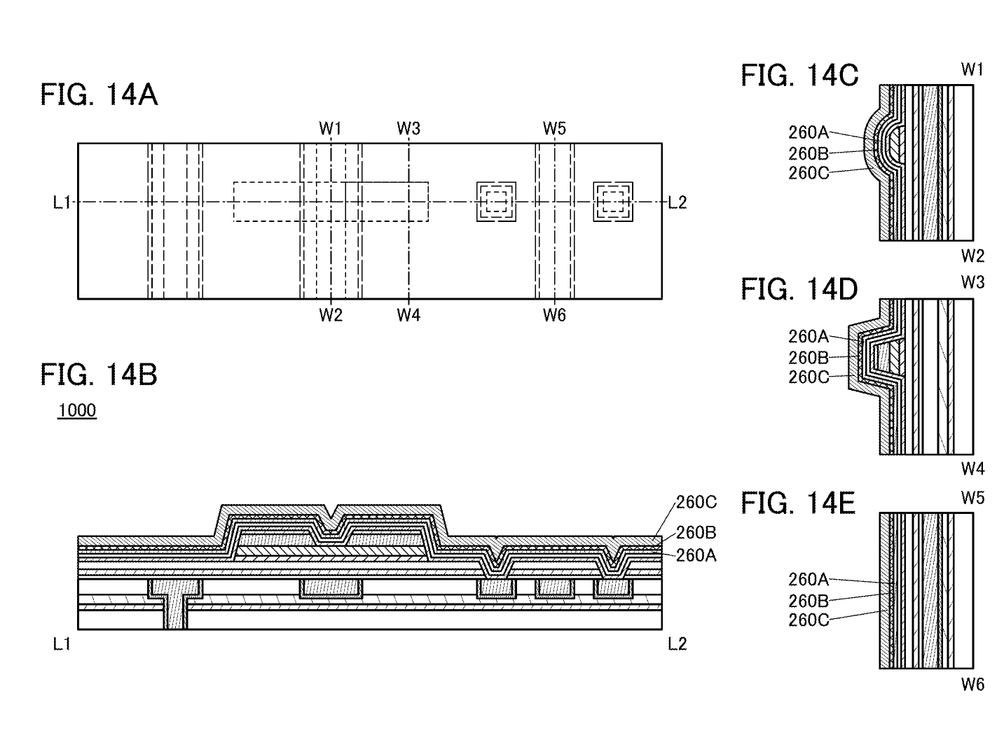

Next, a conductive film 260A, a conductive film 260B, and a conductive film 260C are deposited in this order (see FIG. 14(A) to FIG. 14(E)). In this embodiment, a metal oxide deposited by a sputtering method is used for the conductive film 260A, titanium nitride is used for the conductive film 260B, and tungsten is used for the conductive film 260C.

The conductive film 260A is deposited by a sputtering method, whereby oxygen can be added to the insulator 250 to create an oxygen excess state. Thus, oxygen can be supplied from the insulator 250 to the oxide 230b effectively.

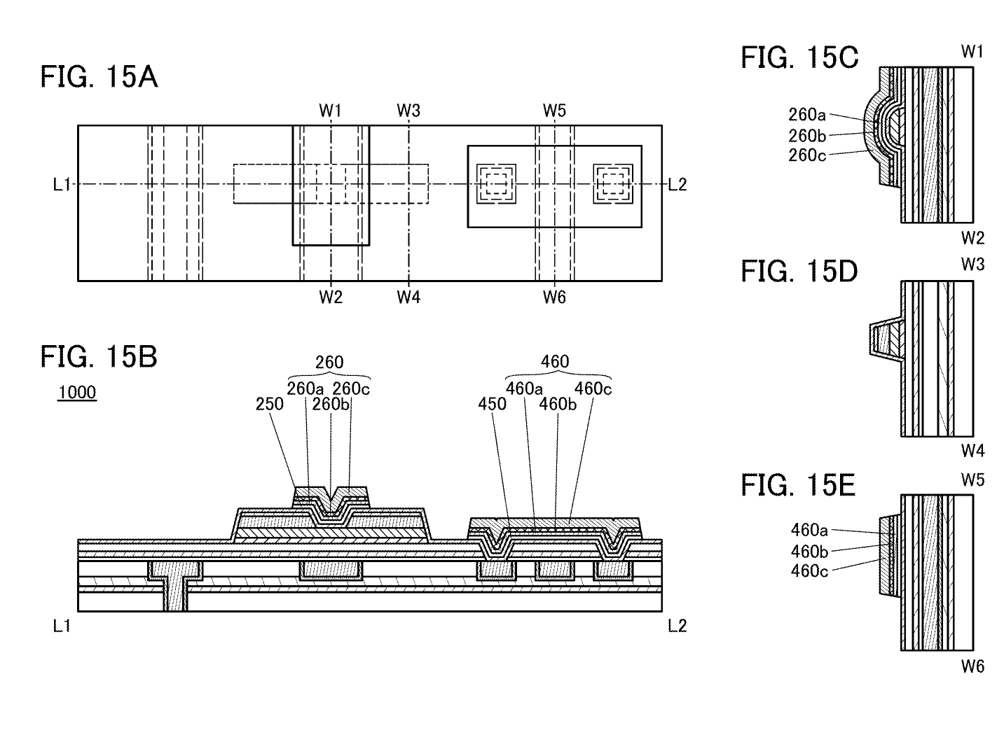

Next, parts of the insulating film 250A, the conductive film 260A, the conductive film 260B, and the conductive film 260C are selectively removed by a photolithography method to form the insulator 250, the insulator 450, the conductor 260a, the conductor 260b, the conductor 260c, the conductor 460a, the conductor 460b, and the conductor 460c (see FIG. 15(A) to FIG. 15(E)).

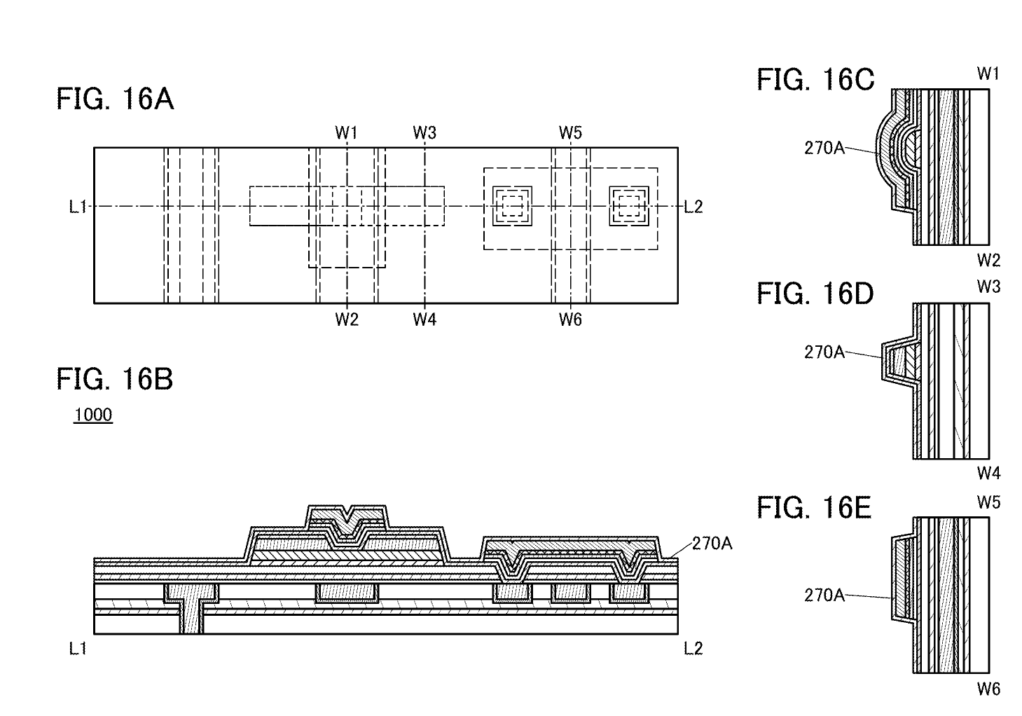

Next, a film 270A to be processed into the layer 270 and the layer 470 in a later step is deposited (see FIG. 16(A) to FIG. 16(E)). The film functions as a gate cap, and in this embodiment, aluminum oxide deposited by an ALD method is used.

Here, as described above, in order to impart stable electrical characteristics and high reliability to the transistor 200 and the transistor 400, it is important to supply oxygen in the insulator 212, the insulator 214, the insulator 272, the insulator 274, the insulator 282, and the insulator 284 to the oxide 230 and the oxide 430 without outward diffusion and to prevent impurities such as hydrogen or water from entering the transistor 200 and the transistor 400 from the outside.

Next, part of the film 270A is selectively removed by a photolithography method to form the layer 270 and the layer 470 that function as gate caps. The layer 270 is formed over the conductor 260, whereby consumption of surrounding excess oxygen by oxidation of the conductor 260 can be prevented.

The etching of the layer 270 and the layer 470 can be performed by a dry etching method, a wet etching method, or the like. In this embodiment, the layer 270 and the layer 470 are formed by a dry etching method. At this time, although part of the oxide film 230C can be removed in some cases, a residue of the oxide film 230C is likely to be formed on the side surfaces of the oxide 230a and the oxide 230b, or the like.

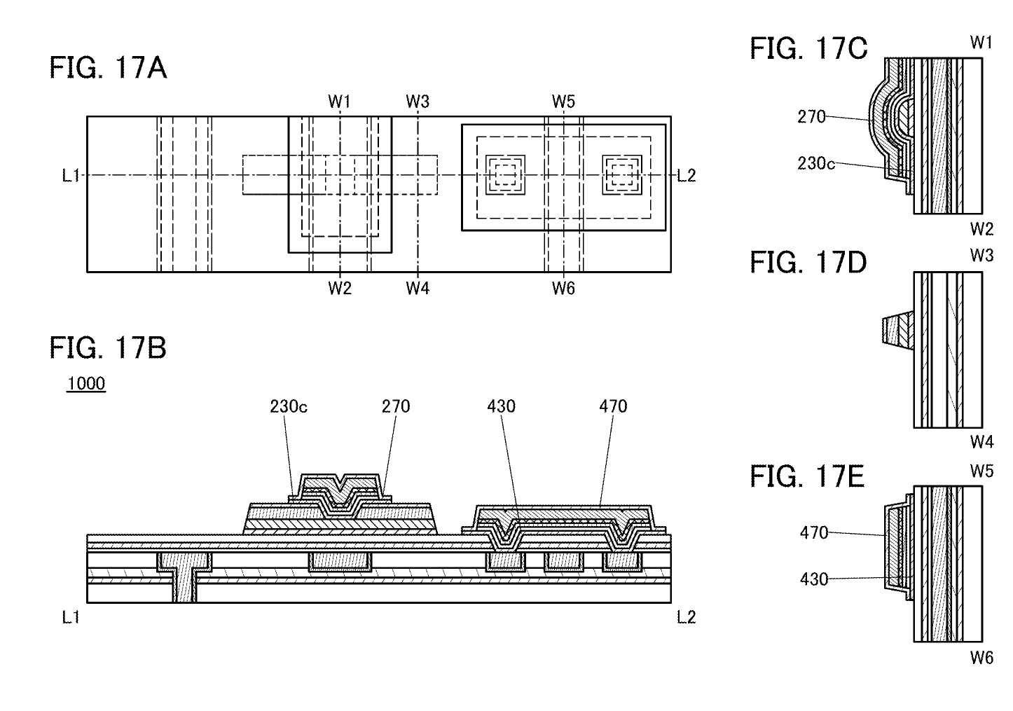

Next, the oxide film 230C is etched using the layer 270 and the layer 470 as masks (see FIG. 17(A) to FIG. 17(E)). The etching treatment in this step is performed by wet etching or the like, and in this embodiment, wet etching is performed using phosphoric acid. Thus, the island-shaped oxide 230c and the island-shaped oxide 430 are formed. Even when part of the oxide film 230C remains as a residue, it can be removed to expose the side surfaces of the oxide 230b.

Next, heat treatment is preferably performed. For the heat treatment, refer to the above description. In this embodiment, after heat treatment is performed at 400° C. in a nitrogen gas atmosphere for one hour, the nitrogen gas is replaced by an oxygen gas and another heat treatment is performed at 400° C. for one hour. By performing the heat treatment in a nitrogen gas atmosphere first, impurities such as moisture or hydrogen contained in the oxide 230 are released, so that the impurity concentration in the oxide 230 is reduced. By performing the heat treatment in an oxygen gas atmosphere next, oxygen is introduced into the oxide 230.

Next, the substrate is carried into a film deposition apparatus including a plurality of chambers, and heat treatment is performed in any of the chambers of the film deposition apparatus. For the heating atmosphere or the like of the heat treatment, refer to the conditions of the above heat treatment. For example, the heat treatment is preferably performed in an oxygen atmosphere and the pressure in the chamber is higher than or equal to 1.0×10⁻⁸ Pa and lower than or equal to 1000 Pa, preferably higher than or equal to 1.0×10⁻⁸ Pa and lower than or equal to 100 Pa, further preferably higher than or equal to 1.0×10⁻⁸ Pa and lower than or equal to 10 Pa, and still further preferably higher than or equal to 1.0×10⁻⁸ Pa and lower than or equal to 1 Pa. The heating temperature is higher than or equal to 100° C. and lower than or equal to 500° C., and preferably higher than or equal to 200° C. and lower than or equal to 450° C. Furthermore, in the case where a metal that is likely to diffuse when heated, such as Cu, is used for the conductor, the temperature is set to lower than or equal to 410° C., and preferably lower than or equal to 400° C. Note that the heating temperature is preferably higher than the substrate temperature in the deposition of the insulator 272 described later.

In this embodiment, the heat treatment is performed in an oxygen gas atmosphere at a substrate temperature of 400° C. for about five minutes. This can remove moisture such as adsorbed water before the insulator 272 is deposited. In particular, when the heat treatment is performed in an oxygen gas atmosphere, the heat treatment can be performed without the formation of oxygen vacancies in the oxide 230.

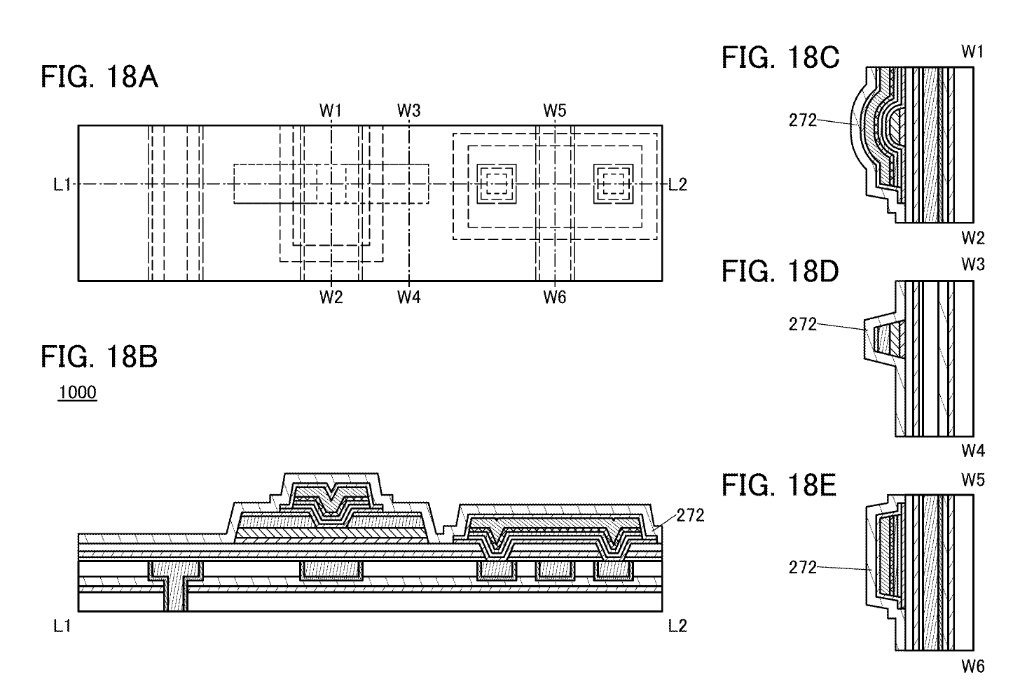

Then, the insulator 272 is deposited by a sputtering method in a different chamber of the above film deposition apparatus from the chamber in which the heat treatment is performed (see FIG. 18(A) to FIG. 18(E)). This step corresponds to Step S08 in the flow chart shown in FIG. 2. The deposition of the insulator 272 is successively performed following the heat treatment in Step S07 without exposure to the outside air. In this embodiment, the film deposition is performed so that the thickness of the insulator 272 is 5 nm or greater and 100 nm or less, preferably 5 nm or greater and 20 nm or less, and further preferably 5 nm or greater and 10 nm or less, approximately.

The insulator 272 is preferably deposited in an atmosphere containing oxygen by a sputtering method. In this embodiment, as the insulator 272, an aluminum oxide film is deposited in an atmosphere containing oxygen by a sputtering method. Accordingly, oxygen can be added to the vicinity of surfaces in contact with the insulator 272 (the side surface of the oxide 230a, the side surface of the oxide 230b, the top surface of the insulator 224, and the like), so that an oxygen excess state can be created. Although oxygen is added as an oxygen radical here, for example, the state of oxygen at the time of being added is not limited thereto. Oxygen may be added in the state of an oxygen atom, an oxygen ion, or the like. Heat treatment in a later step can diffuse oxygen so that oxygen can be supplied to the oxide 230b effectively.

Note that at the time of the deposition of the insulator 272, the substrate heating is preferably performed. The substrate heating is preferably performed at higher than 100° C. and lower than or equal to 200° C. Further preferably, the substrate heating is performed at higher than or equal to 120° C. and lower than or equal to 150° C. When the substrate temperature is higher than 100° C., water in the oxide 230 can be removed. Furthermore, surface adsorbed water can be prevented from being attached to the formed film. Furthermore, the temperature of the substrate heating is preferably as low as possible. When a film is deposited at low temperatures, a function of gettering impurities in a film that is in contact with the film deposited at low temperatures is enhanced in later heat treatment. For example, when the insulator 272 is deposited at around 130° C., hydrogen contained in the insulator 224, the oxide 230a, the oxide 230b, and the like can be gettered by the insulator 272.

Even when impurities such as water are removed by the heat treatment before the deposition of the insulator 272, impurities such as hydrogen or water may enter the oxide 230 or the like again because of exposure to the outside air before the film deposition. However, as described in this embodiment, the film deposition is successively performed following the heat treatment in the same film deposition apparatus without exposure to the outside air, so that the transistor 200 and the transistor 400 can be covered with the insulator 272 without entry of impurities such as water. Furthermore, a larger amount of oxygen can be contained when oxygen is added to a site formed by the release of impurities such as water by the heat treatment in Step S07. Furthermore, heat treatment and film deposition treatment are performed in different chambers of a multi-chamber film deposition apparatus, so that the insulator 272 can be deposited without being influenced by impurities such as water released by the heat treatment.

Furthermore, for the insulator 272, an insulating material that is less likely to transmit impurities such as water or hydrogen is preferably used, and in this embodiment, aluminum oxide is used. Furthermore, when deposited by a sputtering method, the insulator 272 can be deposited at a higher deposition rate than the insulator 274 and the thickness of a stacked-layer film of the insulator 272 and the insulator 274 can be increased with high productivity. In this manner, a barrier property against impurities such as hydrogen or water can be improved with high productivity.

Next, the insulator 274 is deposited over the insulator 272 by an ALD method (see FIG. 19(A) to FIG. 19(E)). In this embodiment, the thickness of the insulator 274 is 5 nm or greater and 20 nm or less, preferably 5 nm or greater and 10 nm or less, and further preferably 5 nm or greater and 7 nm or less, approximately.

For the insulator 274, an insulating material that is less likely to transmit impurities such as water or hydrogen is preferably used, and for example, aluminum oxide is preferably used. Moreover, the film deposition using an ALD method can suppress formation of cracks, pinholes, and the like; thus, the insulator 274 can be deposited with good coverage. Although the insulator 272 and the insulator 274 are deposited over a shape having unevenness, the deposition of the insulator 274 by an ALD method enables the transistor 200 and the transistor 400 to be covered with the insulator 274 without formation of breaks, cracks, pinholes, or the like. Thus, the barrier property against impurities such as hydrogen or water can be improved more noticeably.

Next, heat treatment is preferably performed. Refer to the above description for the heat treatment. In this embodiment, the heat treatment is performed at 400° C. in a nitrogen gas atmosphere for one hour.

By the heat treatment, in the transistor 200, oxygen contained in the insulator 224, the insulator 250, and the like can be diffused. Thus, the amount of oxygen vacancies in the oxide 230a, the oxide 230b, and the oxide 230c can be reduced. Furthermore, in the transistor 400, oxygen contained in the insulator 224, the insulator 450, and the like can be diffused and supplied to the oxide 430, particularly to a channel formation region of the oxide 430.

Here, the insulator 212, the insulator 214, the insulator 222, the insulator 272, and the insulator 274 can prevent oxygen from being diffused over and under the transistor 200 and the transistor 400; thus, oxygen can be supplied to the oxide 230b and the oxide 430 effectively.

In FIG. 25, a schematic diagram shows states of hydrogen and water in the vicinity of the side surface of the oxide 230b (region 299) when the heat treatment is performed. By performing the heat treatment, hydrogen contained in the insulator 224, the oxide 230a, the oxide 230b, and the like is gettered by the insulator 272 and diffused outward from the upper side of the insulator 274 as water.

The insulator 272 and the insulator 274 have a function of releasing hydrogen contained in the insulator 224, the oxide 230a, the oxide 230b, and the like outside the insulator 274 as water. Note that the function of gettering impurities in the film such as the oxide 230b is enhanced when the insulator 272 is deposited at low temperatures.

It can be said that the above function of the insulator 272 and the insulator 274 produces an effect similar to a catalyst. That is, it can be said that the insulator 272 and the insulator 274 each have a catalytic effect. In this manner, the amount of impurities such as hydrogen in the insulator 250, the oxide 230a, and the oxide 230b can be further reduced.

As described above, when a structure is employed in which the transistor 200 and the transistor 400 are sandwiched between the insulators 274 and 272 and the insulators 214 and 212, a large amount of oxygen can be contained in the insulator 224, the oxide 230, and the insulator 250 without outward diffusion of oxygen. Moreover, impurities such as hydrogen or water can be prevented from entering from over the insulator 274 and from under the insulator 212; thus, the impurity concentrations in the insulator 224, the oxide 230, and the insulator 250 can be lowered.

In this manner, the amount of oxygen vacancies in the oxide 230b functioning as an active layer of the transistor 200 is reduced and the amount of impurities such as hydrogen or water is reduced, so that the electrical characteristics of the transistor 200 can be stabilized and the reliability thereof can be improved.

Next, the insulator 280 is deposited over the insulator 274. In this embodiment, silicon oxide deposited by a plasma CVD method is used for the insulator 280.

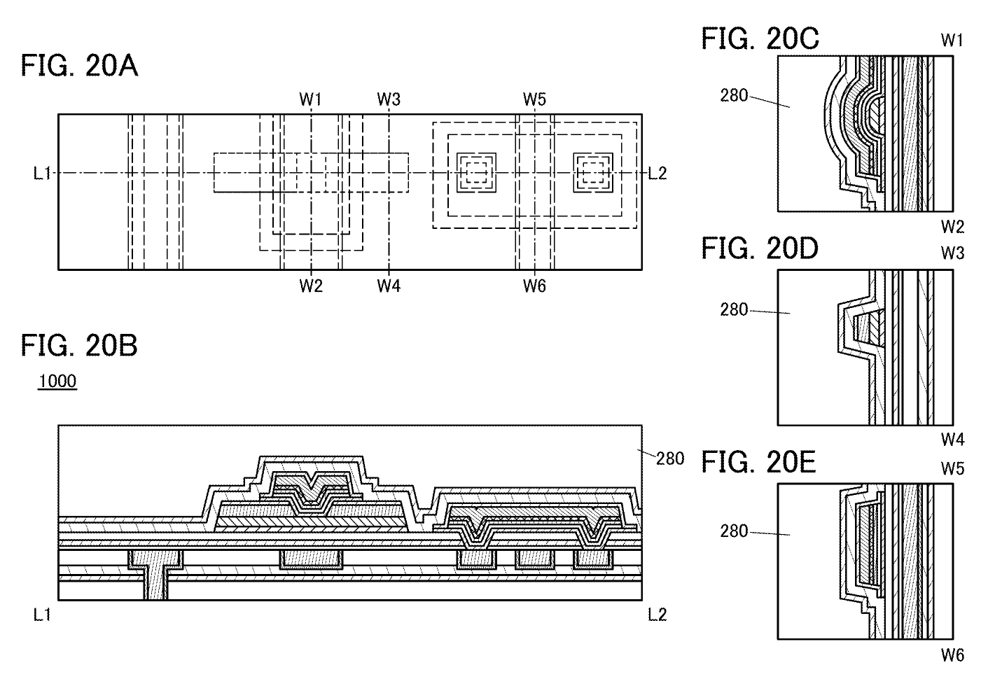

Next, CMP treatment is performed on the insulator 280 to reduce unevenness of a film surface (see FIG. 20(A) to FIG. 20(E)).

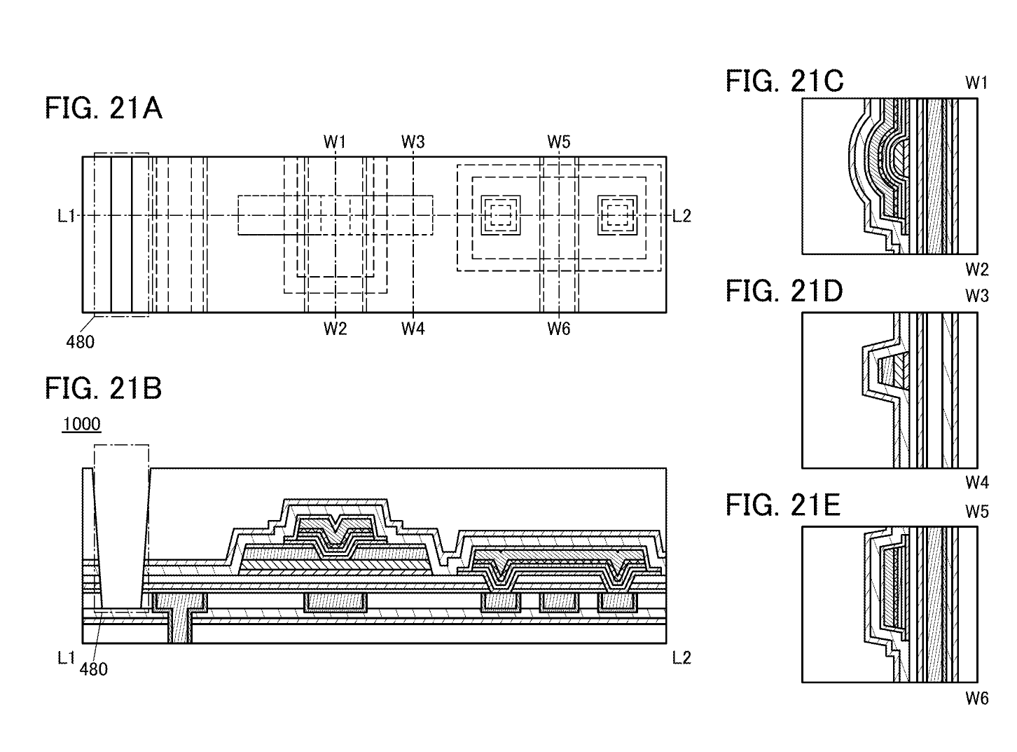

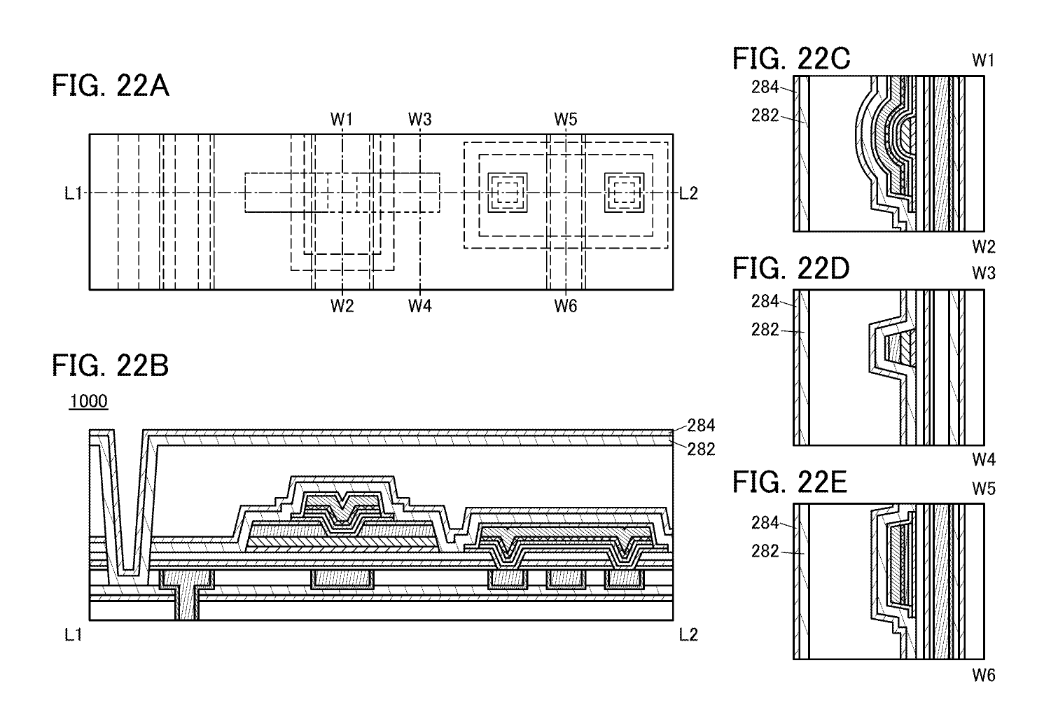

Next, in the insulator 216, the insulator 220, the insulator 222, the insulator 224, the insulator 272, the insulator 274, and the insulator 280, the opening 480 reaching the insulator 214 is formed (see FIG. 21(A) to FIG. 21(E)). Note that although only part of the opening 480 extending in the W1-W2 direction is shown in FIG. 22(A), the opening 480 is formed to surround the transistor 200 and the transistor 400.

Here, the opening 480 is preferably formed inside dicing lines or scribe lines along which the semiconductor device 1000 is cut out. In this way, even when the semiconductor device 1000 is cut out, the side surfaces of the insulator 280, the insulator 224, the insulator 216, and the like remain sealed with the insulator 282 and the insulator 284 which are formed in a later step; thus, impurities such as hydrogen or water can be prevented from entering and diffusing from these insulators into the transistor 200 and the transistor 400. Note that a structure may be employed in which a plurality of regions surrounded by the opening 480 are provided inside the dicing lines or the scribe lines and a plurality of semiconductor devices are separately sealed with the insulator 282 and the insulator 284.

Next, as in the formation step of the insulator 272, a substrate is carried into a film deposition apparatus including a plurality of chambers, and heat treatment is performed in any of the chambers of the film deposition apparatus. Accordingly, impurities such as moisture adsorbed on the substrate can be removed before the deposition of the insulator 282. Then, the insulator 282 is deposited by a sputtering method in a different chamber of the above film deposition apparatus from the chamber in which the heat treatment is performed. The deposition of the insulator 282 is successively performed following the preceding heat treatment without exposure to the outside air.

The insulator 282 is formed in contact with the top surface of the insulator 214 in the opening 480. Thus, the transistor 200 and the transistor 400 can be surrounded and sealed with the insulator 282 in not only a perpendicular direction but also a lateral direction of the substrate. Accordingly, impurities such as water or hydrogen can be prevented from diffusing from the outside of the insulator 282 into the transistor 200 and the transistor 400.

As described in this embodiment, when the deposition of the insulator 272 and the insulator 282 is successively performed following the heat treatment in the same film deposition apparatus without exposure to the outside air, the transistor 200 and the transistor 400 can be covered with the insulator 282 without entry of impurities such as water. Furthermore, a larger amount of oxygen can be contained when oxygen is added to a site formed by the release of impurities such as water in the heat treatment. Furthermore, heat treatment and film deposition treatment are performed in different chambers of a multi-chamber film deposition apparatus, so that the insulator 282 can be deposited without being influenced by impurities such as water released by the heat treatment.

Next, the insulator 284 is deposited over the insulator 282 by an ALD method (see FIG. 22(A) to FIG. 22(E)).

For the insulator 284, an insulating material that is less likely to transmit impurities such as water or hydrogen is preferably used, and for example, aluminum oxide is preferably used. Moreover, the film deposition using an ALD method can suppress formation of cracks, pinholes, and the like; thus, the insulator 284 can be deposited with good coverage. The insulator 282 can be deposited without a break or the like even in the opening 480 when deposited by an ALD method; thus, the barrier property against impurities can be further improved.

Next, heat treatment is preferably performed. By performing the heat treatment, hydrogen contained in the insulator 280 and the like is gettered by the insulator 282 and is out-diffused as water from the upper side of the insulator 284. In this manner, the amount of impurities such as hydrogen contained in the insulator 280 can be reduced.

Through the above steps, the transistor 200, the transistor 400, and the semiconductor device 1000 are formed. By the above-described fabrication method, the transistor 200 and the transistor 400 having different structures can be provided over the same substrate through substantially the same process. According to the above-described fabrication method, for example, the transistor 400 is not necessarily fabricated after the transistor 200 is fabricated; thus, the productivity of the semiconductor device can be increased.

In the transistor 200, a channel is formed in the oxide 230b, which is in contact with the oxide 230a and the oxide 230c. In the transistor 400, a channel is formed in the oxide 230c, which is in contact with the insulator 224 and the insulator 450. Thus, the transistor 400 is likely to be affected by interface scattering compared with the transistor 200. Furthermore, the electron affinity of the oxide 230c described in this embodiment is lower than the electron affinity of the oxide 230b. Accordingly, Vth of the transistor 400 can be higher than Vth of the transistor 200, and Icut of the transistor 400 can be small.

### Modification Example

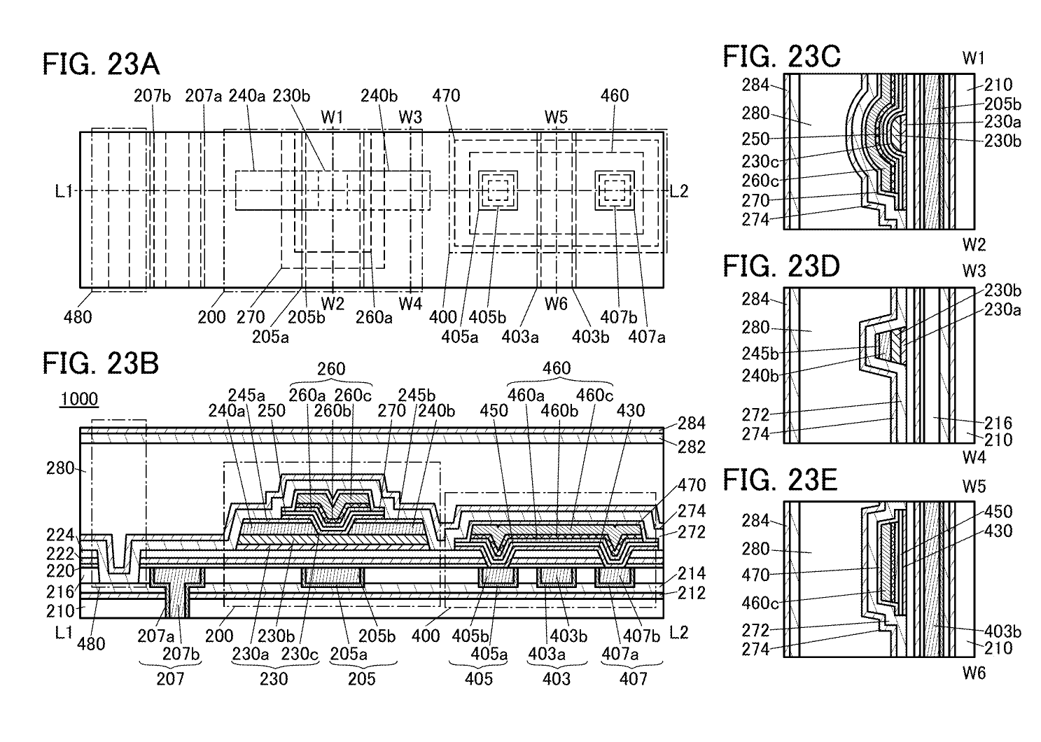

The semiconductor device described in this embodiment is not limited to that shown in FIG. 1. For example, a structure shown in FIG. 23 may be employed.

The semiconductor device 1000 shown in FIG. 23 is different from the semiconductor device 1000 shown in FIG. 1 in that the opening 480 is formed in the insulator 216, the insulator 220, the insulator 222, and the insulator 224 and the insulator 272 is in contact with a top surface of the insulator 214. Thus, a structure in which the transistor 200 and the transistor 400 are sealed with the insulator 212, the insulator 214, the insulator 272, and the insulator 274 is obtained. In this case, even when the insulator 282 and the insulator 284 are not provided, entry of impurities such as water or hydrogen from the side surfaces of the insulator 216 and the insulator 224 can be prevented.

Furthermore, the semiconductor device 1000 shown in FIG. 23 is different from the semiconductor device 1000 shown in FIG. 1 in that the layer 270, the insulator 250, and the oxide 230c extend beyond the end portions of the conductor 260 and have regions where they overlap and are in contact with each other in the extending portions and end portions of the layer 270, end portions of the insulator 250, and end portions of the oxide 230c are substantially aligned with each other. In this structure, the insulator 272 is in contact with side surfaces of the insulator 250. Accordingly, oxygen can be added from the insulator 272 to the insulator 250. Furthermore, impurities such as hydrogen contained in the insulator 250 can be gettered by the insulator 272 and diffused outward.

As described above, one embodiment of the present invention can provide a semiconductor device having high reliability. Alternatively, one embodiment of the present invention can provide a semiconductor device including an oxide with the reduced amount of impurities. Alternatively, one embodiment of the present invention can provide a semiconductor device including an oxide with the reduced amount of oxygen vacancies.

This embodiment can be implemented in appropriate combination with the structures described in the other embodiments, examples, and the like.

### Embodiment 2

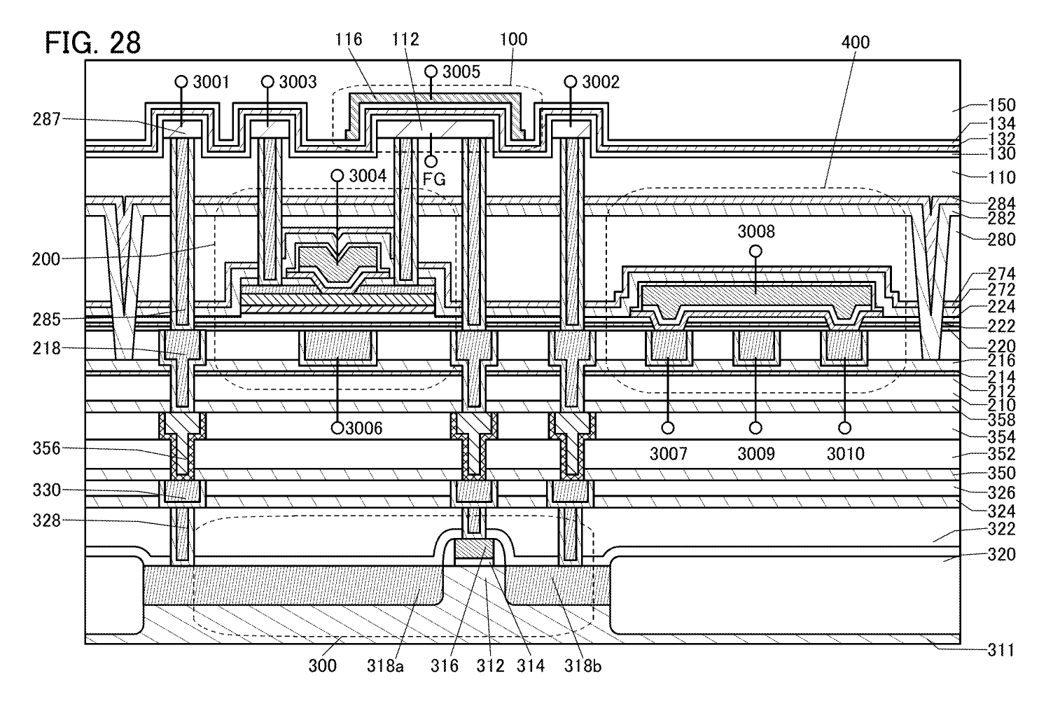

In this embodiment, embodiments of semiconductor devices will be described with reference to FIG. 28 to FIG. 30.

### [Memory Device]

An example of a memory device using the semiconductor device of one embodiment of the present invention is shown in each of FIG. 28 to FIG. 30.

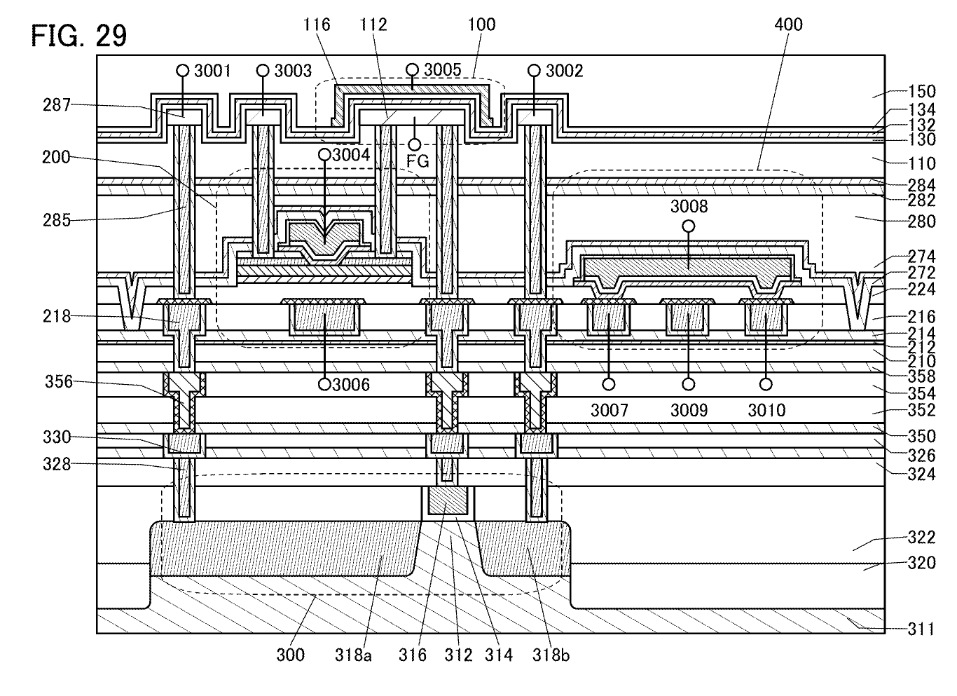

The memory devices shown in FIG. 28 and FIG. 29 each include the transistor 400, a transistor 300, the transistor 200, and a capacitor 100. Here, the transistor 200 and the transistor 400 are similar to the transistors described in Embodiment 1.

The transistor 200 is a transistor in which a channel is formed in a semiconductor layer containing an oxide. Since the off-state current of the transistor 200 is small, a memory device using it can retain stored contents for a long time. In other words, since refresh operation is not required or frequency of refresh operation is extremely low, the power consumption of the memory device can be sufficiently reduced.

Moreover, supplying a negative potential to a back gate of the transistor 200 can further reduce the off-state current of the transistor 200. In that case, with a structure in which the back gate voltage of the transistor 200 can be maintained, stored data can be retained for a long time without power supply.

The back gate voltage of the transistor 200 is controlled by the transistor 400. For example, a structure is employed in which a top gate and a back gate of the transistor 400 are diode-connected to a source thereof and the source of the transistor 400 and the back gate of the transistor 200 are connected to each other. When the negative potential of the back gate of the transistor 200 is retained in this structure, the top gate-source voltage and the back gate-source voltage of the transistor 400 each become 0 V. As described in the above embodiment, the Icut of the transistor 400 is extremely small. Thus, with this structure, the negative potential of the back gate of the transistor 200 can be held for a long time without power supply to the transistor 200 and the transistor 400. Accordingly, the memory device including the transistor 200 and the transistor 400 can retain stored contents for a long time.

In FIG. 28 and FIG. 29, a wiring 3001 is electrically connected to a source of the transistor 300, and a wiring 3002 is electrically connected to a drain of the transistor 300. Furthermore, a wiring 3003 is electrically connected to one of the source and the drain of the transistor 200, a wiring 3004 is electrically connected to the gate of the transistor 200, and a wiring 3006 is electrically connected to the back gate of the transistor 200. In addition, a gate of the transistor 300 and the other of the source and the drain of the transistor 200 are electrically connected to one electrode of the capacitor 100, and a wiring 3005 is electrically connected to the other electrode of the capacitor 100. A wiring 3007 is electrically connected to the source of the transistor 400, a wiring 3008 is electrically connected to the gate of the transistor 400, a wiring 3009 is electrically connected to the back gate of the transistor 400, and a wiring 3010 is electrically connected to the drain of the transistor 400. Here, the wiring 3006, the wiring 3007, the wiring 3008, and the wiring 3009 are electrically connected to each other.

### <Configuration 1 of Memory Device>

The memory devices shown in FIG. 28 and FIG. 29 have a feature that the potential of the gate of the transistor 300 can be retained, and thus enable writing, retaining, and reading of data as follows.

Writing and retaining of data are described. First, the potential of the wiring 3004 is set to a potential at which the transistor 200 is in a conducting state, so that the transistor 200 is brought into a conducting state. Accordingly, the potential of the wiring 3003 is supplied to a node FG where the gate of the transistor 300 and the one electrode of the capacitor 100 are electrically connected to each other. That is, a predetermined charge is supplied to the gate of the transistor 300 (writing). Here, one of charges providing two different potential levels (hereinafter, referred to as Low-level charge and High-level charge) is supplied. After that, the potential of the wiring 3004 is set to a potential at which the transistor 200 is in a non-conducting state, so that the transistor 200 is brought into a non-conducting state; thus, the charge is retained in the node FG (retaining).

In the case where the off-state current of the transistor 200 is small, the charge in the node FG is retained for a long time.

Next, reading of data is described. An appropriate potential (reading potential) is supplied to the wiring 3005 while a predetermined potential (constant potential) is supplied to the wiring 3001, whereby the wiring 3002 has a potential corresponding to the amount of charge retained in the node FG. This is because when the transistor 300 is of an n-channel type, an apparent threshold voltage Vₜₕ_{_}_{H} at the time when the High-level charge is supplied to the gate of the transistor 300 is lower than an apparent threshold voltage Vₜₕ_{_}_{L} at the time when the Low-level charge is supplied to the gate of the transistor 300. Here, an apparent threshold voltage refers to the potential of the wiring 3005 that is needed to bring the transistor 300 into a “conducting state”. Thus, the potential of the wiring 3005 is set to a potential V₀ that is between Vₜₕ_{_}_{H} and Vₜₕ_{_}_{L}, whereby the charge supplied to the node FG can be determined. For example, in the case where the High-level charge is supplied to the node FG in writing, the transistor 300 is in a “conducting state” when the potential of the wiring 3005 becomes V₀ (>Vₜₕ_{_}_{H}). On the other hand, in the case where the Low-level charge is supplied to the node FG, the transistor 300 remains in a “non-conducting state” even when the potential of the wiring 3005 becomes V₀ (<Vₜₕ_{_}_{L}). Thus, the data retained in the node FG can be read by determining the potential of the wiring 3002.

Furthermore, by arranging the memory devices shown in FIG. 28 and FIG. 29 in a matrix, a memory cell array can be formed.

Note that in the case where memory cells are arranged in an array, data of a desired memory cell needs to be read in reading. For example, when the transistor 300 is of a p-channel type, the memory cell has a NOR-type structure. Thus, only data of a desired memory cell can be read by supplying a potential at which the transistor 300 is in a “non-conducting state” regardless of the charge supplied to the node FG, that is, a potential lower than Vₜₕ_{_}_{H} to the wiring 3005 of memory cells from which data is not read. Alternatively, when the transistor 300 is of an n-channel type, the memory cell has a NAND-type structure. Thus, only data of a desired memory cell can be read by supplying a potential at which the transistor 300 is in a “conducting state” regardless of the charge supplied to the node FG, that is, a potential higher than Vₜₕ_{_}_{L} to the wiring 3005 of memory cells from which data is not read.

### <Configuration 2 of Memory Device>

The memory devices shown in FIG. 28 and FIG. 29 may each have a configuration in which the transistor 300 is not included. Also in the case where the transistor 300 is not included, writing and retaining operation of data can be performed in a manner similar to that for the operation of the memory device described above.

For example, data reading in the case where the transistor 300 is not included is described. When the transistor 200 is in a conducting state, the wiring 3003 that is in a floating state and the capacitor 100 are brought into conduction, and the charge is redistributed between the wiring 3003 and the capacitor 100. As a result, the potential of the wiring 3003 changes. The amount of change in the potential of the wiring 3003 varies depending on the potential of the one electrode of the capacitor 100 (or the charge accumulated in the capacitor 100).

For example, when the potential of the one electrode of the capacitor 100 is V, the capacitance of the capacitor 100 is C, the capacitance component of the wiring 3003 is CB, and the potential of the wiring 3003 before the charge redistribution is VB0, the potential of the wiring 3003 after the charge redistribution is (CB×VB0+CV)/(CB+C). Thus, it is found that, assuming that the memory cell is in either of two states in which the potential of the one electrode of the capacitor 100 is V1 and V0 (V1>V0), the potential of the wiring 3003 when the potential V1 is retained (=(CB×VB0+CV1)/(CB+C)) is higher than the potential of the wiring 3003 when the potential V0 is retained (=(CB×VB0+CV0)/(CB+C)).

Then, by comparing the potential of the wiring 3003 with a predetermined potential, data can be read.

In the case of employing this configuration, a transistor using silicon is used for a driver circuit for driving a memory cell, and a transistor using an oxide is stacked as the transistor 200 and positioned over the driver circuit.

When using a transistor that uses an oxide and has a small off-state current, the memory device described above can retain stored contents for a long time. In other words, since refresh operation becomes unnecessary or the frequency of refresh operation can be extremely low, a memory device with low power consumption can be achieved. Furthermore, stored contents can be retained for a long time even when power is not supplied (note that a potential is preferably fixed).

Furthermore, the memory device does not need a high voltage for data writing and thus deterioration of elements is less likely to occur. Unlike in a conventional nonvolatile memory, for example, the injection of electrons into a floating gate and the extraction of electrons from the floating gate are not performed; thus, a problem such as deterioration of an insulator is not caused. That is, unlike a conventional nonvolatile memory, the memory device of one embodiment of the present invention does not have a limit on the number of times data can be rewritten and the reliability of the memory device is drastically improved. Moreover, data is written depending on the conducting state and the non-conducting state of the transistor, which enables high-speed operation.

### <Structure 1 of Memory Device>

An example of the memory device of one embodiment of the present invention is shown in FIG. 28. The memory device includes the transistor 400, the transistor 300, the transistor 200, and the capacitor 100. The transistor 200 is provided over the transistor 300, and the capacitor 100 is provided over the transistor 300 and the transistor 200.

The transistor 300 is provided over a substrate 311 and includes a conductor 316, an insulator 314, a semiconductor region 312 that is part of the substrate 311, and a low-resistance region 318a and a low-resistance region 318b functioning as a source region and a drain region.

The transistor 300 is of either a p-channel type or an n-channel type.

A region of the semiconductor region 312 where a channel is formed, a region in the vicinity thereof, the low-resistance region 318a and the low-resistance region 318b functioning as the source region and the drain region, and the like preferably include a semiconductor such as a silicon-based semiconductor, and preferably include single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing. Alternatively, the transistor 300 may be a HEMT (High Electron Mobility Transistor) with the use of GaAs and GaAlAs, or the like.

The low-resistance region 318a and the low-resistance region 318b include an element that imparts n-type conductivity, such as arsenic or phosphorus, or an element that imparts p-type conductivity, such as boron, in addition to a semiconductor material used for the semiconductor region 312.

For the conductor 316 functioning as a gate electrode, a semiconductor material such as silicon including an element that imparts n-type conductivity, such as arsenic or phosphorus, or an element that imparts p-type conductivity, such as boron, or a conductive material such as a metal material, an alloy material, or a metal oxide material can be used.

Note that the work function is determined by a material for the conductor, whereby the threshold voltage can be adjusted. Specifically, it is preferable to use a material such as titanium nitride or tantalum nitride for the conductor. Moreover, in order to ensure both conductivity and embeddability, it is preferable to use a stacked layer of metal materials such as tungsten and aluminum as the conductor, and it is particularly preferable to use tungsten in terms of heat resistance.

Note that the transistor 300 shown in FIG. 28 is an example and the structure is not limited to that illustrated therein; an appropriate transistor is used in accordance with a circuit configuration or a driving method. Furthermore, when the configuration described in <Configuration 2 of memory device> is employed, the transistor 300 is not necessarily provided.

An insulator 320, an insulator 322, an insulator 324, and an insulator 326 are stacked in this order and provided to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride is used, for example.

The insulator 322 may have a function as a planarization film for planarizing a level difference caused by the transistor 300 or the like provided thereunder. For example, the top surface of the insulator 322 may be planarized by planarization treatment using a CMP method or the like to increase the level of planarity.

Furthermore, as the insulator 324, a film having a barrier property that prevents hydrogen and impurities from diffusing from the substrate 311, the transistor 300, or the like into regions where the transistor 200 and the transistor 400 are provided is preferably used. Here, a barrier property refers to a function of inhibiting diffusion of impurities typified by hydrogen and water. For example, the diffusion length of hydrogen in the film having a barrier property per hour under an atmosphere at 350° C. or 400° C. is less than or equal to 50 nm. The diffusion length of hydrogen in the film having a barrier property per hour under an atmosphere at 350° C. or 400° C. is preferably less than or equal to 30 nm, further preferably less than or equal to 20 nm.

As an example of the film having a barrier property against hydrogen, silicon nitride formed by a CVD method can be used. Here, the diffusion of hydrogen into a semiconductor element including an oxide, such as the transistor 200, degrades the characteristics of the semiconductor element in some cases. Thus, a film that inhibits the diffusion of hydrogen is preferably used between the transistors 200 and 400 and the transistor 300. The film that inhibits the diffusion of hydrogen is specifically a film from which the released amount of hydrogen is small.

The released amount of hydrogen can be analyzed by TDS, for example. The released amount of hydrogen from the insulator 324 that is the released amount converted into hydrogen molecules per area of the insulator 324 is less than or equal to 2×10¹⁵ molecules/cm², preferably less than or equal to 1×10¹⁵ molecules/cm², and further preferably less than or equal to 5×10¹⁴ molecules/cm² in TDS analysis in the range from 50° C. to 500° C., for example.

Note that the dielectric constant of the insulator 326 is preferably lower than that of the insulator 324. For example, the relative dielectric constant of the insulator 326 is preferably lower than 4, further preferably lower than 3. Furthermore, for example, the relative dielectric constant of the insulator 324 is preferably 0.7 times or less, further preferably 0.6 times or less the relative dielectric constant of the insulator 326. When a material with a low dielectric constant is used for an interlayer film, the parasitic capacitance generated between wirings can be reduced.

Furthermore, a conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 each have a function as a plug or a wiring. Furthermore, a plurality of structures of conductors having functions as plugs or wirings are collectively denoted by the same reference numeral in some cases, as described later. Furthermore, in this specification and the like, a wiring and a plug electrically connected to the wiring may be a single component. That is, part of a conductor functions as a wiring in some cases and part of a conductor functions as a plug in other cases.

As a material for each of plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 28, an insulator 350, an insulator 352, and an insulator 354 are provided and stacked in this order. Furthermore, a conductor 356 is formed in the insulator 350, the insulator 352, and the insulator 354. The conductor 356 has a function as a plug or a wiring. Note that the conductor 356 can be provided using a material similar to that for the conductor 328 and the conductor 330.

Note that for example, as the insulator 350, an insulator having a barrier property against hydrogen is preferably used, as with the insulator 324. Furthermore, the conductor 356 preferably includes a conductor having a barrier property against hydrogen. In particular, the conductor having a barrier property against hydrogen is formed in an opening portion of the insulator 350 having a barrier property against hydrogen. With this structure, the transistor 300 can be separated from the transistor 200 and the transistor 400 by a barrier layer, so that the diffusion of hydrogen from the transistor 300 into the transistor 200 and the transistor 400 can be inhibited.

Note that as the conductor having a barrier property against hydrogen, tantalum nitride is preferably used, for example. Furthermore, by stacking tantalum nitride and tungsten, which has high conductivity, the diffusion of hydrogen from the transistor 300 can be inhibited while the conductivity of a wiring is kept. In this case, a structure in which a tantalum nitride layer having a barrier property against hydrogen is in contact with the insulator 350 having a barrier property against hydrogen is preferable.

An insulator 358, the insulator 210, the insulator 212, the insulator 214, and the insulator 216 are stacked in this order and provided over the insulator 354. A substance having a barrier property against oxygen or hydrogen is preferably used for one of the insulator 358, the insulator 210, the insulator 212, the insulator 214, and the insulator 216.

For the insulator 358, the insulator 212, and the insulator 214, for example, a film having a barrier property that prevents hydrogen and impurities from diffusing from the substrate 311, a region where the transistor 300 is provided, or the like into the regions where the transistor 200 and the transistor 400 are provided is preferably used. Thus, a material similar to that for the insulator 324 can be used.

Furthermore, as an example of the film having a barrier property against hydrogen, silicon nitride formed by a CVD method can be used. Here, the diffusion of hydrogen into a semiconductor element including an oxide, such as the transistor 200, degrades the characteristics of the semiconductor element in some cases. Thus, a film that inhibits the diffusion of hydrogen is preferably used between the transistors 200 and 400 and the transistor 300. The film that inhibits the diffusion of hydrogen is specifically a film from which the released amount of hydrogen is small.

Furthermore, as the film having a barrier property against hydrogen, for example, as the insulator 212 and the insulator 214, a metal oxide such as aluminum oxide, hafnium oxide, or tantalum oxide is preferably used.

In particular, aluminum oxide has an excellent blocking effect that prevents the passage of oxygen and impurities such as hydrogen and moisture that become factors of a change in electrical characteristics of the transistor. Accordingly, aluminum oxide can prevent entry of impurities such as hydrogen and moisture into the transistor 200 and the transistor 400 in a fabrication process and after the fabrication of the transistors. Furthermore, release of oxygen from the oxide included in the transistor 200 can be inhibited. Thus, aluminum oxide is suitably used as a protective film for the transistor 200 and the transistor 400.

Furthermore, for example, a material similar to that for the insulator 320 can be used for the insulator 210 and the insulator 216. Furthermore, when interlayer films formed of a material with a relatively low dielectric constant are used as the insulating films, the parasitic capacitance generated between wirings can be reduced. For example, a silicon oxide film or a silicon oxynitride film can be used as the insulator 216.

Furthermore, a conductor 218, conductors included in the transistor 200 and the transistor 400 (the conductor 205, the conductor 405, the conductor 403, and the conductor 407), and the like are embedded in the insulator 358, the insulator 210, the insulator 212, the insulator 214, and the insulator 216. Note that the conductor 218 has a function as a plug or a wiring that is electrically connected to the capacitor 100 or the transistor 300. The conductor 218 can be provided using a material similar to that for the conductor 328 and the conductor 330.

In particular, the conductor 218 in a region in contact with the insulator 358, the insulator 212, and the insulator 214 is preferably a conductor having a barrier property against oxygen, hydrogen, and water. With this structure, the transistor 300 and the transistor 200 can be completely and further separated by the layer having a barrier property against oxygen, hydrogen, and water, so that the diffusion of hydrogen from the transistor 300 into the transistor 200 and the transistor 400 can be inhibited.

The transistor 200 and the transistor 400 are provided over the insulator 216. Note that as the transistor 200 and the transistor 400, the transistor 200 and the transistor 400 described in Embodiment 1 are preferably used.

An insulator 110 is provided over the transistor 200 and the transistor 400. A material similar to that for the insulator 320 can be used for the insulator 110. Furthermore, when an interlayer film formed of a material with a relatively low dielectric constant is used for the insulating film, the parasitic capacitance generated between wirings can be reduced. For example, a silicon oxide film or a silicon oxynitride film can be used as the insulator 110.

Furthermore, a conductor 285 and the like are embedded in the insulator 220, the insulator 222, the insulator 224, the insulator 272, the insulator 274, and the insulator 110.

The conductor 285 has a function as a plug or a wiring that is electrically connected to the capacitor 100, the transistor 200, or the transistor 300. The conductor 285 can be provided using a material similar to that for the conductor 328 and the conductor 330.

For example, in the case where the conductor 285 is provided to have a stacked-layer structure, a conductor that is less likely to be oxidized (that has high oxidation resistance) is preferably included. In particular, a conductor having high oxidation resistance is preferably provided in a region in contact with the insulator 224 including an excess-oxygen region. Such a structure can prevent the conductor 285 from absorbing excess oxygen from the insulator 224. Furthermore, the conductor 285 preferably includes a conductor having a barrier property against hydrogen. In particular, when a conductor having a barrier property against impurities such as hydrogen is provided in a region in contact with the insulator 224 including an excess-oxygen region, the diffusion of impurities in the conductor 285 and part of the conductor 285 and the formation of a diffusion path of impurities from the outside can be inhibited.

Furthermore, a conductor 287, the capacitor 100, and the like are provided over the insulator 110 and the conductor 285. Note that the capacitor 100 includes a conductor 112, an insulator 130, an insulator 132, an insulator 134, and a conductor 116. The conductor 112 and the conductor 116 each have a function as an electrode of the capacitor 100, and the insulator 130, the insulator 132, and the insulator 134 each have a function as a dielectric of the capacitor 100.

The conductor 287 has a function as a plug or a wiring that is electrically connected to the capacitor 100, the transistor 200, or the transistor 300. Furthermore, the conductor 112 has a function as the one electrode of the capacitor 100. Note that the conductor 287 and the conductor 112 can be formed at the same time.

For the conductor 287 and the conductor 112, a metal film containing an element selected from molybdenum, titanium, tantalum, tungsten, aluminum, copper, chromium, neodymium, and scandium; a metal nitride film containing any of the above elements as its component (a tantalum nitride, a titanium nitride film, a molybdenum nitride film, or a tungsten nitride film); or the like can be used. Alternatively, a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can be used.

The insulator 130, the insulator 132, and the insulator 134 can be provided to have a stacked layer or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, in the case where a high dielectric constant (high-k) material such as aluminum oxide is used for the insulator 132, the capacitance per unit area of the capacitor 100 can be increased. Furthermore, a material having high dielectric strength, such as silicon oxynitride, is preferably used for the insulator 130 and the insulator 134. When a high dielectric is sandwiched between insulators having high dielectric strength, electrostatic breakdown of the capacitor 100 can be inhibited and the capacitor can have large capacitance.

Furthermore, the conductor 116 is provided to cover the side surfaces and the top surface of the conductor 112 with the insulator 130, the insulator 132, and the insulator 134 positioned therebetween. With this structure, the side surfaces of the conductor 112 are wrapped in the conductor 116 with the insulators positioned therebetween. With this structure, capacitance is also formed on the side surfaces of the conductor 112, so that the capacitance per projected area of the capacitor can be increased. Thus, the memory device can be reduced in area, highly integrated, and miniaturized.

Note that for the conductor 116, a conductive material such as a metal material, an alloy material, or a metal oxide material can be used. It is preferable to use a high-melting-point material that has both heat resistance and conductivity, such as tungsten or molybdenum, and it is particularly preferable to use tungsten. Furthermore, in the case where the conductor 116 is formed concurrently with another component such as a conductor, Cu (copper), Al (aluminum), or the like, which is a low-resistance metal material, is used.

An insulator 150 is provided over the conductor 116 and the insulator 134. The insulator 150 can be provided using a material similar to that for the insulator 320. Furthermore, the insulator 150 may function as a planarization film that covers uneven shapes thereunder.

The above is the description of the structure example. With the use of this structure, a change in electrical characteristics can be suppressed and reliability can be improved in a memory device using a transistor including an oxide. Alternatively, a transistor including an oxide with a large on-state current can be provided. Alternatively, a transistor including an oxide with a small off-state current can be provided. Alternatively, a memory device with reduced power consumption can be provided.

### Modification Example 1

One example of a modification example of the memory device is shown in FIG. 29. FIG. 29 is different from FIG. 29 in the structure of the transistor 300, the shapes of the insulator 272 and the insulator 274, and the like.

In the transistor 300 shown in FIG. 29, the semiconductor region 312 (part of the substrate 311) in which a channel is formed has a convex shape. Furthermore, the conductor 316 is provided to cover the side surfaces and the top surface of the semiconductor region 312 with the insulator 314 positioned therebetween. Note that for the conductor 316, a material that adjusts the work function may be used. Such a transistor 300 is also referred to as a FIN-type transistor because it utilizes a convex portion of the semiconductor substrate. Note that an insulator functioning as a mask for forming the convex portion may be included in contact with an upper portion of the convex portion. Furthermore, although the case where the convex portion is formed by processing part of the semiconductor substrate is described here, a semiconductor film having a convex shape may be formed by processing an SOI substrate.

The use of a combination of the transistor 300 having such a structure and the transistor 200 enables a reduction in area, high integration, and miniaturization.

Furthermore, as shown in FIG. 29, the insulator 220 and the insulator 222 are not necessarily provided. Such a structure can increase the productivity.

Furthermore, as shown in FIG. 29, a structure may be employed in which the bottom surface of the insulator 272 and the top surface of the insulator 214 are in contact with each other in openings formed in the insulator 216 and the insulator 224.

The above is the description of the modification example. With the use of this structure, a change in electrical characteristics can be suppressed and reliability can be improved in a memory device using a transistor including an oxide. Alternatively, a transistor including an oxide with a large on-state current can be provided. Alternatively, a transistor including an oxide with a small off-state current can be provided. Alternatively, a memory device with reduced power consumption can be provided.

### Modification Example 2

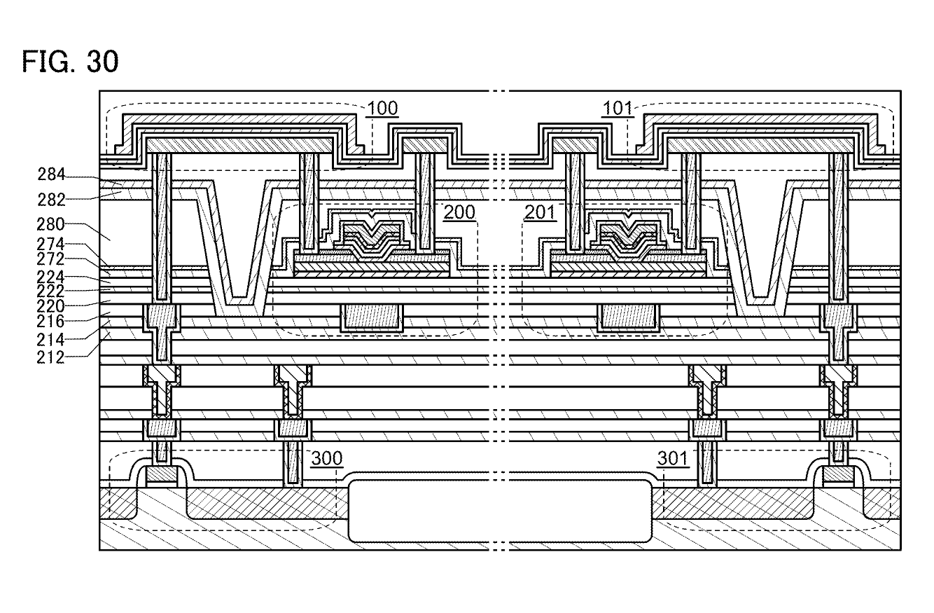

Furthermore, one example of a modification example of this embodiment is shown in FIG. 30. FIG. 30 is a cross-sectional view that illustrates an extracted part of a row in which the memory devices each of which is shown in FIG. 30 are arranged in a matrix.

In FIG. 30, the memory device that includes the transistor 300, the transistor 200, and the capacitor 100 and a memory device that includes a transistor 301, a transistor 201, and a capacitor 101 are arranged in the same row.

As shown in FIG. 30, a structure may be employed in which a plurality of transistors (the transistor 200 and the transistor 201 in the figure) and the insulator 224 including an excess-oxygen region are wrapped in a stacked-layer structure of the insulator 212 and the insulator 214 and a stacked-layer structure of the insulator 282 and the insulator 284. At that time, a structure in which the insulator 212 and the insulator 214 are stacked and the insulator 282 and the insulator 284 are stacked is preferably formed between the transistor 200 or the transistor 201 and a through electrode that connects the transistor 300 or the transistor 301 and the capacitor 100 or the capacitor 101.

Note that an opening provided in the insulator 216, the insulator 220, the insulator 222, the insulator 224, the insulator 272, the insulator 274, and the insulator 280 can be provided at the same time as the opening 480 described in Embodiment 1.

Thus, oxygen released from the insulator 224, the transistor 200, and the transistor 201 can be inhibited from diffusing into the layer where the capacitor 100 and the capacitor 101 or the transistor 300 and the transistor 301 are formed. Alternatively, impurities such as hydrogen and water can be inhibited from diffusing from a layer over the insulator 282 and a layer under the insulator 214 into the transistor 200 or the transistor 201.

That is, oxygen can be efficiently supplied from the excess-oxygen region of the insulator 224 to oxides where channels are formed in the transistor 200 and the transistor 201, so that the amount of oxygen vacancies can be reduced. Furthermore, oxygen vacancies can be prevented from being formed by impurities in the oxide where a channel is formed in the transistor 200. Thus, the oxides where channels are formed in the transistor 200 and the transistor 201 can each be an oxide with a low density of defect states and stable characteristics. That is, a change in electrical characteristics of the transistor 200 and the transistor 201 can be suppressed and the reliability thereof can be improved.

At least part of this embodiment can be implemented in appropriate combination with the other embodiments described in this specification.

### Embodiment 3

### <Manufacturing Apparatus>

A manufacturing apparatus of one embodiment of the present invention that performs high-density plasma treatment will be described below.

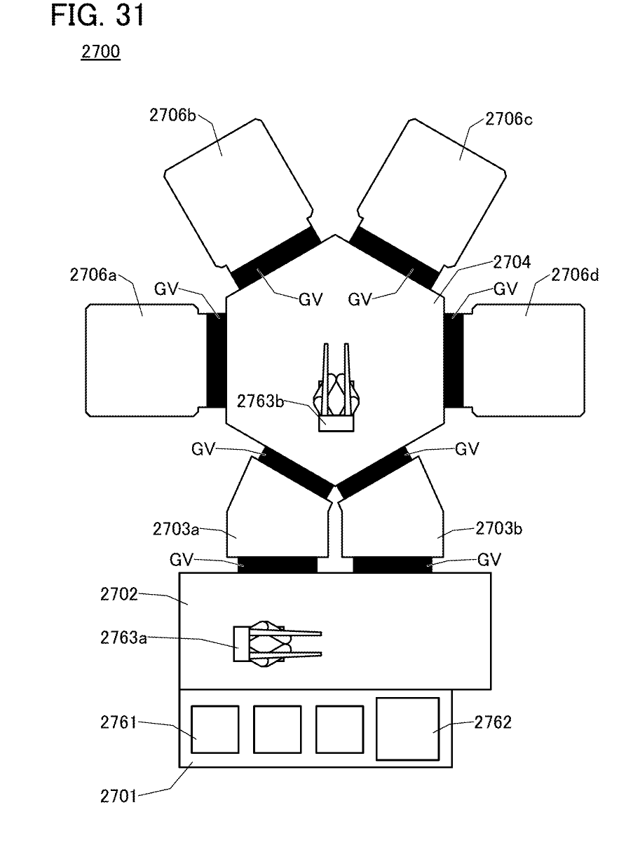

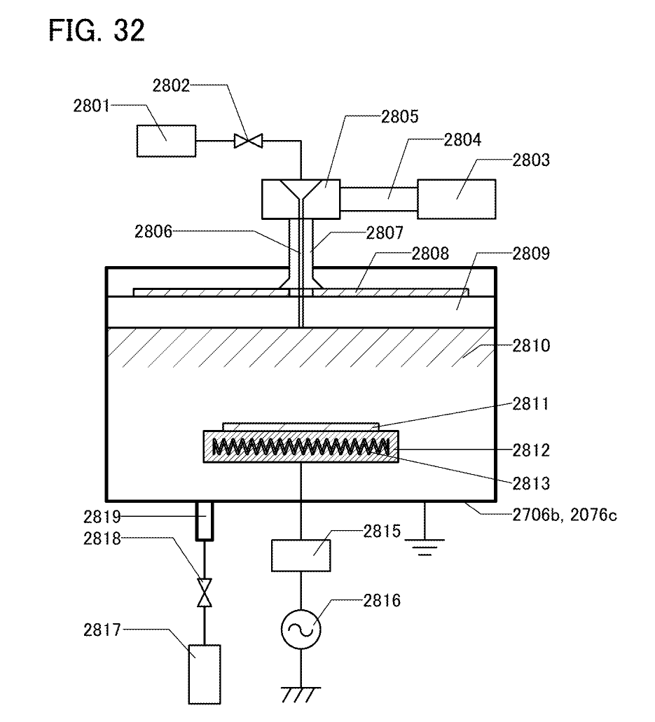

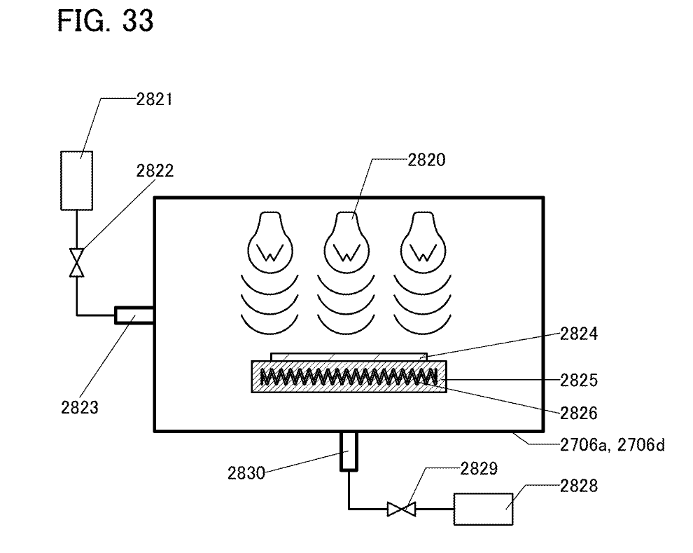

First, a structure of a manufacturing apparatus that allows entry of few impurities in manufacturing a semiconductor device or the like will be described with reference to FIG. 31, FIG. 32, and FIG. 33.

FIG. 31 schematically shows a top view of a single wafer multi-chamber manufacturing apparatus 2700. The manufacturing apparatus 2700 includes an atmosphere-side substrate supply chamber 2701 including a cassette port 2761 for storing substrates and an alignment port 2762 for performing alignment of substrates; an atmosphere-side substrate transfer chamber 2702 through which a substrate is transferred from the atmosphere-side substrate supply chamber 2701; a load lock chamber 2703a where a substrate is carried in and the pressure inside the chamber is switched from atmospheric pressure to reduced pressure or from reduced pressure to atmospheric pressure; an unload lock chamber 2703b where a substrate is carried out and the pressure inside the chamber is switched from reduced pressure to atmospheric pressure or from atmospheric pressure to reduced pressure; a transfer chamber 2704 through which a substrate is transferred in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that each chamber excluding the atmosphere-side substrate supply chamber 2701 and the atmosphere-side substrate transfer chamber 2702 can be independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, and further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, and further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, and further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, and further preferably lower than or equal to 3×10⁻⁶ Pa.

Note that the total pressure and the partial pressure in the transfer chamber 2704 and each of the chambers can be measured using a mass analyzer. For example, Qulee CGM-051, a quadrupole mass analyzer (also referred to as Q-mass) produced by ULVAC, Inc. can be used.

Furthermore, the transfer chamber 2704 and the chambers each desirably have a structure in which the amount of external leakage or internal leakage is small. For example, the leakage rate in the transfer chamber 2704 and each of the chambers is less than or equal to 3×10⁻⁶ Pa˜m³/s, and preferably less than or equal to 1×10⁻⁶ Pa˜m³/s. Furthermore, for example, the leakage rate of a gas molecule (atom) having m/z of 18 is less than or equal to 1×10⁻⁷ Pa˜m³/s, and preferably less than or equal to 3×10⁻⁸ Pa˜m³/s. Furthermore, for example, the leakage rate of a gas molecule (atom) having m/z of 28 is less than or equal to 1×10⁻⁵ Pa˜m³/s, and preferably less than or equal to 1×10⁻⁶ Pa˜m³/s. Furthermore, for example, the leakage rate of a gas molecule (atom) having m/z of 44 is less than or equal to 3×10⁻⁶ Pa˜m³/s, and preferably less than or equal to 1×10⁻⁶ Pa˜m³/s.

Note that a leakage rate can be derived from the total pressure and partial pressure measured using the above-described mass analyzer. The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with the use of the metal covered with iron fluoride, aluminum oxide, chromium oxide, or the like, which is in the passive state, the release of gas containing impurities released from the metal gasket is suppressed, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing iron, chromium, nickel, and the like covered with the above-described material may be used. The alloy containing iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to suppress release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump with high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a rare gas is preferably used as the inert gas.

Alternatively, treatment for evacuating the transfer chamber 2704 and each of the chambers is preferably performed a certain period of time after a heated inert gas such as a rare gas, heated oxygen, or the like is introduced to increase the pressure in the transfer chamber 2704 and each of the chambers. The introduction of the heated gas can desorb the adsorbed substance in the transfer chamber 2704 and each of the chambers, and the amount of impurities present in the transfer chamber 2704 and each of the chambers can be reduced. Note that this treatment is effective when repeated more than or equal to 2 times and less than or equal to 30 times, and preferably more than or equal to 5 times and less than or equal to 15 times. Specifically, an inert gas, oxygen, or the like with a temperature higher than or equal to 40° C. and lower than or equal to 400° C., and preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, and further preferably higher than or equal to 5 Pa and lower than or equal to 100 Pa in the time range of 1 minute to 300 minutes, and preferably 5 minutes to 120 minutes. After that, the transfer chamber 2704 and each of the chambers are evacuated in the time range of 5 minutes to 300 minutes, and preferably 10 minutes to 120 minutes.

Next, the chamber 2706b and the chamber 2706c will be described with reference to a schematic cross-sectional view shown in FIG. 32.

The chamber 2706b and the chamber 2706c are chambers that can perform high-density plasma treatment on an object, for example. Note that the chamber 2706b is different from the chamber 2706c only in the atmosphere in performing the high-density plasma treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is positioned in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 281 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function as an electrostatic chuck or a mechanical chuck for holding the substrate 2811. Furthermore, the substrate holder 2812 has a function as an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2827, a cryotrap may be used. The use of the cryopump and the cryotrap is particularly preferable because water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is −80° C. or lower, and preferably −100° C. or lower is preferably used. For example, an oxygen gas, a nitrogen gas, or a rare gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high density region of high-density plasma 2810 described later; thus, provision of the protective layer can reduce the damage. Consequently, an increase in the number of particles or the like during the treatment can be suppressed.

The high-frequency generator 2803 has a function of generating a microwave of, for example, more than or equal to 0.3 GHz and less than or equal to 3.0 GHz, more than or equal to 0.7 GHz and less than or equal to 1.1 GHz, or more than or equal to 2.2 GHz and less than or equal to 2.8 GHz. The microwave generated by the high-frequency generator 2803 is propagated to the mode converter 2805 through the waveguide 2804. The mode converter 2805 converts the microwave propagated in the TE mode into a microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals or nitrogen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b, oxygen radical treatment using the high-density plasma 2810 can be performed by introducing oxygen from the gas supply source 2801, and in the chamber 2706c, nitrogen radical treatment using the high-density plasma 2810 can be performed by introducing nitrogen from the gas supply source 2801.

Next, the chamber 2706a and the chamber 2706d will be described with reference to a schematic cross-sectional view shown in FIG. 33.

The chamber 2706a and the chamber 2706d are chambers that can irradiate an object with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or a plurality of lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is provided to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak in a wavelength of longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may generate heat in the substrate holder 2825 to heat the substrate 2824. In this case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

With the use of the above-described manufacturing apparatus, the quality of a film or the like can be modified while the entry of impurities into an object is suppressed.

The structures and methods described in this embodiment can be used in appropriate combination with the structures and methods described in the other embodiments.

### Example 1

In this example, SIMS analysis was performed using a stacked-layer structure of an oxide and an insulator of one embodiment of the present invention. Note that Sample 1A to Sample 1C were fabricated in this example.

### <1. Structure and Fabrication Method of Samples>

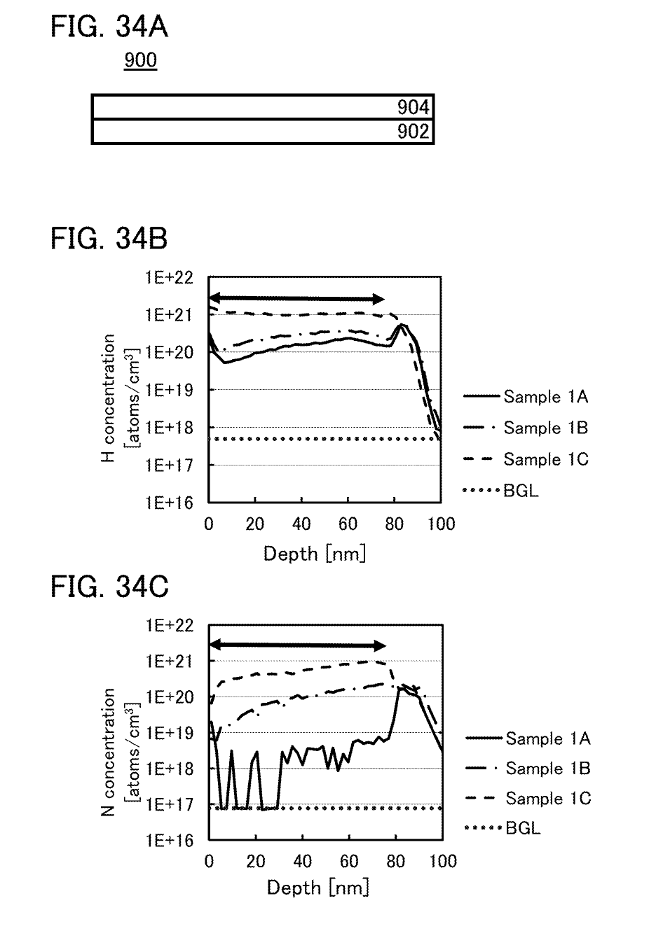

Sample 1A, Sample 1B, and Sample 1C of one embodiment of the present invention will be described below. Sample 1A to Sample 1C each include a substrate 902 and an insulator 904 over the substrate 902 as a structure 900 shown in FIG. 34(A).

Here, Sample 1A is a sample in which the insulator 904 was subjected to microwave-excited plasma treatment while an RF bias was applied to the substrate. Sample 1B is a sample in which the insulator 904 was subjected to the microwave-excited plasma treatment without an RF bias. Sample 1C is a comparative sample in which the insulator 904 was not subjected to the microwave-excited plasma treatment.

Next, a method for fabricating the samples will be described.

First, a silicon substrate is prepared as the substrate 902. Then, a 100-nm-thick silicon oxynitride film was formed as the insulator 904 over the substrate 902 by a plasma CVD method. As deposition gases, silane (SiH₄) at a flow rate of 8 sccm and dinitrogen monoxide (N₂O) at a flow rate of 4000 sccm were used. Furthermore, the film deposition was performed under the conditions where the pressure in a reaction chamber was 800 Pa, the substrate surface temperature was 325° C., and a high-frequency (RF) power of 150 W (60 MHz) was applied.

Next, the microwave-excited plasma treatment was performed on Sample 1A and Sample 1B with a microwave plasma treatment apparatus for 60 minutes. The microwave-excited plasma treatment was performed under an atmosphere of argon (Ar) at a flow rate of 150 sccm and oxygen (O₂) at a flow rate of 50 sccm. Furthermore, the pressure in the reaction chamber was 60 Pa, a high-frequency (RF) bias of 13.56 MHz was applied, and plasma was generated with a microwave of 4000 W (2.45 GHz). Note that as the microwave plasma treatment apparatus, a μ-wave plasma treatment apparatus produced by Tokyo Electron Limited (Triase+SPAi−RB×2chSystem) was used.

In the step of the microwave-excited plasma treatment on Sample 1A, plasma treatment was performed while a high-frequency (RF) bias of 600 W was applied.

Through the above steps, Sample 1A to Sample 1C of this example were fabricated.

### <2. SIMS Measurement Results of Samples>

Next, FIG. 34(B) and FIG. 34(C) show measurement results of hydrogen (H) concentration and nitrogen (N) concentration obtained by SIMS analysis performed on Sample 1A to Sample 1C. Note that the hydrogen concentration evaluation was performed by secondary ion mass spectrometry (Secondary Ion Mass Spectrometry: SIMS) with the use of a dynamic SIMS apparatus PHI ADEPT-1010 produced by ULVAC-PHI, Inc. as an analysis apparatus.

FIG. 34(B) shows hydrogen (H) concentration profiles in the depth direction of the film. Note that a double-headed arrow in the figure shows the range of the insulator 904 that is a quantified layer, and a broken line shows a background level (BGL).

The H concentration of each of Sample 1A and Sample 1B was found to be lower than that of Sample 1C. That is, the H concentration in the insulator can be reduced by the microwave-excited plasma treatment performed with the microwave plasma treatment apparatus. Moreover, the H concentration in the insulator can be further reduced when the microwave-excited plasma treatment is performed while a bias is applied.

FIG. 34(C) shows nitrogen (N) concentration profiles in the depth direction of the film. Note that a double-headed arrow in the figure shows the range of the insulator 904 that is a quantified layer, and a broken line shows a background level (BGL).

The N concentration of each of Sample 1A and Sample 1B was found to be lower than that of Sample 1C. That is, the N concentration in the insulator can be reduced by the microwave-excited plasma treatment performed with the microwave plasma treatment apparatus. Moreover, the N concentration in the insulator can be reduced more effectively when the microwave-excited plasma treatment is performed while a bias is applied.

The structure described in this example can be used in appropriate combination with the other examples or the other embodiments.

### Example 2

In this example, the released amounts of hydrogen (H₂), water (H₂O), nitrogen monoxide (NO), and oxygen (O₂) were evaluated using a stacked-layer structure of an oxide and insulators of one embodiment of the present invention. Note that Sample 2A to Sample 2D were fabricated in this example.

### <1. Structure and Fabrication Method of Samples>

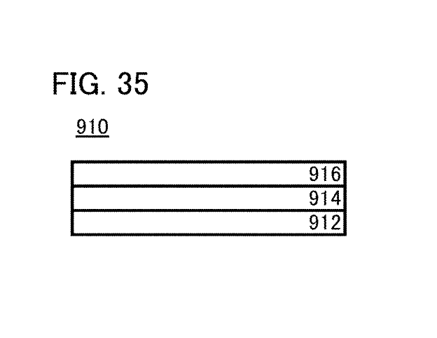

Sample 2A, Sample 2B, Sample 2C, and Sample 2D of one embodiment of the present invention will be described below. Sample 2A to Sample 2D each include a substrate 912, an insulator 914 over the substrate 912, and an insulator 916 over the insulator 914 as a structure 910 shown in FIG. 35.

Here, Sample 2A is a sample in which the insulator 916 was subjected to the microwave-excited plasma treatment while an RF bias of 600 W was applied to the substrate. Here, Sample 2B is a sample in which the insulator 916 was subjected to the microwave-excited plasma treatment while an RF bias of 300 W was applied to the substrate. Sample 2C is a sample in which the insulator 916 was subjected to the microwave-excited plasma treatment without an RF bias. Sample 2D is a comparative sample in which the insulator 916 was not subjected to the microwave-excited plasma treatment was.

Next, a method for fabricating the samples will be described.

First, a silicon substrate is prepared as the substrate 912. Then, a 100-nm-thick thermal oxide film was formed as the insulator 914 over the substrate 912. Next, a 100-nm-thick silicon oxynitride film was formed as the insulator 916 over the insulator 914 by a plasma CVD method. As deposition gases, silane (SiH₄) at a flow rate of 8 sccm and dinitrogen monoxide (N₂O) at a flow rate of 4000 sccm were used. Furthermore, the film deposition was performed under the conditions where the pressure in the reaction chamber was 800 Pa, the substrate surface temperature was 325° C., and a high-frequency (RF) power of 150 W (60 MHz) was applied.

Next, the microwave-excited plasma treatment was performed on Sample 2A to Sample 2C with the microwave plasma treatment apparatus for 60 minutes. The microwave-excited plasma treatment was performed under an atmosphere of argon (Ar) at a flow rate of 150 sccm and oxygen (O₂) at a flow rate of 50 sccm. Furthermore, the pressure in the reaction chamber was 60 Pa, a high-frequency (RF) bias of 13.56 MHz was applied, and plasma was generated with a microwave of 4000 W (2.45 GHz).

In the step of the microwave-excited plasma treatment on Sample 2A, plasma treatment was performed while a high-frequency (RF) bias of 600 W was applied. In the step of the microwave-excited plasma treatment on Sample 2B, plasma treatment was performed while a high-frequency (RF) bias of 300 W was applied.

Through the above steps, Sample 2A to Sample 2D of this example were fabricated.

### <2. TDS Measurement Results of Samples>

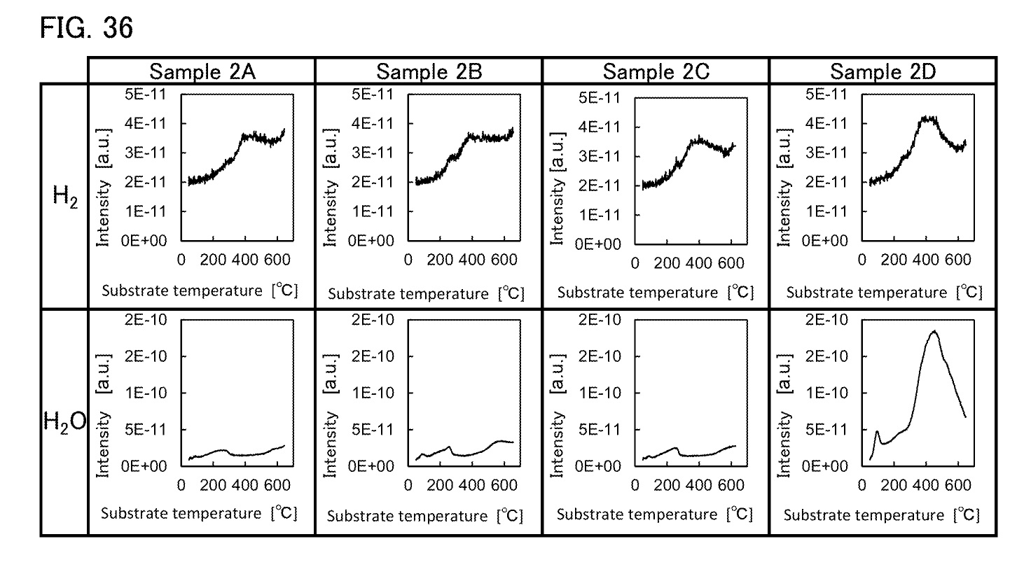

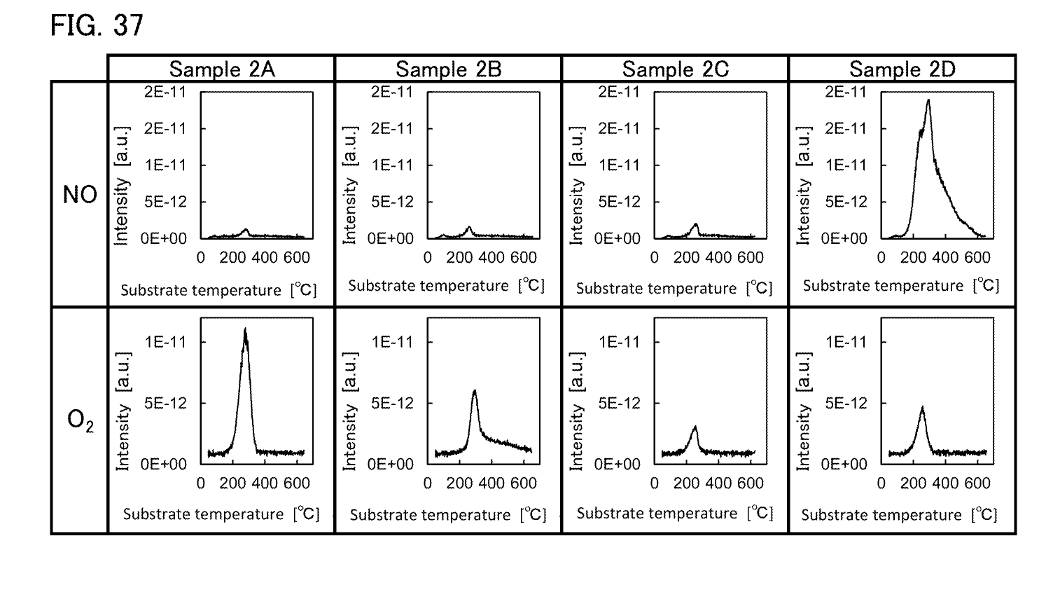

FIG. 36 and FIG. 37 show results of TDS analysis. Note that in the TDS analysis, the released amount with a mass-to-charge ratio m/z=2 which corresponds to a hydrogen molecule, the released amount with a mass-to-charge ratio m/z=18 which corresponds to a water molecule, the released amount with a mass-to-charge ratio m/z=30 which corresponds to nitrogen monoxide, and the released amount with a mass-to-charge ratio m/z=32 which corresponds to an oxygen molecule were measured. WA1000S produced by ESCO Ltd. was used as a TDS analysis apparatus, and a temperature rising rate was 30° C./min.

FIG. 36 shows substrate temperature dependence of the released amounts of hydrogen and water, and FIG. 37 shows substrate temperature dependence of the released amounts of nitrogen monoxide and oxygen. In FIG. 36 and FIG. 37, the horizontal axis represents substrate heating temperature [° C.] and the vertical axis represents intensity proportional to the released amount with each mass-to-charge ratio.

Furthermore, as shown in FIG. 36, it was found that the released amounts of hydrogen and water were reduced by performing the microwave-excited plasma treatment. In particular, the released amount of water was found to be greatly reduced. Note that the released amount of water can be reduced more effectively when the microwave-excited plasma treatment is performed while a bias of 600 W is applied.

As shown in FIG. 37, the released amount of nitrogen monoxide was found to be greatly reduced by performing the microwave-excited plasma treatment. That is, it was found that almost all nitrogen monoxide contained in the structure 910 was removed.

FIG. 37 also shows that the released amount of oxygen is reduced when the microwave-excited plasma treatment is performed without application of an RF bias. By contrast, the released amount of oxygen is increased when the microwave-excited plasma treatment is performed while an RF bias is applied to the substrate. That is, when the microwave-excited plasma treatment is performed while an RF bias is applied to the substrate, oxygen is added (excessively) to the insulator 916. Furthermore, more oxygen is added (excessively) in the case where an RF bias of 600 W is applied than in the case where 300 W is applied. That is, as the RF bias to be applied becomes higher, more oxygen tends to be added (excessively).

The structure described in this example can be used in appropriate combination with the other examples or the other embodiments.

### Example 3

In this example, the released amounts of hydrogen (H₂), water (H₂O), nitrogen monoxide (NO), and oxygen (O₂) were evaluated using a stacked-layer structure of an oxide and insulators of one embodiment of the present invention. Note that Sample 3A to Sample 3F were fabricated in this example.

### <1. Structure and Fabrication Method of Samples>

Sample 3A, Sample 3B, Sample 3C, Sample 3D, Sample 3E, and Sample 2F of one embodiment of the present invention will be described below. Sample 3A to Sample 3F each include the substrate 912, the insulator 914 over the substrate 912, and the insulator 916 over the insulator 914 as the structure 910 shown in FIG. 35.

Next, a method for fabricating the samples will be described.

First, a silicon substrate is prepared as the substrate 912. Then, a 100-nm-thick thermal oxide film was formed as the insulator 914 over the substrate 912. Next, a 100-nm-thick silicon oxynitride film was formed as the insulator 916 over the insulator 914 by a plasma CVD method. As deposition gases, silane (SiH₄) at a flow rate of 8 sccm and dinitrogen monoxide (N₂O) at a flow rate of 4000 sccm were used. Furthermore, the film deposition was performed under the conditions where the pressure in the reaction chamber was 800 Pa, the substrate surface temperature was 325° C., and a high-frequency (RF) power of 150 W (60 MHz) was applied.

Next, the microwave-excited plasma treatment was performed on Sample 3B to Sample 3F with the microwave plasma treatment apparatus while a high-frequency (RF) bias of 600 W was applied. The microwave-excited plasma treatment was performed under an atmosphere of argon (Ar) at a flow rate of 150 sccm and oxygen (O₂) at a flow rate of 50 sccm. Furthermore, the pressure in the reaction chamber was 60 Pa, a high-frequency (RF) bias of 13.56 MHz was applied, and plasma was generated with a microwave of 4000 W (2.45 GHz).

Here, the microwave-excited plasma treatment was performed on Sample 3B for 30 seconds, Sample 3C for 5 minutes, Sample 3D for 10 minutes, Sample 3E for 15 minutes, and Sample 3F for 60 minutes.

Through the above steps, Sample 3A to Sample 3F of this example were fabricated.

### <2. TDS Measurement Results of Samples>

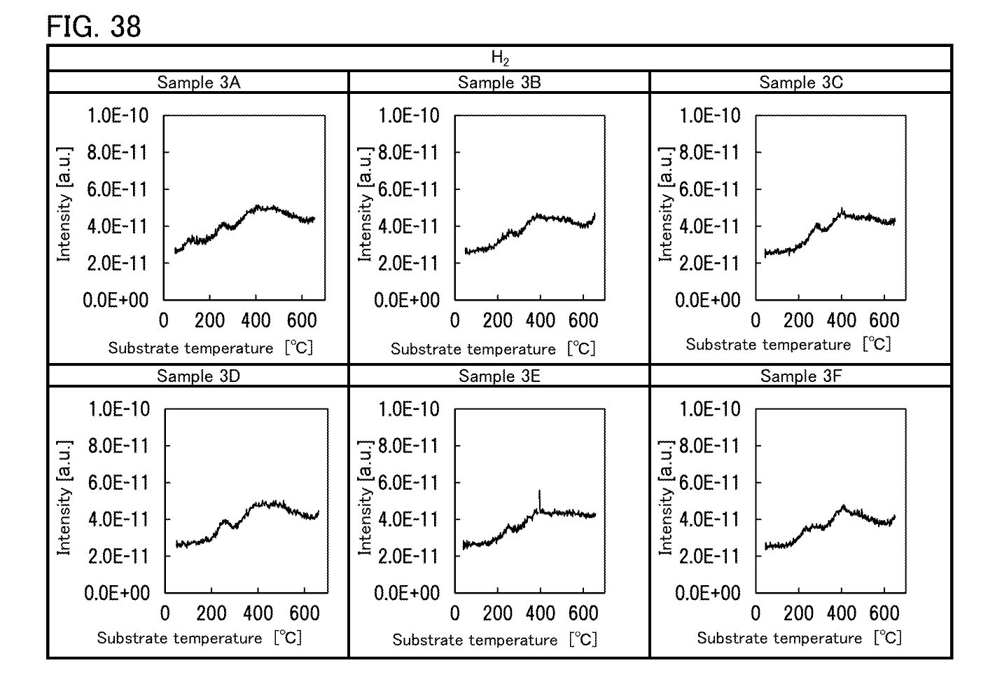

FIG. 38 to FIG. 41 show results of TDS analysis. Note that in the TDS analysis, the released amount with a mass-to-charge ratio m/z=2 which corresponds to a hydrogen molecule, the released amount with a mass-to-charge ratio m/z=18 which corresponds to a water molecule, the released amount with a mass-to-charge ratio m/z=30 which corresponds to nitrogen monoxide, and the released amount with a mass-to-charge ratio m/z=32 which corresponds to an oxygen molecule were measured. WA1000S produced by ESCO Ltd. was used as a TDS analysis apparatus, and a temperature rising rate was 30° C./min.

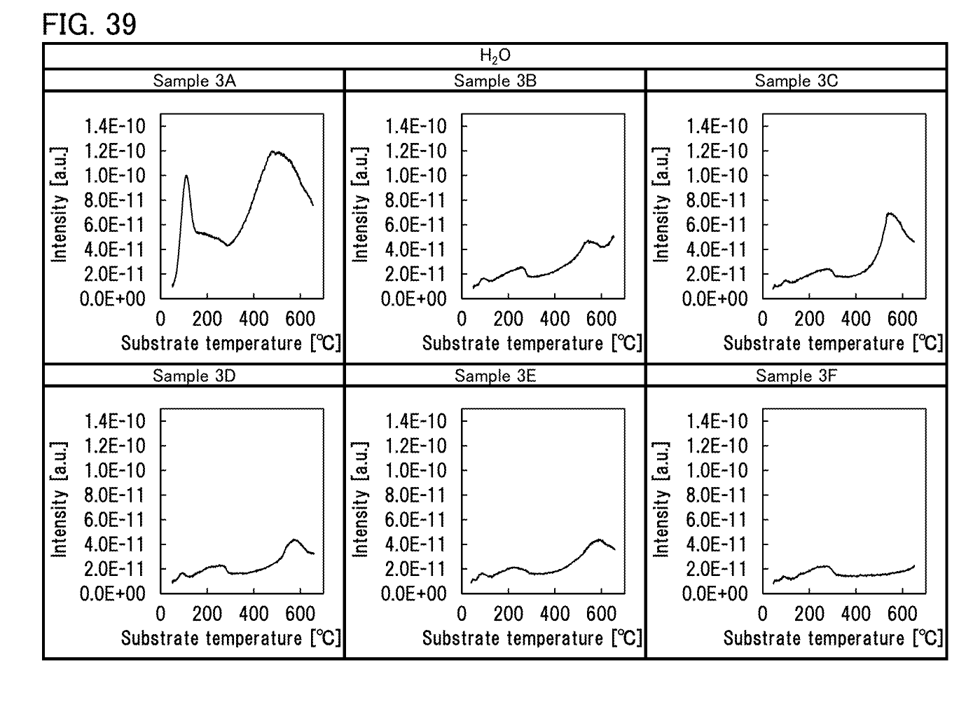

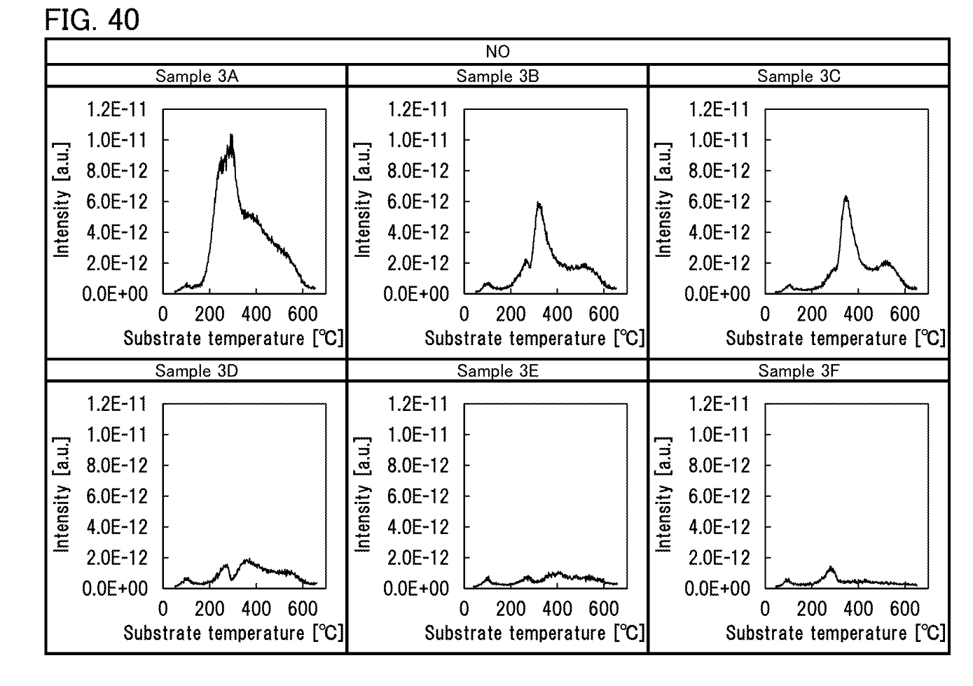

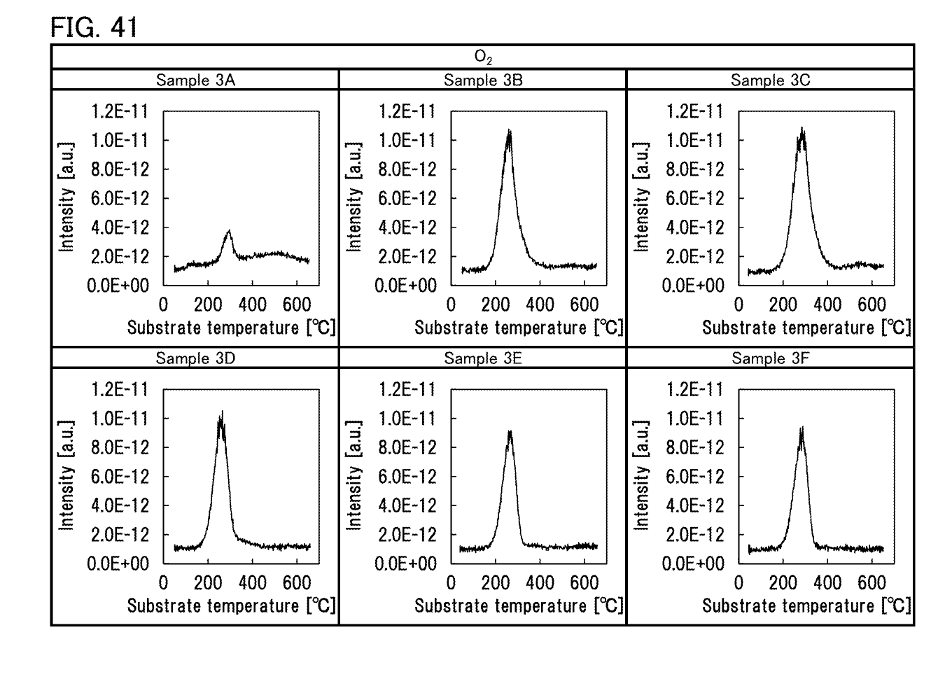

FIG. 38 shows substrate temperature dependence of the released amount of hydrogen, FIG. 39 shows substrate temperature dependence of the released amount of water, FIG. 40 shows substrate temperature dependence of the released amount of nitrogen monoxide, and FIG. 41 shows substrate temperature dependence of the released amount of oxygen. In FIG. 38 to FIG. 41, the horizontal axis represents substrate heating temperature [° C.] and the vertical axis represents intensity proportional to the released amount with each mass-to-charge ratio.

FIG. 38 shows the released amount of hydrogen. The content of hydrogen is originally smaller than that of other impurities in the insulator 916; thus, a significant change was not observed.

As shown in FIG. 39, it was found that the released amount of water was reduced by performing the microwave-excited plasma treatment. In particular, in the range of 400° C. or lower, the released amount of water was found to be greatly reduced by the microwave-excited plasma treatment performed for 30 seconds. Furthermore, by the microwave-excited plasma treatment performed for 10 minutes or more, the released amount of water can be reduced to a negligible level in the range of 400° C. or higher.

As shown in FIG. 40, it was found that the released amount of nitrogen monoxide was greatly reduced by performing the microwave-excited plasma treatment. In particular, by the microwave-excited plasma treatment performed for 10 minutes or more, the released amount of nitrogen monoxide can be reduced to a negligible level.

Furthermore, as shown in FIG. 41, it was found that the released amount of oxygen was greatly increased by the microwave-excited plasma treatment performed for 30 seconds or more. That is, the microwave-excited plasma treatment adds oxygen (excessively) to the insulator 916.

The structure described in this example can be used in appropriate combination with the other examples or the other embodiments.

### Example 4

In this example, SIMS analysis was performed using a stacked-layer structure of an oxide and insulators of one embodiment of the present invention. Note that Sample 4A to Sample 4H were fabricated in this example.

### <1. Structure and Fabrication Method of Samples>

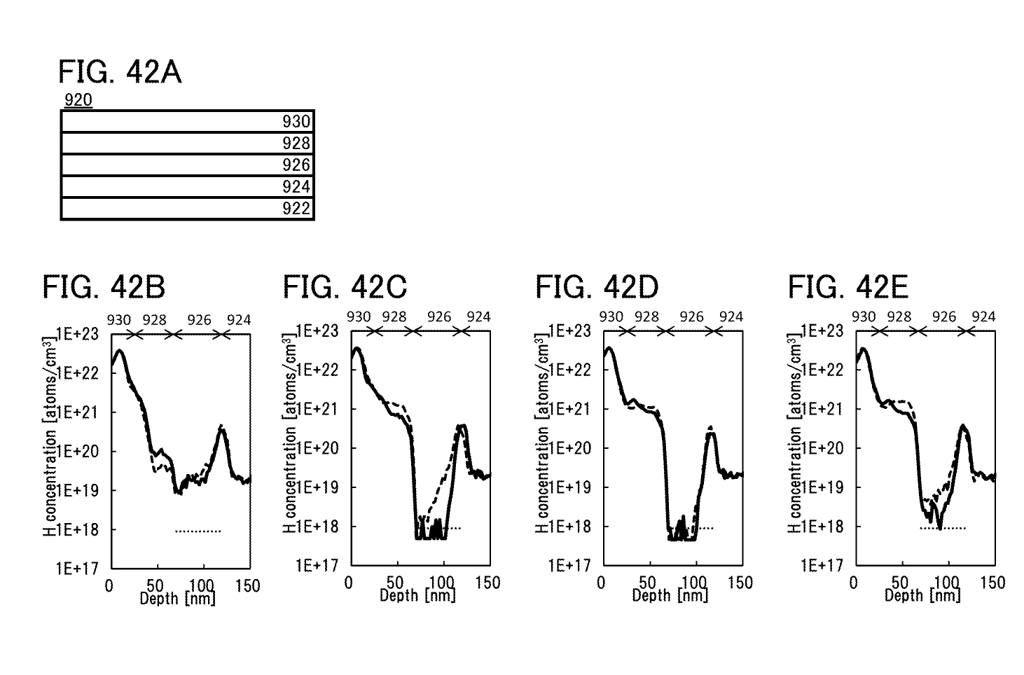

Sample 4A, Sample 4B, Sample 4C, Sample 4D, Sample 4E, Sample 4F, Sample 4G, and Sample 4H of one embodiment of the present invention will be described below. Sample 4A to Sample 4H each include a substrate 922, an insulator 924 over the substrate 922, an oxide 926 over the insulator 924, an insulator 928 over the oxide 926, and an insulator 930 over the insulator 928 as a structure 920 shown in FIG. 42(A).

Next, a method for fabricating the samples will be described.

First, a silicon substrate was prepared as the substrate 922. Then, a 100-nm-thick thermal oxide film was formed as the insulator 924 over the substrate 922.

Next, the 50-nm-thick oxide 926 containing In, Ga, and Zn was deposited over the insulator 924 by a DC sputtering method. The oxide 926 was deposited under the conditions where an oxide target containing In, Ga, and Zn (with an atomic ratio of In:Ga:Zn=4:2:4.1) was used, argon (Ar) at a flow rate of 40 sccm and oxygen (O₂) at a flow rate of 5 sccm were used as deposition gases, the deposition pressure was 0.7 Pa, the deposition power was 500 W, the substrate temperature was 130° C., and the target-substrate distance was 60 mm.

Then, after heat treatment was performed under a nitrogen atmosphere at 400° C. for one hour, the atmosphere was replaced by an oxygen atmosphere and heat treatment was performed under the oxygen atmosphere at 400° C. for one hour.

Next, 20-nm-thick aluminum oxide was deposited as the insulator 928 over the oxide 926 by an RF sputtering method. The insulator 928 was deposited under the conditions where an Al₂O₃ target was used, argon (Ar) at a flow rate of 25 sccm and oxygen (O₂) at a flow rate of 25 sccm were used as deposition gases, the deposition pressure was 0.4 Pa, the deposition power was 2500 W, and the target-substrate distance was 60 mm.

Here, for Sample 4A, Sample 4C, Sample 4E, and Sample 4G, the substrate temperature was 130° C. Furthermore, for Sample 4B, Sample 4D, Sample 4F, and Sample 4H, the substrate temperature was 250° C.

Furthermore, for Sample 4C, Sample 4D, Sample 4G, and Sample 4H, after heat treatment was performed under a nitrogen atmosphere at 400° C. for one hour, the atmosphere was replaced by an oxygen atmosphere and heat treatment was performed under the oxygen atmosphere at 400° C. for one hour.

Next, 5-nm-thick aluminum oxide was deposited as the insulator 930 over the insulator 928 by an ALD method. The insulator 930 was deposited using trimethylaluminum (Al(CH₃)₃), ozone (O₃), and oxygen (O₂) as precursors and at a substrate temperature of 250° C.

Furthermore, for Sample 4E, Sample 4F, Sample 4G, and Sample 4H, after heat treatment was performed under a nitrogen atmosphere at 400° C. for one hour, the atmosphere was replaced by an oxygen atmosphere and heat treatment was performed under the oxygen atmosphere at 400° C. for one hour.

Through the above steps, Sample 4A to Sample 4C of this example were fabricated. Note that Table 1 shows the deposition temperature of the insulator 928 in Sample 4A to Sample 4H and whether the heat treatment was performed.

TABLE 1

| | Deposition | Heat treatment after | Heat treatment after |
|---|---|---|---|
| Sample | temperature of the | the deposition | the deposition of |
| name | insulator 928 [° C.] | of the insulator 928 | the insulator 930 |
| 4A | 130 | X | X |
| 4B | 250 | | |
| 4C | 130 | ◯ | X |
| 4D | 250 | | |
| 4E | 130 | X | ◯ |
| 4F | 250 | | |
| 4G | 130 | ◯ | ◯ |
| 4H | 250 | | |

### <2. SIMS Measurement Results of Samples>

Next, FIG. 42(B) to FIG. 42(E) show measurement results of hydrogen (H) concentration obtained by SIMS analysis from the substrate side with the oxide 926 in each of Sample 4A to Sample 4H used as a quantified layer. Note that the hydrogen concentration evaluation was performed by secondary ion mass spectrometry (Secondary Ion Mass Spectrometry: SIMS) with the use of a dynamic SIMS apparatus IMS-7f produced by CAMECA SAS as an analysis apparatus.

FIG. 42(B) shows hydrogen (H) concentration profiles in the depth direction of films of Sample 4A (solid line) and Sample 4B (broken line). Note that double-headed arrows in the figure show the range of the quantified layer, and a broken line shows a background level (BGL).

In the case of not performing the heat treatment, a difference in the hydrogen concentration in the oxide 926 due to the deposition temperature of the insulator 928 was not observed.

FIG. 42(C) shows hydrogen (H) concentration profiles in the depth direction of films of Sample 4C (solid line) and Sample 4D (broken line). Note that double-headed arrows in the figure show the range of the quantified layer, and a broken line shows the background level (BGL).

The comparison between FIG. 42(C) and FIG. 42(B) shows that hydrogen in the oxide 926 can be reduced when the heat treatment is performed after the insulator 928 is deposited. In particular, hydrogen in the oxide 926 can be further reduced in the case where the deposition temperature of the insulator 928 is low.

FIG. 42(D) shows hydrogen (H) concentration profiles in the depth direction of films of Sample 4E (solid line) and Sample 4F (broken line). Note that double-headed arrows in the figure show the range of the quantified layer, and a broken line shows the background level (BGL).

The comparison between FIG. 42(D) and FIG. 42(B) shows that hydrogen in the oxide 926 can be reduced when the heat treatment is performed after the insulator 930 is deposited. The comparison between FIG. 42(D) and FIG. 42(C) also shows that even in the case where the deposition temperature of the insulator 928 is high, hydrogen in the oxide 926 can be reduced to the background level when the heat treatment is performed after the insulator 930 is deposited.

FIG. 42(E) shows hydrogen (H) concentration profiles in the depth direction of films of Sample 4G (solid line) and Sample 4H (broken line). Note that double-headed arrows in the figure show the range of the quantified layer, and a broken line shows the background level (BGL).

The comparison between FIG. 42(E) and FIG. 42(B) shows that hydrogen in the oxide 926 can be reduced when the heat treatment is performed after the insulator 928 is deposited and after the insulator 930 is deposited. By contrast, the comparison between FIG. 42(E), FIG. 42(C), and FIG. 42(D) shows that hydrogen in the oxide 926 is increased in the case where the heat treatment is performed after the insulator 928 is deposited and after the insulator 930 is deposited as compared to the case where the heat treatment is performed after the insulator 928 is deposited or after the insulator 930 is deposited.

This is because hydrogen in the oxide 926 moves into the insulator 928 when the heat treatment is performed once after the insulator 928 is deposited, so that hydrogen in the insulator 928 increases. Furthermore, the insulator 930 is deposited by an ALD method and thus has a high hydrogen content. In the case where 910 containing a lot of hydrogen is stacked over the insulator 928 containing an increased amount of hydrogen and heating is performed, hydrogen in the insulator 928 probably diffuses into the oxide 926 whose hydrogen concentration is lower than that of the insulator 930.

Thus, hydrogen in an oxide can be reduced when heat treatment is performed after aluminum oxide deposited at a low deposition temperature is deposited in contact with the oxide. In particular, hydrogen in an oxide can be effectively reduced when heat treatment is performed after aluminum oxide deposited by a sputtering method and aluminum oxide deposited by an ALD method are stacked over the oxide.

The structure described in this example can be used in appropriate combination with the other examples or the other embodiments.

### REFERENCE NUMERALS

100 capacitor
101 capacitor
110 insulator
112 conductor
116 conductor
130 insulator
132 insulator
134 insulator
150 insulator
200 transistor
201 transistor
205 conductor
205a conductor
205b conductor
207 conductor
207a conductor
207b conductor
s210 insulator
212 insulator
214 insulator
216 insulator
218 conductor
220 insulator
222 insulator
224 insulator
226 insulator
230 oxide
230a oxide
230A oxide film
230b oxide
230B oxide film
230c oxide
230C oxide film
240 conductor
240a conductor
240A conductive film
240b conductor
240B conductive film
245 layer
245a layer
245A film
245b layer
245B film
247a conductor
247A conductive film
247b conductor
247B conductive film
250 insulator
250A insulating film
260 conductor
260a conductor
260A conductive film
260b conductor
260B conductive film
260c conductor
260C conductive film
270 layer
272 insulator
274 insulator
280 insulator
281 valve
282 insulator
284 insulator
285 conductor
287 conductor
290 resist mask
299 region
300 transistor
301 transistor
311 substrate
312 semiconductor region
314 insulator
316 conductor
318a low-resistance region
318b low-resistance region
320 insulator
322 insulator
324 insulator
326 insulator
328 conductor
330 conductor
350 insulator
352 insulator
354 insulator
356 conductor
358 insulator
400 transistor
403 conductor
403a conductor
403b conductor
405 conductor
405a conductor
405b conductor
405c conductor
407 conductor
407a conductor
407b conductor
407c conductor
430 oxide
450 insulator
460 conductor
460a conductor
460b conductor
460c conductor
470 layer
480 opening
900 structure
902 substrate
904 insulator
910 structure
912 substrate
914 insulator
916 insulator
920 structure
922 substrate
924 insulator
926 oxide
928 insulator
930 insulator
1000 semiconductor device
2700 manufacturing apparatus
2701 atmosphere-side substrate supply chamber
2702 atmosphere-side substrate transfer chamber
2703a load lock chamber
2703b unload lock chamber
2704 transfer chamber
2706a chamber
2706b chamber
2706c chamber
2706d chamber
2761 cassette port
2762 alignment port
2763a transfer robot
2763b transfer robot
2801 gas supply source
2802 valve
2803 high-frequency generator
2804 waveguide
2805 mode converter
2806 gas pipe
2807 waveguide
2808 slot antenna plate
2809 dielectric plate
2810 high-density plasma
2811 substrate
2812 substrate holder
2813 heating mechanism
2815 matching box
2816 high-frequency power source
2817 vacuum pump
2818 valve
2819 exhaust port
2820 lamp
2821 gas supply source
2822 valve
2823 gas inlet
2824 substrate
2825 substrate holder
2826 heating mechanism
2827 vacuum pump
2828 vacuum pump
2829 valve
2830 exhaust port
3001 wiring
3002 wiring
3003 wiring
3004 wiring
3005 wiring
3006 wiring
3007 wiring
3008 wiring
3009 wiring
3010 wiring

1. A method for fabricating a semiconductor device, comprising:
forming a first conductor;
forming a first insulator over the first conductor;
forming a second insulator over the first insulator;
forming a third insulator over the second insulator;
performing microwave-excited plasma treatment on the third insulator;
forming an island-shaped first oxide semiconductor over the third insulator, and a second conductor and a third conductor over the first oxide semiconductor;
forming an oxide semiconductor film over the first oxide semiconductor, the second conductor, and the third conductor;
forming a first insulating film over the oxide semiconductor film;
forming a conductive film over the first insulating film;
forming a fourth insulator and a fourth conductor by partly removing the first insulating film and the conductive film;
forming a second insulating film to cover the oxide semiconductor film, the fourth insulator, and the fourth conductor;
forming a second oxide semiconductor and a fifth insulator by partly removing the oxide semiconductor film and the second insulating film to expose a side surface of the first oxide semiconductor;
forming a sixth insulator in contact with the side surface of the first oxide semiconductor and a side surface of the second oxide semiconductor;
forming a seventh insulator in contact with the sixth insulator; and
performing heat treatment.

2. A method for fabricating a semiconductor device according to claim 1,
wherein the microwave-excited plasma treatment is performed with a pressure of lower than or equal to 70 Pa.

3. The method for fabricating a semiconductor device according to claim 1,
wherein the microwave-excited plasma treatment is performed with an oxygen flow rate of higher than or equal to 10% and lower than or equal to 30%.

4. The method for fabricating a semiconductor device according to claim 1,
wherein the microwave-excited plasma treatment is performed while an RF bias is applied to a substrate.

5. The method for fabricating a semiconductor device according to claim 1,
wherein the sixth insulator is formed by a sputtering method at a substrate temperature of higher than or equal to 120° C. and lower than or equal to 150° C.

6. The method for fabricating a semiconductor device according to claim 1,
wherein heat treatment is performed at higher than or equal to 100° C. in a film deposition apparatus, and then the sixth insulator is deposited in the film deposition apparatus without exposure to air.

7. A method for fabricating a semiconductor device, comprising:
forming a first conductor;
forming a first insulator over the first conductor;
forming a second insulator over the first insulator;
forming a third insulator over the second insulator;
performing microwave-excited plasma treatment on the third insulator;
forming an island-shaped first oxide semiconductor over the third insulator, and a second conductor and a third conductor over the first oxide semiconductor;
forming an oxide semiconductor film over the first oxide semiconductor, the second conductor, and the third conductor;
forming a first insulating film over the oxide semiconductor film;
forming a conductive film over the first insulating film;
forming a fourth conductor by partly removing the conductive film;
forming a second insulating film to cover the first insulating film and the fourth conductor;
forming a second oxide semiconductor, the fourth insulator, and a fifth insulator by partly removing the oxide semiconductor film, the first insulating film, and the second insulating film to expose a side surface of the first oxide semiconductor;
forming a sixth insulator in contact with the side surface of the first oxide semiconductor and a side surface of the second oxide semiconductor;
forming a seventh insulator in contact with the sixth insulator; and
performing heat treatment.

8. The method for fabricating a semiconductor device according to claim 7,
wherein the microwave-excited plasma treatment is performed with a pressure of lower than or equal to 70 Pa.

9. The method for fabricating a semiconductor device according to claim 7,
wherein the microwave-excited plasma treatment is performed with an oxygen flow rate of higher than or equal to 10% and lower than or equal to 30%.

10. The method for fabricating a semiconductor device according to claim 7,
wherein the microwave-excited plasma treatment is performed while an RF bias is applied to a substrate.

11. The method for fabricating a semiconductor device according to claim 7,
wherein the sixth insulator is formed by a sputtering method at a substrate temperature of higher than or equal to 120° C. and lower than or equal to 150° C.

12. The method for fabricating a semiconductor device according to claim 7,
wherein heat treatment is performed at higher than or equal to 100° C. in a film deposition apparatus, and then the sixth insulator is deposited in the film deposition apparatus without exposure to air.
